(19) United States
(12) Patent Application Publication
(10) Pub. No.: US 2026/0013326 A1
(43) Pub. Date: Jan. 8, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Shaojie QIN, Beijing (CN); Yipeng CHEN, Beijing (CN); Cuicui LIANG, Beijing (CN); Rui HOU, Beijing (CN); Xinxing GUAN, Beijing (CN)

(21) Appl. No.: 18/992,583

(22) PCT Filed: Apr. 24, 2024
(86) PCT No.: PCT/CN2024/089483

§ 371 Date: Jan. 9, 2025

(30) Foreign Application Priority Data
May 30, 2023 (CN) 202310629021.9

(51) Int. Cl. H10K 59/121; H10K 59/122; H10K 59/126; H10K 59/131; H10K 59/35

(52) U.S. Cl. CPC H10K 59/1213; H10K 59/122; H10K 59/126; H10K 59/131; H10K 59/352

(57) ABSTRACT

A display substrate and a display apparatus. The display substrate comprises a base, and a plurality of sub-pixels, a driving circuit layer and a pixel definition layer, which are arranged on the base, wherein the driving circuit layer is located between the base and the pixel definition layer, a plurality of pixel openings are formed in the pixel definition layer, and each sub-pixel comprises at least one pixel opening; and a plurality of types of sub-pixels among the plurality of sub-pixels at least comprise a first sub-pixel and a second sub-pixel, the area of a pixel opening of the first sub-pixel is smaller than the area of a pixel opening of the second sub-pixel, and the pixel opening and the pixel opening of the second sub-pixel overlap at least one conductive layer in the driving circuit layer.

### CROSS-REFERENCE TO RELATED APPLICATIONS

The present application is a U.S. National Phase Entry of International Application PCT/CN2024/089483 having an international filing date of Apr. 24, 2024, which claims priority to Chinese Patent Application No. 202310629021.9, filed to the CNIPA on May 30, 2023 and entitled “Display Substrate and Display Apparatus”, and contents of which should be construed as being incorporated into the present application by reference.

### TECHNICAL FIELD

Embodiments of the present disclosure relate to, but are not limited to, the field of display technologies, and particularly to a display substrate and a display apparatus.

### BACKGROUND

An Organic Light Emitting Diode (OLED) and a Quantum dot Light Emitting Diode (QLED) are active light emitting display devices and have advantages such as self-illumination, wide viewing angle, high contrast ratio, low power consumption, very high reaction speed, lightness and thinness, flexibility, and low cost. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matter described herein in detail. This summary is not intended to limit the protection scope of claims.

In a first aspect, an embodiment of the present disclosure provides a display substrate, including a base substrate, and a plurality of sub-pixels, a drive circuit layer and a pixel definition layer disposed on the base substrate, wherein in a direction perpendicular to a plane of the display substrate, the drive circuit layer is located between the base substrate and the pixel definition layer, a plurality of pixel openings are formed in the pixel definition layer, and each sub-pixel includes at least one pixel opening;
the plurality of sub-pixels include a plurality of types of sub-pixels, the plurality of types of sub-pixels at least include a first sub-pixel and a second sub-pixel, an area of a pixel opening of the first sub-pixel is smaller than an area of a pixel opening of the second sub-pixel, the pixel opening of the first sub-pixel and the pixel opening of the second sub-pixel overlap with at least one conductive layer in the drive circuit layer, and an overlapping area of the pixel opening of the first sub-pixel with the at least one conductive layer is larger than an overlapping area of the pixel opening of the second sub-pixel with the at least one conductive layer.

In an exemplary implementation, the plurality of types of sub-pixels further include a third sub-pixel, the area of the pixel opening of the first sub-pixel is smaller than an area of a pixel opening of the third sub-pixel, and an overlapping area of the pixel opening of the third sub-pixel with the at least one conductive layer is larger than the overlapping area of the pixel opening of the second sub-pixel with the at least one conductive layer.

In an exemplary implementation, orthographic projections of the pixel opening of the first sub-pixel and the pixel opening of the third sub-pixel on the base substrate are within a range of an orthographic projection of the at least one conductive layer on the base substrate.

In an exemplary implementation, the at least one conductive layer includes a first protrusion and a second protrusion, an orthographic projection of the pixel opening of the first sub-pixel on the base substrate is within a range of an orthographic projection of the first protrusion on the base substrate, and an orthographic projection of the pixel opening of the third sub-pixel on the base substrate is within a range of an orthographic projection of the second protrusion on the base substrate.

In an exemplary implementation, the pixel opening of the second sub-pixel overlaps with patterns of at least two portions of signal lines in the at least one conductive layer, and the patterns of the at least two portions of signal lines are distributed on two sides of a center of the pixel opening of the second sub-pixel.

In an exemplary implementation, the pixel opening of the first sub-pixel and the pixel opening of the third sub-pixel are arranged in a column direction, and main body portions of the signal lines in the patterns of the at least two portions of signal lines extend in the column direction.

In an exemplary implementation, the display substrate further includes an anode via and an anode connection electrode, the patterns of the at least two portions of signal lines include a proximal portion and a distal portion relative to the pixel opening of the second sub-pixel, the pixel opening of the second sub-pixel overlaps with the proximal portion, a hollow structure is provided in the middle of the distal portion, the hollow structure is configured to accommodate the anode connection electrode, an orthographic projection of the anode connection electrode on the base substrate is overlapped with an orthographic projection of a corresponding hollow structure on the base substrate, and an orthographic projection of the anode via on the base substrate is overlapped with an orthographic projection of the corresponding anode connection electrode on the base substrate.

In an exemplary implementation, the pixel opening of the second sub-pixel also overlaps with at least part of signal wires other than the patterns of the at least two portions of signal lines in the drive circuit layer, and the at least part of signal wires located on two sides of the center of the pixel opening of the second sub-pixel have a same overlapping area with the pixel opening of the second sub-pixel.

In an exemplary implementation, the display substrate further includes an anode conductive layer, in the direction perpendicular to the plane of the display substrate, the anode conductive layer is located between the drive circuit layer and the pixel definition layer, and at least a part of the at least one conductive layer includes a conductive layer closest to the anode conductive layer in the drive circuit layer.

In an exemplary implementation, pixel openings of a plurality of a same type of sub-pixels are arranged in a row direction and a column direction, and centers of pixel openings of a plurality of a same type of sub-pixels located in a same row are on a same straight line. In an exemplary implementation, the pixel openings of a plurality of the same type of sub-pixels form M rows and N columns, where M and N are positive integers greater than 1, among the pixel openings of the plurality of the same type of sub-pixels in the M rows and N columns, a center of a pixel opening of a sub-pixel located in row i and column j is on a same straight line as centers of pixel openings of sub-pixels located in row i+1 and column j+1 and in row i+2 and column j+2, where i is a positive integer greater than 1 and smaller than or equal to M, and j is a positive integer greater than 1 and smaller than or equal to N.

In an exemplary implementation, among the pixel openings of the plurality of the same type of sub-pixels in M rows and N columns, a centerline of a pixel opening of a sub-pixel located in row i and column j+2 is on a same straight line as centerlines of pixel openings of sub-pixels located in row i+1 and column j+1 and in row i+2 and column j.

In an exemplary implementation, the at least one conductive layer includes a plurality of data signal lines, a main body portion of a data signal line extends in the column direction, the pixel definition layer is further formed with a plurality of first openings arranged in an array, an orthographic projection of a first opening on the base substrate does not overlap with an orthographic projection of the data signal line on the base substrate, and the first openings and the pixel openings of the second sub-pixels are alternately arranged in the column direction.

In an exemplary implementation, in the column direction, the pixel openings of the first sub-pixels and the pixel openings of the third sub-pixels are alternately arranged, a pixel opening of a second sub-pixel and a first opening are located between pixel openings of first sub-pixels and pixel openings of third sub-pixels in adjacent columns, and a pixel opening of a first sub-pixel and a pixel opening of a third sub-pixel are located between first openings and pixel openings of second sub-pixels in adjacent columns.

In an exemplary implementation, in the row direction, a pixel opening of a first sub-pixel and a pixel opening of a third sub-pixel are located between two first openings in adjacent rows and pixel openings of two second sub-pixels in adjacent rows, and a pixel opening of a second sub-pixel and a first opening are located between pixel openings of two first sub-pixels in adjacent rows and pixel openings of two third sub-pixels in adjacent rows.

In an exemplary implementation, the display substrate further includes an anode conductive layer, the at least one conductive layer includes a fifth conductive layer, on the plane perpendicular to the display substrate, the anode conductive layer is located between the fifth conductive layer and the pixel definition layer, the anode conductive layer includes an anode of the second sub-pixel, there is a first overlapping area between an orthographic projection of the fifth conductive layer on the base substrate and orthographic projections of the pixel opening of the second sub-pixel and the anode of the second sub-pixel on the base substrate, and on a plane parallel to the display substrate, the first overlapping area is symmetrical with respect to centerlines of the pixel opening of the second sub-pixel in the row direction and the column direction.

In an exemplary implementation, the anode conductive layer further includes an anode of the first sub-pixel and an anode of the third sub-pixel, the fifth conductive layer includes a plurality of first power supply lines, main body portions of the first power supply lines extend in the column direction, and orthographic projections of the pixel opening and the anode of the first sub-pixel and the pixel opening and the anode of the third sub-pixel on the base substrate are within a range of an orthographic projection of the first power supply lines on the base substrate.

In an exemplary implementation, in the row direction, the first opening is located between two adjacent data signal lines, and the two data signal lines located on two sides of the first opening are symmetrically disposed with respect to a centerline, extending in the column direction, of the pixel opening of the second sub-pixel in the column where the first opening is located.

In an exemplary implementation, at least one sub-pixel includes a pixel drive circuit, the pixel drive circuit includes a plurality of transistors, the plurality of transistors include a drive transistor and a fourth transistor, a second electrode of the fourth transistor is electrically connected to a first electrode of the drive transistor, the fourth transistor is disposed to provide a data signal to the drive transistor, the data signal lines located on the two sides of the first opening in the row direction include a first portion and a second portion which are integrally formed, the first portion extends in the column direction, the second portion is a bent structure, orthographic projections of a channel region and a first region of the fourth transistor on the base substrate overlap with an orthographic projection of the first portion on the base substrate, first portions of the two data signal lines located on the two sides of the first opening in the row direction form a second opening, and an orthographic projection of the first opening on the base substrate is within a range of an orthographic projection of the second opening on the base substrate.

In an exemplary implementation, a middle portion of the second portion is bent in a direction close to the first opening, and an orthographic projection of the middle portion of the second portion on the base substrate is overlapped with orthographic projections of the pixel opening and the anode of the second sub-pixel on the base substrate.

In an exemplary implementation, a distance between two adjacent data signal lines at a position of the first opening is larger than a distance between two adjacent data signal lines at a position of the pixel opening of the second sub-pixel.

In an exemplary implementation, the plurality of sub-pixels further include light-emitting layers corresponding to the pixel openings, the first sub-pixel includes a first light-emitting layer, the second sub-pixel includes a second light-emitting layer, the third sub-pixel includes a third light-emitting layer, light-emitting layers of a plurality of types of sub-pixels are arranged in the row direction and the column direction, and centerlines of light-emitting layers of a plurality of a same type of sub-pixels located in a same row are on a same straight line.

In an exemplary implementation, the light-emitting layers of the plurality of the same type of sub-pixels form M rows and N columns, where M and N are positive integers greater than 1, among the light-emitting layers of the plurality of the same type of sub-pixels in the M rows and N columns, a center of a light-emitting layer of a sub-pixel located in row i and column j is on a same straight line as centers of light-emitting layers of sub-pixels located in row i+1 and column j+1 and in row i+2 and column j+2, where i is a positive integer greater than 1 and smaller than or equal to M, and j is a positive integer greater than 1 and smaller than or equal to N.

In an exemplary implementation, among the light-emitting layers of the plurality of the same type of sub-pixels in M rows and N columns, a centerline of a light-emitting layer of a sub-pixel located in row i and column j+2 is on a same straight line as centerlines of light-emitting layers of sub-pixels located in row i+1 and column j+1 and in row i+2 and column j.

In an exemplary implementation, the light-emitting layers of the plurality of sub-pixels have a same shape as corresponding pixel openings, and an orthographic projection of the light-emitting layers of the plurality of sub-pixels on the base substrate is overlapped with an orthographic projection of the corresponding pixel openings on the base substrate.

In an exemplary implementation, the pixel opening and the light-emitting layer are in a shape of a circle or an oval.

In an exemplary implementation, the first sub-pixel is a sub-pixel emitting red light, the second sub-pixel is a sub-pixel emitting blue light, and the third sub-pixel is a sub-pixel emitting green light.

In a second aspect, an embodiment of the present disclosure further provides a display apparatus, including the display substrate according to any one of the embodiments described above.

In a third aspect, an embodiment of the present disclosure further provides a display apparatus, including the above-described display substrate including first openings. The display apparatus further includes a photosensitive element, and an orthographic projection of the photosensitive element on the base substrate of the display substrate is within a range of an orthographic projection of the first opening of the display substrate on the base substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of embodiments of the present disclosure, constitute a portion of the specification, and are used for explaining the technical solutions of the present disclosure together with embodiments of the present disclosure, but do not constitute limitations on the technical solutions of the present disclosure. Shapes and sizes of each component in the drawings do not reflect actual scales, but are only intended to schematically illustrate contents of the present disclosure.

FIG. 1 is a schematic diagram of a structure of a display apparatus.

FIG. 2 is a schematic diagram of a structure of a display substrate.

FIG. 3 is a schematic diagram of a planar structure of a display area in a display substrate.

FIG. 4 is a schematic diagram of a sectional structure of a display area in a display substrate.

FIG. 5 is an equivalent circuit diagram of a pixel drive circuit.

FIG. 6 is a working timing diagram of a pixel drive circuit.

FIG. 7a is a schematic diagram of a structure of a display substrate according to an embodiment of the present disclosure.

FIG. 7b is a schematic diagram of a structure of a display substrate according to an embodiment of the present disclosure.

FIG. 7c is a schematic diagram of a planar structure of a pixel opening in a display substrate according to an exemplary embodiment of the present disclosure.

FIG. 8a is an equivalent circuit diagram of a pixel drive circuit according to an exemplary embodiment of the present disclosure.

FIG. 8b is a schematic diagram of an arrangement of circuit units according to an exemplary embodiment of the present disclosure.

FIG. 8c is a schematic diagram of an arrangement of light-emitting units according to an exemplary embodiment of the present disclosure.

FIG. 9 is a schematic diagram of a display substrate after a pattern of a shield layer is formed according to an exemplary embodiment of the present disclosure.

FIG. 10a is a schematic diagram of a display substrate after a pattern of a first semiconductor layer is formed according to an exemplary embodiment of the present disclosure.

FIG. 10b is a schematic diagram of a first semiconductor layer in a display substrate according to an exemplary embodiment of the present disclosure.

FIG. 11a is a schematic diagram of a display substrate after a pattern of a first conductive layer is formed according to an exemplary embodiment of the present disclosure.

FIG. 11b is a schematic diagram of a first conductive layer in a display substrate according to an exemplary embodiment of the present disclosure.

FIG. 12a is a schematic diagram of a display substrate after a pattern of a second conductive layer is formed according to an exemplary embodiment of the present disclosure.

FIG. 12b is a schematic diagram of a second conductive layer in a display substrate according to an exemplary embodiment of the present disclosure.

FIG. 13a is a schematic diagram of a display substrate after a pattern of a second semiconductor layer is formed according to an exemplary embodiment of the present disclosure.

FIG. 13b is a schematic diagram of a second semiconductor layer in a display substrate according to an exemplary embodiment of the present disclosure.

FIG. 14a is a schematic diagram of a display substrate after a pattern of a third conductive layer is formed according to an exemplary embodiment of the present disclosure.

FIG. 14b is a schematic diagram of a third conductive layer in a display substrate according to an exemplary embodiment of the present disclosure.

FIG. 15 is a schematic diagram of a display substrate after a pattern of a sixth insulation layer is formed according to an exemplary embodiment of the present disclosure.

FIG. 16a is a schematic diagram of a display substrate after a pattern of a fourth conductive layer is formed according to an exemplary embodiment of the present disclosure.

FIG. 16b is a schematic diagram of a fourth conductive layer in a display substrate according to an exemplary embodiment of the present disclosure.

FIG. 17 is a schematic diagram after a pattern of a first planarization layer is formed according to an exemplary embodiment of the present disclosure.

FIG. 18a is a schematic diagram of a display substrate after a pattern of a fifth conductive layer is formed according to an exemplary embodiment of the present disclosure.

FIG. 18b is a schematic diagram of a fifth conductive layer in a display substrate according to an exemplary embodiment of the present disclosure.

FIG. 18c is a schematic diagram of a display substrate after a pattern of a fifth conductive layer is formed according to an exemplary embodiment of the present disclosure.

FIG. 18d is a schematic diagram of a fifth conductive layer in a display substrate according to an exemplary embodiment of the present disclosure.

FIG. 19a is a schematic diagram of a display substrate after a pattern of a second planarization layer is formed according to an exemplary embodiment of the present disclosure.

FIG. 19b is a schematic diagram of a display substrate after a pattern of a second planarization layer is formed according to an exemplary embodiment of the present disclosure.

FIG. 20a is a schematic diagram of a display substrate according to an exemplary embodiment of the present disclosure after a pattern of an anode conductive layer is formed.

FIG. 20b is a schematic diagram of an anode conductive layer in a display substrate according to an exemplary embodiment of the present disclosure.

FIG. 20c is a schematic diagram of a display substrate after a pattern of an anode conductive layer is formed according to an exemplary embodiment of the present disclosure.

FIG. 20d shows a schematic diagram of an anode conductive layer in a display substrate according to an exemplary embodiment of the present disclosure.

FIG. 21a is a schematic diagram of a display substrate after a pattern of a pixel definition layer is formed according to an exemplary embodiment of the present disclosure.

FIG. 21b is a schematic diagram of a pattern of a pixel definition layer in a display substrate according to an exemplary embodiment of the present disclosure.

FIG. 21c is a schematic diagram of a display substrate according to an exemplary embodiment of the present disclosure after a pattern of a pixel definition layer is formed.

FIG. 21d is a schematic diagram of a pattern of a pixel definition layer in a display substrate according to an exemplary embodiment of the present disclosure.

FIG. 22a is a schematic diagram of a display substrate after a pattern of a light-emitting layer is formed according to an exemplary embodiment of the present disclosure.

FIG. 22b is a schematic diagram of a pattern of a light-emitting layer in a display substrate according to an exemplary embodiment of the present disclosure.

FIG. 23 shows a schematic diagram of a display substrate after a pattern of a shield layer is formed according to an exemplary embodiment of the present disclosure.

FIG. 24a shows a schematic diagram of a display substrate after a pattern of a first semiconductor layer is formed according to an exemplary embodiment of the present disclosure.

FIG. 24b shows a schematic diagram of a first semiconductor layer in a display substrate according to an exemplary embodiment of the present disclosure.

FIG. 25a shows a schematic diagram of a display substrate after a pattern of a first conductive layer is formed according to an exemplary embodiment of the present disclosure.

FIG. 25b shows a schematic diagram of a first conductive layer in a display substrate according to an exemplary embodiment of the present disclosure.

FIG. 26a shows a schematic diagram of a display substrate after a pattern of a second conductive layer is formed according to an exemplary embodiment of the present disclosure.

FIG. 26b shows a schematic diagram of a second conductive layer in a display substrate according to an exemplary embodiment of the present disclosure.

FIG. 27a shows a schematic diagram of a display substrate after a pattern of a second semiconductor layer is formed according to an exemplary embodiment of the present disclosure.

FIG. 27b shows a schematic diagram of a second semiconductor layer in a display substrate according to an exemplary embodiment of the present disclosure.

FIG. 28a shows a schematic diagram of a display substrate after a pattern of a third conductive layer is formed according to an exemplary embodiment of the present disclosure.

FIG. 28b shows a schematic diagram of a third conductive layer in a display substrate according to an exemplary embodiment of the present disclosure.

FIG. 29 shows a schematic diagram of a display substrate after a pattern of a sixth insulation layer is formed according to an exemplary embodiment of the present disclosure.

FIG. 30a shows a schematic diagram of a display substrate after a pattern of a fourth conductive layer is formed according to an exemplary embodiment of the present disclosure.

FIG. 30b shows a schematic diagram of a fourth conductive layer in a display substrate according to an exemplary embodiment of the present disclosure.

FIG. 31 shows a schematic diagram after a pattern of a first planarization layer is formed according to an exemplary embodiment of the present disclosure.

FIG. 32a shows a schematic diagram of a display substrate after a pattern of a fifth conductive layer is formed according to an exemplary embodiment of the present disclosure.

FIG. 32b shows a schematic diagram of a fifth conductive layer in a display substrate according to an exemplary embodiment of the present disclosure.

FIG. 33 shows a schematic diagram of a display substrate after a pattern of a second planarization layer is formed according to an exemplary embodiment of the present disclosure.

FIG. 34a shows a schematic diagram of a display substrate after a pattern of an anode conductive layer is formed according to an exemplary embodiment of the present disclosure.

FIG. 34b shows a schematic diagram of an anode conductive layer in a display substrate according to an exemplary embodiment of the present disclosure.

FIG. 35a is a schematic diagram of a display substrate after a pattern of a pixel definition layer is formed according to an exemplary embodiment of the present disclosure.

FIG. 35b is a schematic diagram of a pattern of a pixel definition layer in a display substrate according to an exemplary embodiment of the present disclosure.

FIG. 36a is a schematic diagram of a display substrate after a pattern of a light-emitting layer is formed according to an exemplary embodiment of the present disclosure.

FIG. 36b is a schematic diagram of a pattern of a light-emitting layer in a display substrate according to an exemplary embodiment of the present disclosure.

### DETAILED DESCRIPTION

The embodiments of the present disclosure will be described in detail hereinafter with reference to the drawings. Implementations may be implemented in a plurality of different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a thickness and a pitch of each film layer, and a width and a pitch of each signal line may be adjusted according to an actual situation. The drawings described in the present disclosure are only schematic diagrams of structures, and one implementation of the present disclosure is not limited to shapes or numerical values or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate according to a direction which is used for describing each constituent element. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification. In an embodiment of the present disclosure, the gate electrode may be referred to as a control electrode.

In the specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In an embodiment of the present disclosure, “about” refers to a value that is not strictly limited, a value within a range of process and measurement error is allowed.

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver respectively. The data driver is connected to a plurality of data signal lines (D1 to Dn) respectively. The scan driver is connected to a plurality of scan signal lines (S1 to Sm) respectively. The light emitting driver is connected to a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive the clock signal, the emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate the emission signal by sequentially transmitting the emission stop signal provided in a form of an off-level pulse to a next-stage circuit under control of the clock signal, wherein o may be a natural number.

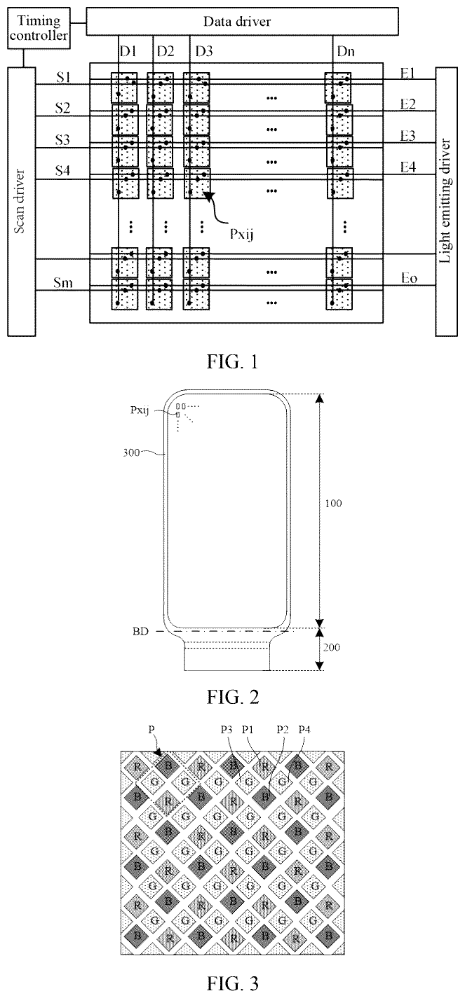

FIG. 2 is a schematic diagram of a structure of a display substrate. As shown in FIG. 2, the display substrate may include a display area 100, a bonding area 200 located on a side of the display area 100, and a bezel area 300 located on another side of the display area 100. In an exemplary implementation, the display area 100 may be a planar area including a plurality of sub-pixels Pxij that form a pixel array, the plurality of sub-pixels Pxij are configured to display a dynamic picture or a static image, and the display area 100 may be referred to as an Active Area (AA). In an exemplary implementation, the display substrate may be a flexible substrate, so that the display substrate may be deformable, for example, be curled, bent, folded, or rolled. In an exemplary implementation, the display substrate may further include a display area boundary BD, and the boundary BD may be an edge of the display area 100 at a side close to the bonding area 200.

In an exemplary implementation, the bonding area 200 may include a fanout region, a bending region, a drive chip region, and a bonding pin region disposed sequentially along a direction away from the display area. The fanout region is connected to the display area and includes a plurality of data fanout lines, and a data fanout line is configured to be connected to a data signal line (Data Line) of the display area in a fanout routing manner. The fanout region occupies relatively large space, resulting in a relatively large width of a lower bezel. The bending region is connected to the fanout region and may include a composite insulation layer provided with a groove, and is configured to enable the bonding area to be bent to a back of the display area. The drive chip region may include an integrated circuit (IC for short) and is configured to be connected to the plurality of data fanout lines. The bonding pin region may include a bonding pad, and is configured to be connected to an external flexible printed circuit board (FPC for short) by bonding.

In an exemplary implementation, the bezel area 300 may include a circuit region, a power supply line region, and a crack dam region, and a cutting region which are sequentially arranged along the direction away from the display area. The circuit region is connected to the display area and may at least include a gate drive circuit, and the gate drive circuit is connected to a first scan signal line, a second scan signal line, a third scan signal line, and a light emitting control line of a pixel drive circuit in the display area. The power supply line region is connected to the circuit region and may at least include a power supply lead line. The power supply lead line extends along a direction parallel to an edge of the display area and is connected to a cathode in the display area. The crack dam region is connected to the power supply line region and may at least include a plurality of cracks provided on the composite insulation layer. The cutting region is connected to the crack dam region and may at least include a cutting groove provided on the composite insulation layer, and the cutting groove is configured such that a cutting equipment can implement cutting along cutting grooves respectively after all film layers of the display substrate are manufactured.

In an exemplary implementation, the fanout region in the bonding area 200 and the power supply line region in the bezel area 300 may be provided with a first isolation dam and a second isolation dam. The first isolation dam and the second isolation dam may extend along the direction parallel to the edge of the display area, thus forming an annular structure surrounding the display area. The edge of the display area is an edge at a side of the display area, the bonding area, or the bezel area.

FIG. 3 is a schematic diagram of a planar structure of a display area in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 and a fourth sub-pixel P4 emitting light of a third color. Each sub-pixel may include a circuit unit and a light emitting device. The circuit unit may at least include a pixel drive circuit which is connected to a scan signal line, a data signal line, and a light emitting signal line respectively. The pixel drive circuit is configured to receive a data voltage transmitted by the data signal line and output a corresponding current to the light emitting device under control of the scan signal line and the light emitting signal line. The light emitting device in each sub-pixel is connected to a pixel drive circuit of a sub-pixel where the light emitting device is located, and is configured to emit light with corresponding brightness in response to a current output by the pixel drive circuit of the sub-pixel where the light emitting device is located.

In an exemplary implementation, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation, a sub-pixel may be in shape of a rectangle, a diamond, a pentagon, or a hexagon. The four sub-pixels may be arranged in a manner to form a diamond to form an RGBG pixel arrangement. In other exemplary implementations, the four sub-pixels may be arranged side by side horizontally, side by side vertically, or in a manner to form a square, which is not limited in the present disclosure.

In an exemplary implementation, a pixel unit may include three sub-pixels, and the three sub-pixels may be arranged side by side horizontally, side by side vertically, or in a delta-shaped arrangement, which is not limited here in the present disclosure.

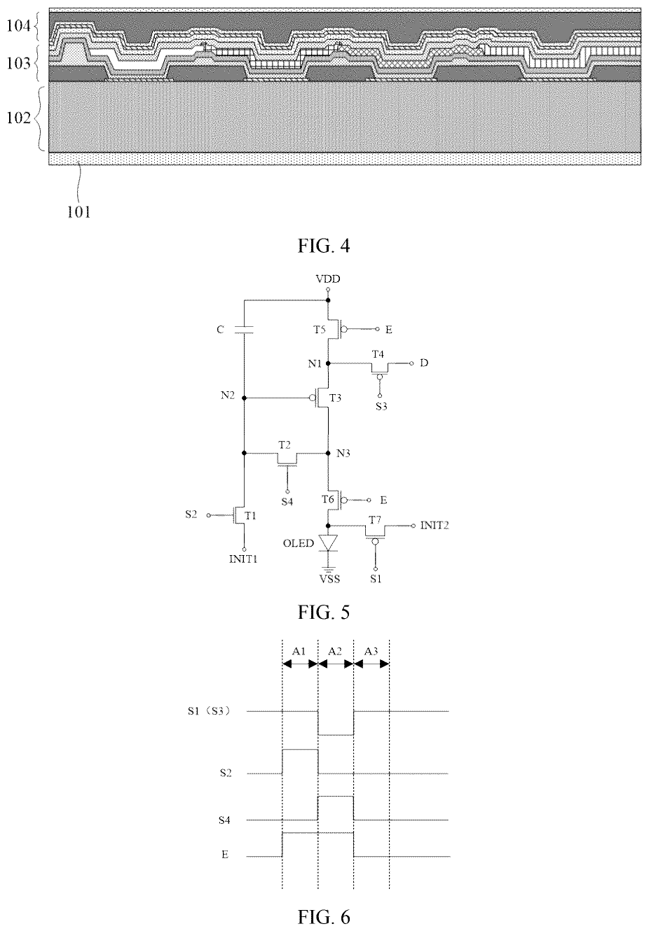

FIG. 4 is a schematic diagram of cross-sectional structure of a display area in a display substrate, illustrating a structure of four sub-pixels in the display area. As shown in FIG. 4, on a plane perpendicular to the display substrate, the display substrate may include a drive circuit layer 102 arranged on a base substrate 101, a light-emitting structure layer 103 arranged on a side of the drive circuit layer 102 away from the base substrate 101, and an encapsulation structure layer 104 arranged on a side of the light-emitting structure layer 103 away from the base substrate 101. In some possible implementations, the display substrate may include another film layer, such as a touch structure layer, which is not limited here in the present disclosure.

In an exemplary implementation, the base substrate 101 may be a flexible base substrate, or may be a rigid base substrate. The drive circuit layer 102 of each sub-pixel may include a pixel drive circuit composed of a plurality of transistors and a storage capacitor. The light emitting structure layer 103 of each sub-pixel may include a light emitting device formed by a plurality of film layers. The plurality of film layers may at least include an anode, a pixel definition layer, an organic emitting layer, and a cathode. The anode is connected to the pixel drive circuit, the organic emitting layer is connected to the anode, the cathode is connected to the organic emitting layer, and the organic emitting layer emits light of a corresponding color under drive of the anode and the cathode. The encapsulation structure layer 104 may include a first encapsulation structure layer, a second encapsulation structure layer, and a third encapsulation structure layer that are stacked. The first encapsulation structure layer and the third encapsulation structure layer may be made of an inorganic material, the second encapsulation structure layer may be made of an organic material, and the second encapsulation structure layer is arranged between the first encapsulation structure layer and the third encapsulation structure layer to form a laminated structure of inorganic material/organic material/inorganic material and ensure that external moisture cannot enter the light emitting structure layer 103.

In an exemplary implementation, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more layers of hole injection layers, hole transport layers, electron block layers, hole block layers, electron transport layers, and electron injection layers of all sub-pixels may be respectively connected together to be a common layer. Emitting layers of adjacent sub-pixels may be overlapped slightly, or may be mutually isolated.

FIG. 5 is an equivalent circuit diagram of a pixel drive circuit. In an exemplary implementation, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7) and one storage capacitor C, and the pixel drive circuit is respectively connected to ten signal lines (a data signal line D, a first scan signal line S1, a second scan signal line S2, a third scan signal line S3, a fourth scan signal line S4, a light emitting signal line E, a first initial signal line INIT1, a second initial signal line INIT2, a first power supply line VDD, and a second power supply line VSS).

In an exemplary implementation, the pixel drive circuit may include a first node N1, a second node N2, and a third node N3. Among them, the first node N1 is respectively connected to a first electrode of the third transistor T3, a second electrode of the fourth transistor T4, and a second electrode of the fifth transistor T5. The second node N2 is respectively connected to a second electrode of the first transistor T1, a control electrode of the third transistor T3, and a second end of the storage capacitor C. The third node N3 is respectively connected to a second electrode of the second transistor T2, a second electrode of the third transistor T3, and a first electrode of the sixth transistor T6.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

In an exemplary implementation, a control electrode of the first transistor Tl is connected to the second scan signal line S2, a first electrode of the first transistor Tl is connected to the first initial signal line INIT1, and the second electrode of the first transistor Tl is connected to the second node N2. When a turned-on scan signal is applied to the second scan signal line S2, the first transistor T1 transmits a first initialization voltage to the second end of the storage capacitor C to initialize the storage capacitor C.

In an exemplary implementation, a control electrode of the second transistor T2 is connected to the fourth scan signal line S4, a first electrode of the second transistor T2 is connected to the second electrode of the first transistor T1, and the second electrode of the second transistor T2 is connected to the third node N3. When a turned-on scan signal is applied to the fourth scan signal line S4, the second transistor T2 enables the control electrode of the third transistor T3 to be connected to the second electrode of the third transistor T3.

In an exemplary implementation, the control electrode of the third transistor T3 is connected to the second node N2, that is, the control electrode of the third transistor T3 is connected to the second end of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines a magnitude of a drive current flowing between the first power supply line VDD and a light emitting device according to a potential difference between the control electrode and the first electrode of the third transistor T3.

In an exemplary implementation, a control electrode of the fourth transistor T4 is connected to the third scan signal line S3, a first electrode of the fourth transistor T4 is connected to the data signal line D, and the second electrode of the fourth transistor T4 is connected to the first node N1. When a turned-on scan signal is applied to the third scan signal line S3, the fourth transistor T4 enables a data voltage of the data signal line D to be input to the first node N1.

In an exemplary implementation, a control electrode of the fifth transistor T5 is connected to the light emitting signal line E, a first electrode of the fifth transistor T5 is connected to the first power supply line VDD, and the second electrode of the fifth transistor T5 is connected to the first node N1. A control electrode of the sixth transistor T6 is connected to the light emitting signal line E, the first electrode of the sixth transistor T6 is connected to the third node N3, and a second electrode of the sixth transistor T6 is connected to a first electrode of a light emitting device. When a turned-on light emitting signal is applied to the light emitting signal line E, the fifth transistor T5 and the sixth transistor T6 enable the light emitting device to emit light by forming a drive current path between the first power supply line VDD and the light emitting device.

In an exemplary implementation, a control electrode of the seventh transistor T7 is connected to the first scan signal line S1, a first electrode of the seventh transistor T7 is connected to the second initial signal line INIT2, and a second electrode of the seventh transistor T7 is connected to the first electrode of the light emitting device. When a turned-on scan signal is applied to the first scan signal line S1, the seventh transistor T7 transmits a second initial voltage to the first electrode of the light emitting device so as to initialize a charge amount accumulated in the first electrode of the light emitting device or release a charge amount accumulated in the first electrode of the light emitting device.

In an exemplary implementation, the light emitting device may be an OLED including a first electrode (anode), an organic emitting layer, and a second electrode (cathode) which are stacked, or may be a QLED including a first electrode (anode), a quantum dot emitting layer, and a second electrode (cathode) which are stacked.

In an exemplary implementation, a second electrode of the light emitting device is connected to the second power supply line VSS, a signal of the second power supply line VSS is a low-level signal, and a signal of the first power supply line VDD is a high-level signal continuously provided.

In an exemplary implementation, the first transistor T1 to the seventh transistor T7 may be P-type transistors or N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first transistor T1 to the seventh transistor T7 may be low-temperature polysilicon transistors, or may be oxide transistors, or may be low-temperature polysilicon transistors and metal oxide transistors. Low Temperature Poly-Silicon (LTPS for short) is adopted for an active layer of a low temperature polysilicon transistor and a metal oxide semiconductor is adopted for an active layer of a metal oxide transistor. A low temperature polysilicon transistor has advantages such as a high migration rate and fast charging, and an oxide transistor has advantages such as a low drain current. The low temperature polysilicon transistor and the metal oxide transistor are integrated on one display substrate to form a Low Temperature Poly-Silicon+Oxide (LTPO) display substrate, such that advantages of the low temperature polysilicon transistor and the metal oxide transistor may be utilized, low-frequency driving may be achieved, power consumption may be reduced, and display quality may be improved.

FIG. 6 is a working timing diagram of a pixel drive circuit. An exemplary embodiment of the present disclosure will be described below through a working process of the pixel drive circuit exemplified in FIG. 5. The pixel drive circuit in FIG. 5 includes seven transistors (a first transistor T1 to a seventh transistor T7) and one storage capacitor C. The first transistor T1 and the second transistor T2 are N-type oxide transistors, and the third transistor T3 to the seven transistor T7 are P-type low-temperature polysilicon transistors. In an exemplary implementation, a working process of the pixel drive circuit may include following stages.

In a first stage A1, which is referred to as a reset stage, a signal of the second scan signal line S2 is a turned-on signal (high-level), and signals of the first scan signal line S1, the third scan signal line S3, the fourth scan signal line S4, and the light emitting signal line E are turned-off signals. The turned-on signal of the second scan signal line S2 enables the first transistor T1 to be turned on, and a signal of the first initial signal line INIT1 is provided to the second node N2 through the first transistor T1 to initialize (reset) the storage capacitor C, thereby clearing original charges in the storage capacitor. The turned-off signals of the first scan signal line S1, the third scan signal line S3, the fourth scan signal line S4, and the light emitting signal line E enable the second transistor T2, the fourth transistor T4, the fifth transistor T5, the sixth transistor T6, and the seventh transistor T7 to be turned off, and an OLED does not emit light in this stage.

In a second stage A2, which is referred to as a data writing stage or a threshold compensation stage, signals of the first scan signal line S1, the third scan signal line S3, and the fourth scan signal line S4 are turned-on signals, signals of the second scan signal line S2 and the light emitting signal line E are turned-off signals, and the data signal line D outputs a data voltage. In this stage, the second end of the storage capacitor C is at a low level, so the third transistor T3 is turned on. The turned-on signals of the first scan signal line S1, the third scan signal line S3, and the fourth scan signal line S4 enable the second transistor T2, the fourth transistor T4, and the seventh transistor T7 to be turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, herein Vd is the data voltage output by the data signal line D, and Vth is the threshold voltage of the third transistor T3. The seventh transistor T7 is turned on, so that a signal of the second initial signal line INIT2 is provided to a first electrode of the OLED to initialize (reset) the first electrode of the OLED and clear its internal pre-stored voltage, thereby completing initialization and ensuring that the OLED does not emit light. A turned-off signal of the second scan signal line S2 enables the first transistor T1 to be turned off, and a turned-off signal of the light emitting signal line E enables the fifth transistor T5 and the sixth transistor T6 to be turned off.

In a third stage A3, which is referred to as a light emitting stage, a signal of the light emitting signal line E is a turned-on signal, and signals of the first scan signal line S1, the second scan signal line S2, the third scan signal line S3, and the fourth scan signal line S4 are turned-off signals. The turned-on signal of the light emitting signal line E enables the fifth transistor T5 and the sixth transistor T6 to be turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata−|Vth|, so the driving current of the third transistor T3 is as follows:

I=K*(Vgs−Vth)²=K*[(Vdd−Vd+|Vth|)−Vth]²=K*[(Vdd−Vd)]²

Herein, I is a driving current flowing through the third transistor T3, i.e., a driving current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

For a display panel, polarizer-less (POL-Less) technology refers to a technology of replacing a conventional polarizers in a display panel with color films or color filters, which has advantages of improving light transmittance of the display panel, reducing the working power consumption of the display panel, making the display panel thinner, etc.

At present, the common POL-Less technology includes a color on encapsulation (COE) technology in which a color filter (CF) is integrated in an encapsulation layer, and an OLED display panel using the COE technology can be called a COE panel. The COE panel generally includes: a base substrate, and a pixel circuit layer, a pixel defining layer (which may be referred to as a pixel definition layer), an encapsulation layer and a black matrix layer located on one side of the base substrate and stacked in this order. The pixel defining layer is used for spacing light-emitting elements of different colors apart from each other. The black matrix layer is configured to space CFs corresponding to light-emitting elements of different colors apart from each other. The pixel circuit layer is configured to drive the light-emitting elements to emit light, and light emitted by the light-emitting elements can be emitted after being filtered by the color CFs, so that a COE panel displays a color picture.

In a COE panel, most of the sub-pixels are rectangular or square, and rectangular or square sub-pixels will easily cause problems of color separation, color cast and poor uniformity of the COE display panel, and in a COE panel in which photosensitive elements (sensors) are integrated, openings for arranging the photosensitive elements are small, resulting in a low transmittance of the photosensitive elements. In addition, since an arrangement of Real RGB is employed for some of the pixels in the current COE panel, the same sub-pixels are not on a same straight line, resulting in a sense of jagging in display.

An exemplary embodiment of the present disclosure provides a display substrate, which may include a base substrate, and a plurality of sub-pixels, a drive circuit layer and a pixel definition layer disposed on the base substrate. In a direction perpendicular to a plane of the display substrate, the drive circuit layer may be located between the base substrate and the pixel definition layer, a plurality of pixel openings are formed in the pixel definition layer, and each sub-pixel may include at least one pixel opening;
the plurality of sub-pixels may include a plurality of types of sub-pixels, the plurality of types of sub-pixels at least include a first sub-pixel and a second sub-pixel, an area of a pixel opening of the first sub-pixel is smaller than an area of a pixel opening of the second sub-pixel, the pixel opening of the first sub-pixel and the pixel opening of the second sub-pixel overlap with at least one conductive layer in the drive circuit layer, and an overlapping area of the pixel opening of the first sub-pixel with the at least one conductive layer is larger than an overlapping area of the pixel opening of the second sub-pixel with the at least one conductive layer.

In the display substrate according to the embodiment of the present disclosure, the area of the pixel opening of the first sub-pixel in the display substrate is smaller than the area of the pixel opening of the second sub-pixel, and the overlapping area of the pixel opening of the first sub-pixel with the at least one conductive layer is larger than the overlapping area of the pixel opening of the second sub-pixel with the at least one conductive layer, which can solve the problems of color separation, color cast and poor uniformity in the display panel.

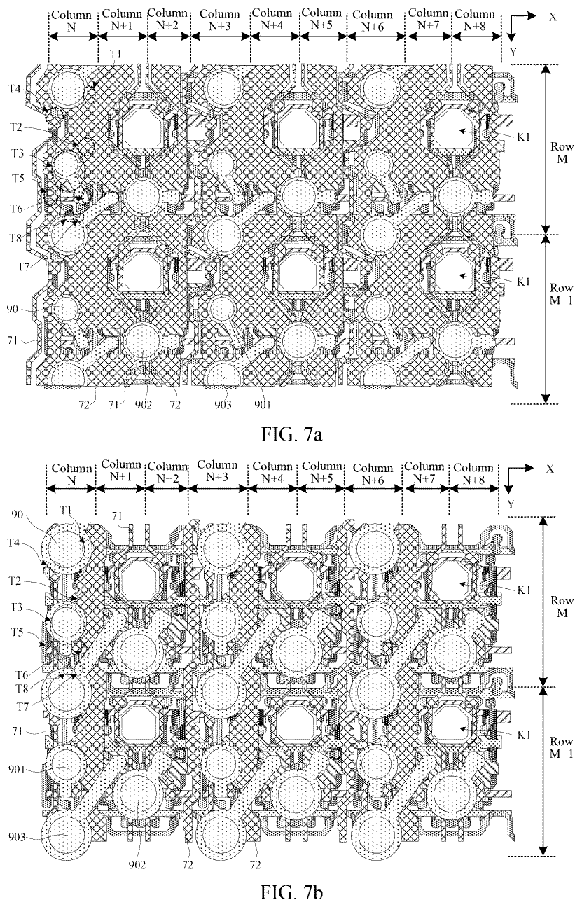

As shown in FIGS. 7a to 7c, the display substrate according to an embodiment of the present disclosure may include a base substrate, and a plurality of sub-pixels, a drive circuit layer and a pixel definition layer disposed on the base substrate. In a direction perpendicular to a plane of the display substrate, the drive circuit layer is located between the base substrate and the pixel definition layer, a plurality of pixel openings are formed in the pixel definition layer, and each sub-pixel includes at least one pixel opening 90;
the plurality of sub-pixels include a plurality of types of sub-pixels, the plurality of types of sub-pixels at least include a first sub-pixel and a second sub-pixel, an area of a pixel opening 901 of the first sub-pixel is smaller than an area of a pixel opening 902 of the second sub-pixel, the pixel opening 901 of the first sub-pixel and the pixel opening 902 of the second sub-pixel overlap with at least one conductive layer in the drive circuit layer, and an overlapping area of the pixel opening 901 of the first sub-pixel with the at least one conductive layer is larger than an overlapping area of the pixel opening 902 of the second sub-pixel with the at least one conductive layer.

In an exemplary implementation, as shown in FIGS. 7a to 7c, the plurality of types of sub-pixels may further include a third sub-pixel, the area of the pixel opening 901 of the first sub-pixel is smaller than an area of a pixel opening 903 of the third sub-pixel, and an overlapping area of the pixel opening 903 of the third sub-pixel with the at least one conductive layer is larger than the overlapping area of the pixel opening 902 of the second sub-pixel with the at least one conductive layer.

In an exemplary implementation, orthographic projections of the pixel opening 901 of the first sub-pixel and the pixel opening 903 of the third sub-pixel on the base substrate are within a range of an orthographic projection of the at least one conductive layer on the base substrate.

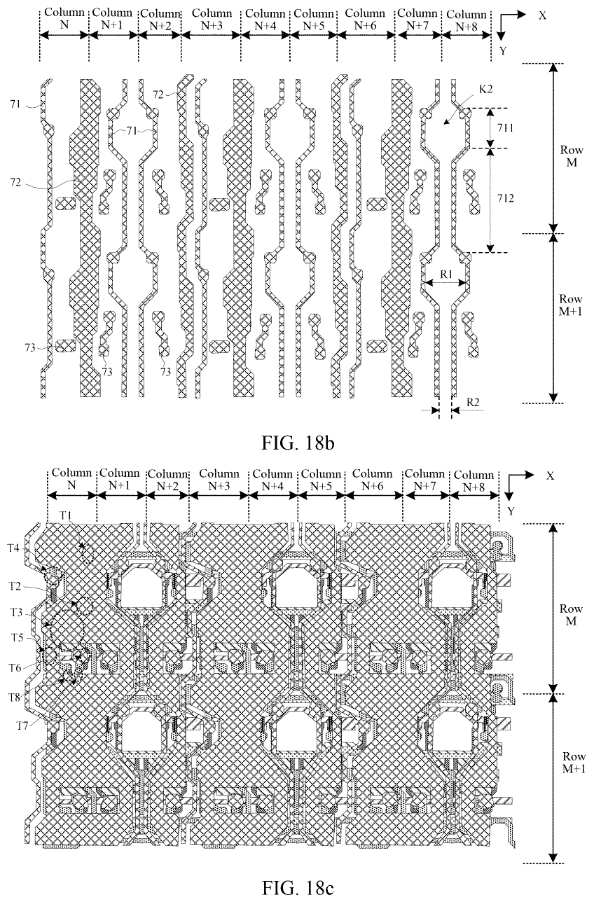

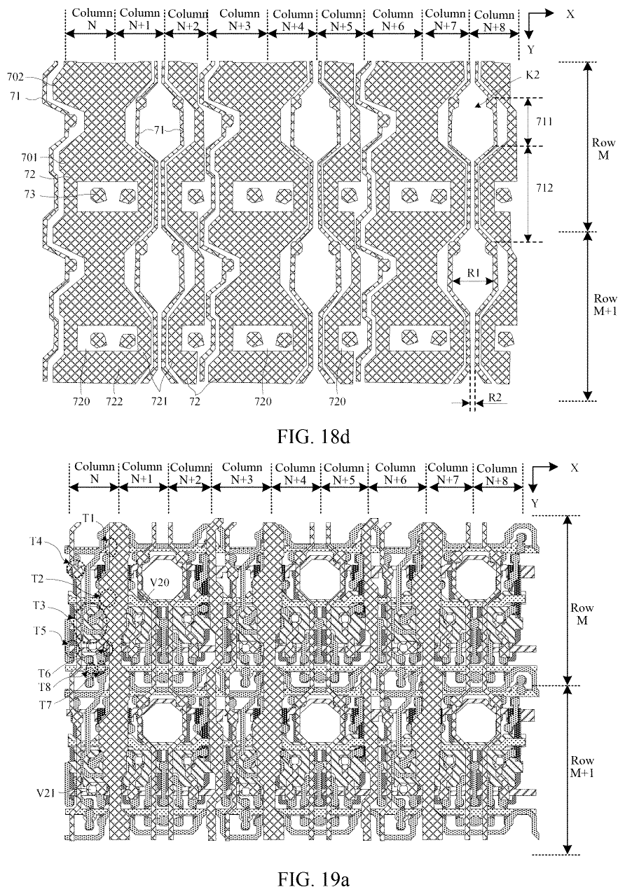

In an exemplary implementation, the at least one conductive layer may include a first protrusion and a second protrusion, the orthographic projection of the pixel opening 901 of the first sub-pixel on the base substrate is within a range of an orthographic projection of the first protrusion on the base substrate, and the orthographic projection of the pixel opening 903 of the third sub-pixel on the base substrate is within a range of an orthographic projection of the second protrusion on the base substrate. As shown in FIG. 18d, at least part of conductive layer may include a fifth conductive layer, the fifth conductive layer may include a first power supply line 72, and the first power supply line 72 may include a first protrusion 701 and a second protrusion 702. The orthographic projection of the pixel opening 901 of the first sub-pixel on the base substrate is within the range of the orthographic projection of the first protrusion on the base substrate, and the orthographic projection of the pixel opening 903 of the third sub-pixel on the base substrate is within the range of the orthographic projection of the second protrusion on the base substrate. In an embodiment of the present disclosure, the first protrusion 701 and the second protrusion 702 can make the anode of the first sub-pixel and the anode of the third sub-pixel be at a same height, thereby improving flatness of the anodes of the first sub-pixel and the third sub-pixel, and improving the problems of color separation and color cast of the COE panel.

In an exemplary implementation, as shown in FIGS. 7a and 7b, the pixel opening 902 of the second sub-pixel overlaps with patterns of at least two portions of signal lines in at least one conductive layer, and the patterns of at least two portions of signal lines are distributed on two sides of a center of the pixel opening 902 of the second sub-pixel, so that flatness of anodes in each area in one second sub-pixel can be as consistent as possible, and flatness of anodes of a plurality of second sub-pixels can be as consistent as possible, thereby improving display uniformity of the display substrate.

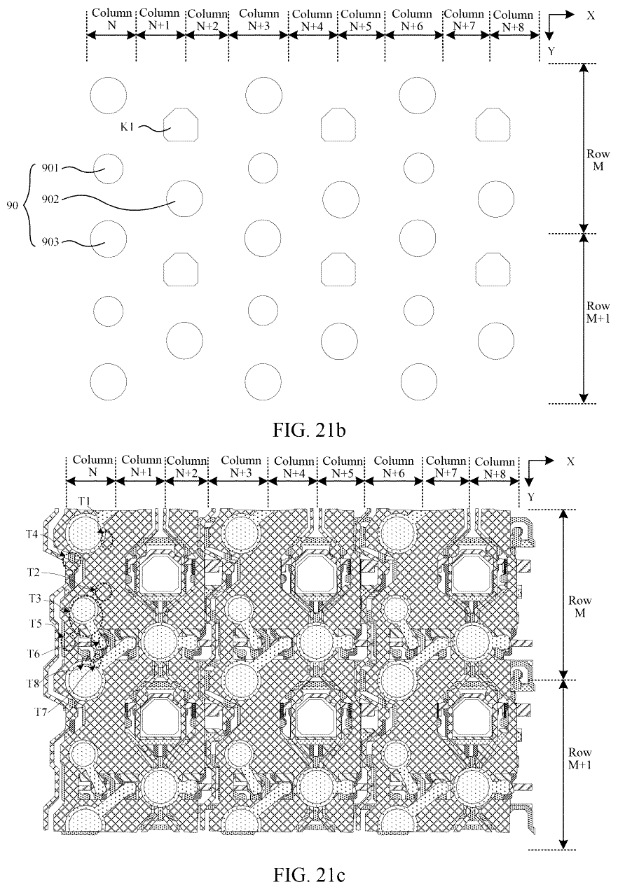

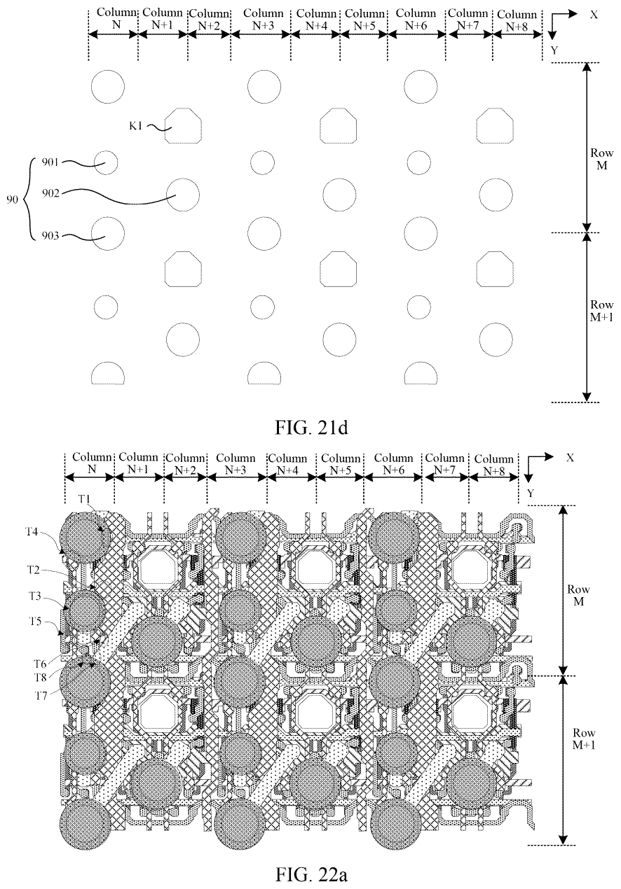

In an exemplary implementation, as shown in FIGS. 7a, 7b, 21b and 21d, the pixel opening 901 of the first sub-pixel and the pixel opening 903 of the third sub-pixel may be arranged in a column direction Y, main body portions of the signal lines in the patterns of at least two portions of signal lines extend in the column direction Y, as shown in FIGS. 18b and 18d. The patterns of at least two portions of signal lines of the at least one conductive layer in the drive circuit layer may include a data signal line 71. A main body portion of the data signal line 71 may extend in the column direction Y, and in the column direction Y, two data signal lines 71 may be distributed on two sides of the center of the pixel opening 902 of the second sub-pixel (i.e., in the column direction Y, an overlapping area of two data signal lines 71 with the pixel opening 902 of the second sub-pixel may be symmetrical with respect to a centerline of the pixel opening 902 of the second sub-pixel extending in the column direction Y). In the row direction X, any data signal line 71 may be distributed on two sides of the center of the pixel opening 902 of the second sub-pixel (i.e., in the row direction X, an overlapping area of a same data signal line 71 with the pixel opening 902 of the second sub-pixel may be symmetrical with respect to a centerline of the pixel opening 902 of the second sub-pixel extending in the row direction X).

In an exemplary implementation, as shown in FIG. 18b, the patterns of at least two portions of signal lines may further include a first power supply line 72, in the column direction Y, two first power supply lines 72 may be distributed on two sides of the center of the pixel opening 902 of the second sub-pixel (i.e., in the column direction Y, an overlapping area of two first power supply lines 72 with the pixel opening 902 of the second sub-pixel may be symmetrical with respect to the centerline of the pixel opening 902 of the second sub-pixel extending in the column direction Y), and in the row direction X, any first power supply line 72 may be distributed on two sides of the center of the pixel opening 902 of the second sub-pixel (i.e., in the row direction X, an overlapping area of a same first power supply line 72 with the pixel opening 902 of the second sub-pixel may be symmetrical with respect to the centerline of the pixel opening 902 of the second sub-pixel extending in the row direction X).

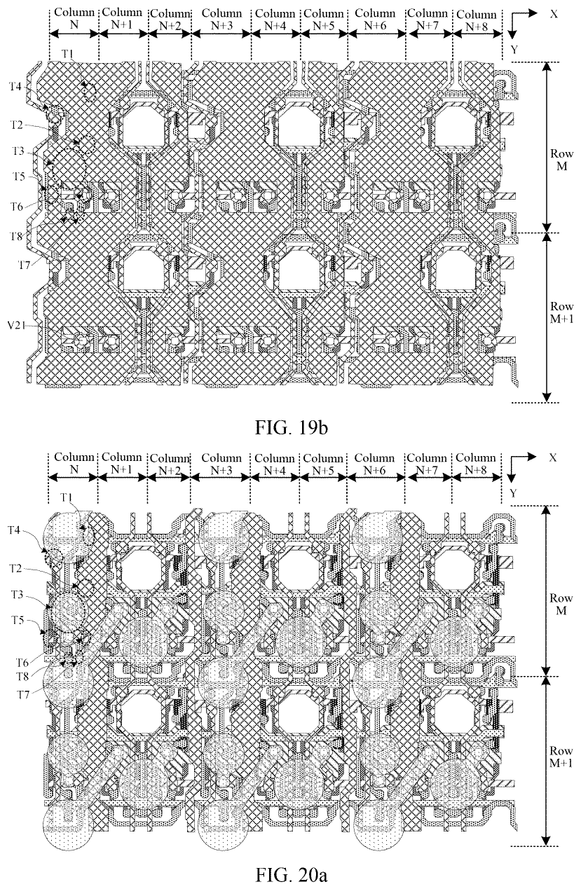

In an exemplary implementation, as shown in FIGS. 18d and 19b, the display substrate may further include an anode via V21 and an anode connection electrode 73, the patterns of at least two portions of signal lines include a proximal portion and a distal portion relative to the pixel opening 902 of the second sub-pixel. The pixel opening 902 of the second sub-pixel overlaps with the proximal portion, a hollow structure is provided in the middle of the distal portion, and the hollow structure is configured to accommodate the anode connection electrode 73. An orthographic projection of the anode connection electrode 73 on the base substrate is overlapped with an orthographic projection of a corresponding hollow structure on the base substrate, and an orthographic projection of the anode via V21 on the base substrate is overlapped with an orthographic projection of a corresponding anode connection electrode 73 on the base substrate. For example, as shown in FIGS. 18d and 19b, the first power supply line 72 may include a proximal portion 721 and a distal portion 722 relative to the pixel opening 902 of the second sub-pixel, the pixel opening 902 of the second sub-pixel overlaps with the proximal portion 721 of the first power supply line 72, a hollow structure 720 may be disposed in the middle of the distal portion 722, the hollow structure 720 is configured to accommodate the anode connection electrode 73, and an orthographic projection of the anode connection electrode 73 on the base substrate is overlapped with an orthographic projection of the corresponding hollow structure 720 on the base substrate. In an exemplary implementation, the orthographic projection of the anode connection electrode 73 on the base substrate is within a range of the orthographic projection of the corresponding hollow structure 720 on the base substrate, and the orthographic projection of the anode via V21 on the base substrate is within the range of the orthographic projection of the corresponding anode connection electrode 73 on the base substrate.

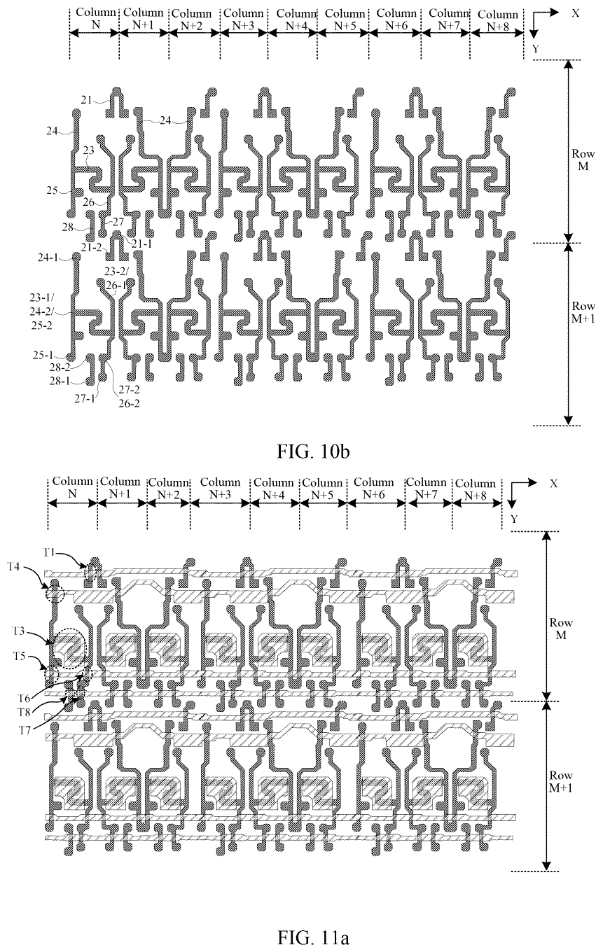

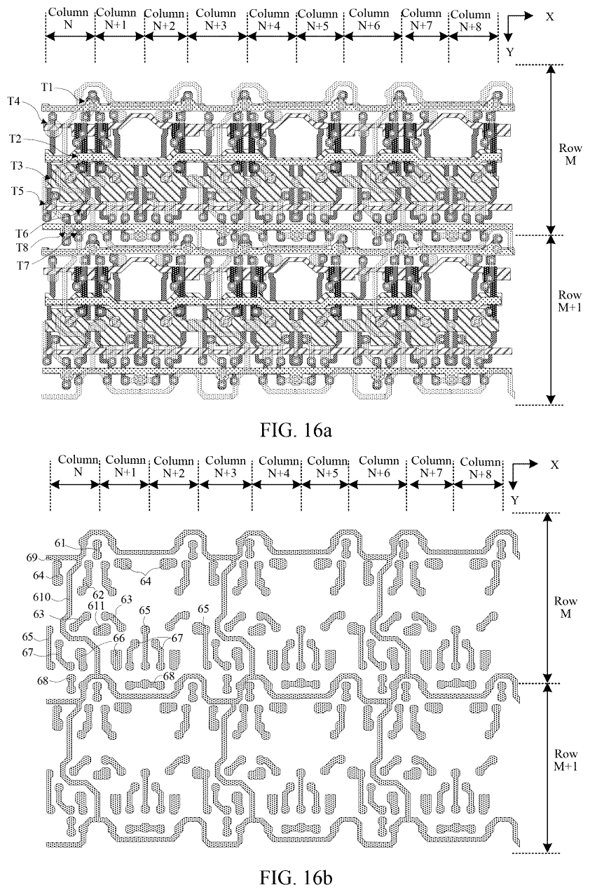

In an exemplary implementation, as shown in FIGS. 7a and 7b, the pixel opening 902 of the second sub-pixel may also overlap with at least part of signal wires other than the patterns of at least two portions of signal lines in the drive circuit layer, and the at least part of signal wires located on two sides of the center of the pixel opening 902 of the second sub-pixel have a same overlapping area so as to improve flatness of the anode of the second sub-pixel, thereby improving the display uniformity of the display substrate. For example, as shown in FIGS. 16a and 16b, the at least part of signal wires may include a fifth connection electrode 65 (which may serve as a first electrode of a fifth transistor T5) and a seventh connection electrode 67 (which may serve as a second electrode of the fifth transistor T5). As shown in FIG. 10b, the at least part of signal wires may further include an active layer 25 of the fifth transistor T5.

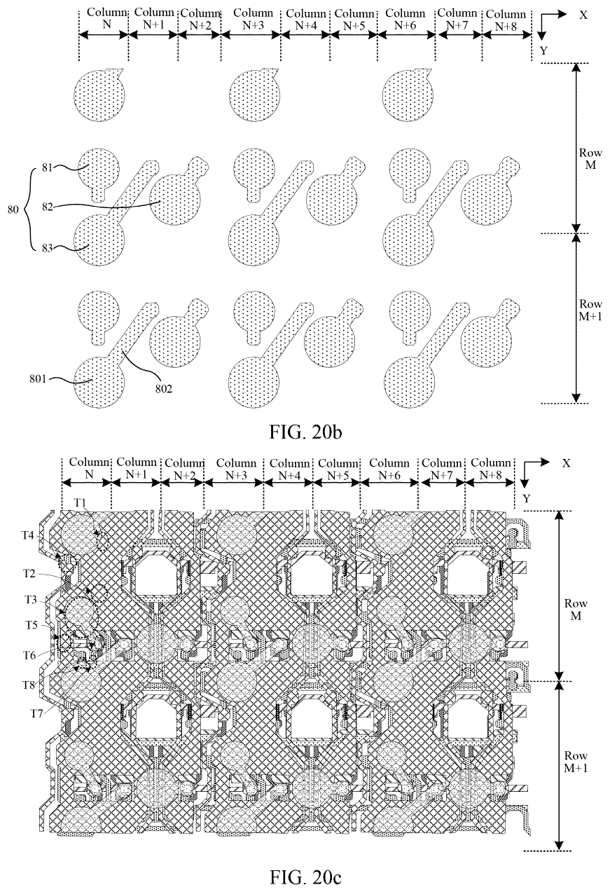

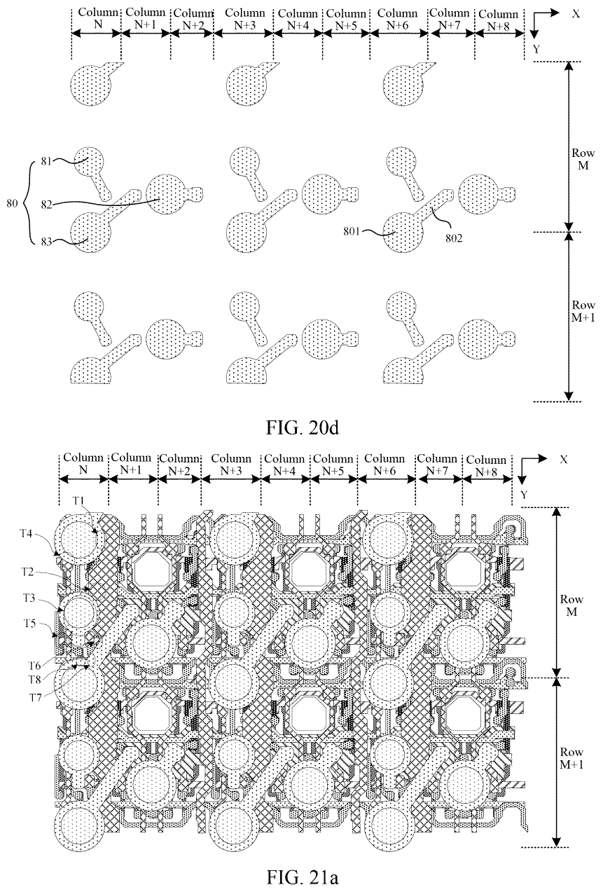

In an exemplary implementation, as shown in FIGS. 20a to 20d, the display substrate may further include an anode conductive layer, in a direction perpendicular to the plane of the display substrate, the anode conductive layer may be located between the drive circuit layer and the pixel definition layer, and at least part of conductive layer includes a conductive layer closest to the anode conductive layer in the drive circuit layer. For example, at least part of conductive layer may include a fifth conductive layer (which may be referred to as a second source-drain metal layer) as shown in FIG. 18b or FIG. 18d in the drive circuit layer. In an embodiment of the present disclosure, the at least part of conductive layer includes a conductive layer closest to the anode conductive layer in the drive circuit layer, which enables patterns of a plurality of signal lines overlapped with anodes in the conductive layer closest to the anode conductive layer to have a same influence on the plurality of anodes, thereby improving the display uniformity of the display substrate.

In an exemplary implementation, as shown in FIGS. 7a to 7c, pixel openings of a plurality of same type sub-pixels are arranged in the row direction X and the column direction Y, and centers of pixel openings 90 of a plurality of a same type of sub-pixels located in a same row are on a same straight line.

In an embodiment of the present disclosure, pixel openings of a plurality of same type sub-pixels in the display substrate are arranged in the row direction and the column direction, and centers of the pixel openings of a plurality of a same type of sub-pixels located in a same row are on a same straight line, thereby greatly reducing a sense of jagging of display and improving display effect.

As shown in FIG. 7c, centers of pixel openings 901 of a plurality of first sub-pixels located in a same row are on a same straight line Q1-Q1 (horizontal straight line Q1-Q1), centers of pixel openings 902 of a plurality of second sub-pixels located in a same row are on a same straight line Q2-Q2 (horizontal straight line Q2-Q2), and centers of pixel openings 903 of a plurality of third sub-pixels located in a same row are on a same straight line Q3-Q3 (horizontal straight line Q3-Q3). The centers of the pixel openings of a plurality of same type of sub-pixels located in a same row are on a same straight line, which greatly reduces a sense of jagging during displaying and improves the display effect.

In an exemplary implementation, as shown in FIGS. 7a to 7c, pixel openings 90 of a plurality of a same type of sub-pixels form M rows and N columns, where M and N are positive integers greater than 1. Among the pixel openings 90 of the plurality of the same type of sub-pixels in the M rows and N columns, a center of the pixel opening of the sub-pixel located in row i and column j is on a same straight line as centers of the pixel openings 90 of the sub-pixels located in row i+1 and column j+1 and in row i+2 and column j+2, where i is a positive integer greater than 1 and smaller than or equal to M, and j is a positive integer greater than 1 and smaller than or equal to N. As shown in FIG. 7c, the center of the pixel opening 901 of the first sub-pixel located in row i and column j is on the same straight line Q1-Q1 (inclined straight line Q1-Q1) as the centers of the pixel openings 901 of the first sub-pixels located in row i+1 and column j+1 and in row i+2 and column j+2. A center of the pixel opening 902 of the second sub-pixel located in row i and column j is on a same straight line Q2-Q2 (inclined straight line Q2-Q2) as centers of the pixel openings 902 of the second sub-pixels located in row i+1 and column j+1 and in row i+2 and column j+2. A center of the pixel opening 903 of the third sub-pixel located in row i and column j is on a same straight line Q3-Q3 (inclined straight line Q3-Q3) as centers of the pixel openings 903 of the third sub-pixels located in row i+1 and column j+1 and in row i+2 and column j+2.

In an exemplary implementation, as shown in FIG. 7c, among the pixel openings of the plurality of the same type sub-pixels in the M rows and N columns, a centerline of the pixel opening of the sub-pixel located in row i and column j+2 is on a same straight line as centerlines of the pixel openings of the sub-pixels located in row i+1 and column j+1 and in row i+2 and column j. As shown in FIG. 7c, a centerline of the pixel opening 901 of the first sub-pixel located in row i and column j+2 is on the same straight line Q1-Q1 (inclined straight line Q1-Q1) as centerlines of the pixel openings 901 of the first sub-pixels located in row i+1 and column j+1 and row i+2 and column j. A centerline of the pixel opening 902 of the second sub-pixel located in row i and column j+2 is on the same straight line Q2-Q2 (inclined straight line Q2-Q2) as centerlines of the pixel openings 902 of the second sub-pixels located in row i+1 and column j+1 and row i+2 and column j. A centerline of the pixel opening 903 of the third sub-pixel located in row i and column j+2 is on the same straight line Q3-Q3 (inclined straight line Q3-Q3) as centerlines of the pixel openings 903 of the third sub-pixels located in row i+1 and column j+1 and row i+2 and column j.

In an exemplary implementation, as shown in FIGS. 7a to 7c, the at least one conductive layer may include a plurality of data signal lines 71, and the main body portions of the data signal lines 71 extend in the column direction Y. The pixel definition layer is further formed with a plurality of first openings K1 arranged in an array, and orthographic projections of the first openings K1 on the base substrate do not overlap with an orthographic projection of the data signal lines 71 on the base substrate.

In an exemplary implementation, as shown in FIGS. 7a to 7c, the first openings K1 and the pixel openings 902 of the second sub-pixels are alternately arranged in the column direction Y. In an embodiment of the present disclosure, in the column direction Y, a first opening K1 (the first opening K1 can accommodate a photosensitive element or a shield structure) is provided between pixel openings 902 of two adjacent second sub-pixels, which can be improve transmittance of a photosensitive element in a COE panel in which the photosensitive element is integrated.

In an exemplary implementation, as shown in FIGS. 7a to 7c, in the column direction Y, the pixel openings 901 of the first sub-pixels and the pixel openings 903 of the third sub-pixels are alternately arranged, the pixel openings 902 of the second sub-pixels and the first opening K1 are located between the pixel openings 901 of the first sub-pixels and the pixel openings 903 of the third sub-pixels in adjacent columns, and the pixel openings 901 of the first sub-pixels and the pixel openings 903 of the third sub-pixels are located between the first openings K1 and the pixel openings 902 of the second sub-pixels in adjacent columns.

In an exemplary implementation, as shown in FIGS. 7a to 7c, in the row direction X, a pixel opening 901 of a first sub-pixel and a pixel opening 903 of a third sub-pixel may be located between two first openings K1 in adjacent rows and pixel openings 902 of two second sub-pixels in adjacent rows, and a pixel opening 902 of a second sub-pixel and a first opening K1 may be located between pixel openings 901 of two first sub-pixels in adjacent rows and pixel openings 903 of two third sub-pixels in adjacent rows.

In an exemplary implementation, as shown in FIGS. 7a, 7b, 18b, 18d, 20b and 20d, the display substrate may further include an anode conductive layer, and the at least one conductive layer may include a fifth conductive layer. On a plane perpendicular to the display substrate, the anode conductive layer is located between the fifth conductive layer and the pixel definition layer, the anode conductive layer may include an anode 82 of a second sub-pixel, there is a first overlapping area between an orthographic projection of the fifth conductive layer on the base substrate and orthographic projections of the pixel opening 902 of the second sub-pixel and the anode 82 of the second sub-pixel on the base substrate, and on a plane parallel to the display substrate, the first overlapping area is symmetrical with respect to centerlines of the pixel opening 902 of the second sub-pixel in the row direction X and the column direction Y.

In an exemplary implementation, as shown in FIGS. 7a, 18c and 18d, the anode conductive layer may further include an anode 81 of a first sub-pixel and an anode 83 of a third sub-pixel, the fifth conductive layer may include a plurality of first power supply lines 72. Main body portions of the first power supply lines 72 extend in the column direction Y, and orthographic projections of the pixel opening 901 and the anode 81 of the first sub-pixel and the pixel opening 903 and the anode 83 of the third sub-pixel on the base substrate are within a range of an orthographic projection of the first power supply lines 72 on the base substrate.

In an exemplary implementation, the first sub-pixel may be a sub-pixel emitting red light, the second sub-pixel may be a sub-pixel emitting blue light, and the third sub-pixel may be a sub-pixel emitting green light.

In an embodiment of the present disclosure, the orthographic projections of the anode 81 of the first sub-pixel and the anode 83 of the third sub-pixel on the base substrate are within the range of the orthographic projections of the first power supply lines 72 on the base substrate, which can improve flatness of the anodes of the first sub-pixel 81 and the third sub-pixel 83, thereby improving the color separation phenomenon of a COE panel and improving of color cast and uniformity in all directions in a bright state of the display substrate.

In an exemplary implementation, as shown in FIG. 7a, in the row direction, the first opening K1 may be located between two adjacent data signal lines 71, and the two data signal lines 71 located on two sides of the first opening K1 are symmetrically disposed with respect to a centerline, extending in the column direction Y, of a pixel opening 902 of a second sub-pixel in a column where the first opening K1 is located.

In an exemplary implementation, as shown in FIGS. 7a and 7b, at least one sub-pixel includes a pixel drive circuit, the pixel drive circuit includes a plurality of transistors, and the plurality of transistors include a drive transistor and a fourth transistor T4. A second electrode of the fourth transistor T4 is electrically connected to a first electrode of the drive transistor T3, the fourth transistor T4 is configured to provide a data signal to the drive transistor T3. As shown in FIGS. 18b and 18d, data signal lines 71 located on two sides of the first opening K1 in the row direction X may each include a first portion 711 and a second portion 712 which are integrally formed. The first portion 711 extends in the column direction Y, the second portion 712 is a bent structure, and orthographic projections of a channel region and a first region of the fourth transistor T4 on the base substrate overlap with an orthographic projection of the first portion 711 on the base substrate. The first portions 711 of the two data signal lines 71 located on two sides of the first opening K1 in the row direction X form a second opening K2, and an orthographic projection of the first opening K1 on the base substrate is within a range of an orthographic projection of the second opening K2 on the base substrate, so as to prevent the data signal lines 71 from shielding the first opening K1.

In an exemplary implementation, as shown in FIGS. 18b and 18d, a middle portion 7120 of the second portion 712 of the data signal line 71 is bent in a direction close to the first opening K1, and an orthographic projection of the middle portion 7120 of the second portion 712 on the base substrate is overlapped with orthographic projections of the pixel opening 902 and the anode 82 of the second sub-pixel on the base substrate.

In an exemplary implementation, in the structure shown in FIG. 7a, the orthographic projections of the pixel opening 902 and the anode 82 of the second sub-pixel on the base substrate may at least partially overlap with orthographic projections of the data signal lines 71 and first power supply lines 72 located on two sides of the first opening Kl on the base substrate. In an embodiment of the present disclosure, the second sub-pixel emits blue light, and as human eyes are less sensitive to blue light than to red light and green light, even if the flatness of the anode 82 of the second sub-pixel emitting blue light is not very high, in a case where the anode 81 of the first sub-pixel and the anode 83 of the third sub-pixel have high flatness after being flattened by the first power supply lines 72, the color separation phenomenon and color cast in all directions in the bright state of the COE panel are not obvious, and human eyes can hardly observe the color separation and color cast phenomenon.

In an exemplary implementation, as shown in FIGS. 18b and 18d, a distance R1 between two adjacent data signal lines 71 at the position of the first opening K1 (i.e., a distance between first portions 711 of the two adjacent data signal lines 71) is larger than a distance R2 between two adjacent data signal lines 72 at the position of the pixel opening 902 of the second sub-pixel (i.e., a distance between the second portions 712 of the two adjacent data signal lines 71).

In an exemplary implementation, as shown in FIGS. 22a and 22b, the plurality of sub-pixels may further include light-emitting layers E0 corresponding to the pixel openings. The first sub-pixel includes a first light-emitting layer E01, the second sub-pixel includes a second light-emitting layer E02, and the third sub-pixel includes a third light-emitting layer E03. Light-emitting layers E0 of a plurality of types of sub-pixels are arranged in the row direction X and the column direction Y, and centerlines of light-emitting layers E0 of a plurality of same type sub-pixels located in a same row are on a same straight line. As shown in FIG. 22b, centerlines of light-emitting layers E01 of a plurality of first sub-pixels located in a same row are on a same straight line O1-O1 (a horizontal straight line O1-O1), centerlines of light-emitting layers E02 of a plurality of second sub-pixels located in a same row are on a same straight line O2-O2 (a horizontal straight line O2-O2), and centerlines of light-emitting layers E03 of a plurality of third sub-pixels located in a same row are on a same straight line O3-O3 (a horizontal straight line O3-O3).

In an exemplary implementation, as shown in FIG. 21b, light-emitting layers E0 of a plurality of a same type of sub-pixels form M rows and N columns, where M and N are positive integers greater than 1. Among light-emitting layers E0 of the plurality of the same type of sub-pixels in the M rows and N columns, a center of the light-emitting layer E0 of the sub-pixel located in row i and column j is on a same straight line as centers of the light-emitting layers E0 of the sub-pixels located in row i+1 and column j+1 and in row i+2 and column j+2, where i is a positive integer greater than 1 and smaller than or equal to M, and j is a positive integer greater than 1 and smaller than or equal to N. As shown in FIG. 22b, a center of the light-emitting layer E01 of the first sub-pixel located in row i and column j is on the same straight line O1-O1 (inclined straight line O1-O1) as centers of the light-emitting layers E01 of the first sub-pixels located in row i+1 and column j+1 and in row i+2 and column j+2. A center of the light-emitting layer E02 of the second sub-pixel located in row i and column j is on the same straight line O2-O2 (inclined straight line O2-O2) as centers of the light-emitting layers E02 of the second sub-pixels located in row i+1 and column j+1 and row i+2 and column j+2. A center of the light-emitting layer E03 of the third sub-pixel located in row i and column j is on the same straight line O3-O3 (inclined straight line O3-O3) as centers of the light-emitting layers E03 of the third sub-pixels located in row i+1 and column j+1 and in row i+2 and column j+2.

In an exemplary implementation, among the light-emitting layers of the plurality of same type sub-pixels in the M rows and N columns, a centerline of the light-emitting layer of the sub-pixel located in row i and column j+2 is on a same straight line as centerlines of the light-emitting layers of the sub-pixels located in row i+1 and column j+1 and in row i+2 and column j. As shown in FIG. 22b, a centerline of the light-emitting layer E01 of the first sub-pixel located in row i and column j+2 is on the same straight line O1-O1 (inclined straight line O1-O1) as centerlines of the light-emitting layers E01 of the first sub-pixels located in row i+1 and column j+1 and in row i+2 and column j. A centerline of the light-emitting layer E02 of the second sub-pixel located in row i and column j+2 is on the same straight line O2-O2 (inclined straight line O2-O2) as centerlines of the light-emitting layers E02 of the second sub-pixels located in row i+1 and column j+1 and in row i+2 and column j. A centerline of the light-emitting layer E03 of the third sub-pixel located in row i and column j+2 is on the same straight line O3-O3 (inclined straight line O3-O3) as centerlines of the light-emitting layers E03 of the third sub-pixels located in row i+1 and column j+1 and in row i+2 and column j.

In an exemplary implementation, as shown in FIGS. 22b and 21b, the light-emitting layers E0 of the plurality of sub-pixels have a same shape as corresponding pixel openings 90, and orthographic projections of the light-emitting layers E0 of the plurality of sub-pixels on the base substrate are overlapped with orthographic projections of the corresponding pixel openings 90 on the base substrate.

In an exemplary implementation, as shown in FIGS. 22b and 21b, the pixel openings 90 and the light-emitting layers E0 may be in a shape of a circle or an oval. In an embodiment of the present disclosure, the circular or oval pixel openings 90 and light-emitting layers E0 may reduce a sense of jagging during displaying of the display substrate.

In an exemplary implementation, a sensing element may be provided at the position of the first opening K1, for example, the sensing element may be a photosensitive element, for example, the photosensitive element may be a photosensitive sensor.

In an embodiment of the present disclosure, the row direction may be a first direction X, and the column direction may be a second direction Y.

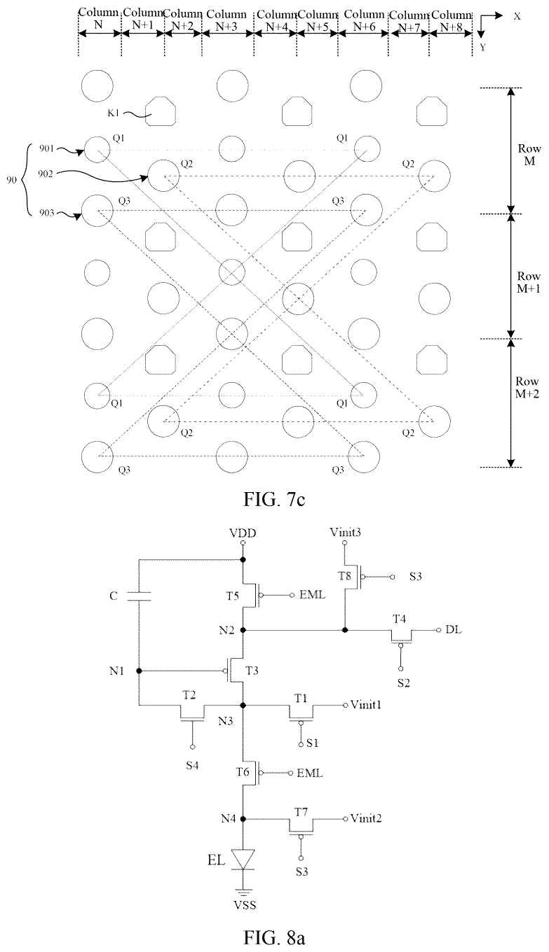

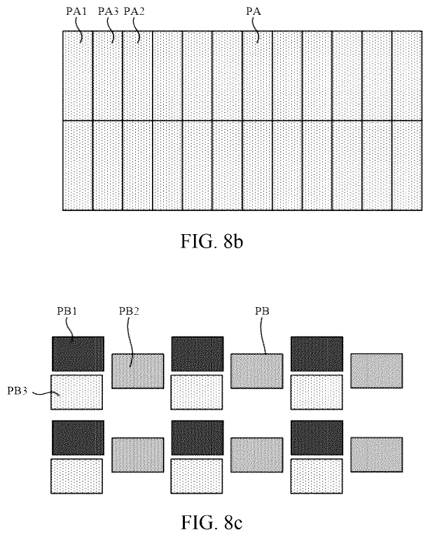

In an exemplary implementation, the pixel drive circuit shown in FIG. 8a has an 8T1C structure. As shown in FIG. 8a, the pixel drive circuit may include eight transistors (a first transistor T1 to an eighth transistor T8) and one storage capacitor C, and the pixel drive circuit is respectively connected to ten signal lines (a data signal line DL, a first scan signal line S1, a second scan signal line S2, a third scan signal line S3, a fourth scan signal line S4, a light-emitting signal line EML, a first initial signal line Vinit1, a second initial signal line Vinit2, a third initial signal line Vinit3, a first power supply line VDD and a second power supply line VSS).

As shown in FIG. 8a, a first electrode of the first transistor T1 is connected to the first initial signal line Vinit1, a second electrode of the first transistor T1 is connected to a third node N3, and a control electrode of the first transistor T1 is connected to the first scan signal line S1. A first electrode of the second transistor T2 is connected to a first node N1, a second electrode of the second transistor T2 is connected to the third node N3, and a control electrode of the second transistor T2 is connected to the fourth scan signal line S4. A first electrode of the third transistor T3 is connected to a second node N2, a second electrode of the third transistor T3 is connected to the third node N3, and a control electrode of the third transistor T3 is connected to the first node N1. A first electrode of the fourth transistor T4 is connected to the data signal line DL, a second electrode of the fourth transistor T4 is connected to the second node N2, and a control electrode of the fourth transistor T4 is connected to the second scan signal line S2. A first electrode of the fifth transistor T5 is connected to the first power supply line VDD, a second electrode of the fifth transistor T5 is connected to the second node N2, and a control electrode of the fifth transistor T5 is connected to the light-emitting signal line EML. A first electrode of the sixth transistor T6 is connected to the third node N3, a second electrode of the sixth transistor T6 is connected to a fourth node N4, and a control electrode of the sixth transistor T6 is connected to the light-emitting signal line EML. A first electrode of the seventh transistor T7 is connected to the second initial signal line Vinit2, a second electrode of the seventh transistor T7 is connected to the fourth node N4, and a control electrode of the seventh transistor T7 is connected to the third scan signal line S3. A first electrode of the eighth transistor T8 is connected to the third initial signal line Vinit3, a second electrode of the eighth transistor T8 is connected to the second node N2, and a control electrode of the eighth transistor T8 is connected to the third scan signal line S3. A first plate of the storage capacitor C is connected to the first node N1, and a second plate of the storage capacitor C is connected to the first power supply line VDD. The fourth node in the pixel drive circuit shown in FIG. 8 is connected to an anode of a light emitting device (e.g. the light emitting device may be a light emitting diode EL).

In an exemplary implementation, the first transistor T1, and the third transistor T3 to the eighth transistor T8 are low temperature polysilicon transistors, and the second transistor T2 is an oxide transistor.

As to the structural diagram of the pixel drive circuit shown in FIG. 8a, reference may be made to FIGS. 7a and 7b, where in the first direction X, the fourth transistor T4 and the fifth transistor T5 are located on one side of the third transistor T3, the first transistor T1, the second transistor T2 and the sixth transistor T6 are located on the other side of the third transistor T3, and the seventh transistor T7 and the eighth transistor T8 are located between the fifth transistor T5 and the sixth transistor T6; and in the second direction Y, the fifth transistor T5, the seventh transistor T7 and the eighth transistor T8 are located on one side of the third transistor T3, the first transistor T1, the second transistor T2 and the fourth transistor T4 are located on the other side of the third transistor T3, and the sixth transistor T6 is located between the first transistor T1 and the seventh transistor T7.

In an exemplary implementation, at least one sub-pixel may include a circuit unit and a light-emitting unit. FIG. 8b is a schematic diagram of an arrangement of circuit units in FIGS. 7a and 7b. In an exemplary implementation, as shown in FIG. 8b, on a plane parallel to the display substrate, a drive circuit layer in the display area may include a plurality of circuit units PA, and the plurality of circuit units PA may constitute a plurality of unit rows and a plurality of unit columns. A unit row may include a plurality of circuit units PA sequentially arranged in the first direction X, a unit column may include a plurality of circuit units PA sequentially arranged in the second direction Y, and the first direction X intersects with the second direction Y.

In an exemplary implementation, a shape of a circuit unit PA may be rectangular, a long side of a circuit unit PA in a rectangular shape may extend along the second direction Y (column direction), and a short side of the circuit unit PA in a rectangular shape may extend along the first direction X (row direction), forming an arrangement of horizontal parallel units.

In an exemplary implementation, the circuit unit PA may at least include a pixel drive circuit. The pixel drive circuit is connected to a scan signal line, a data signal line, and a light emitting signal line respectively, and is configured to receive a data voltage transmitted by the data signal line and output a corresponding current to a connected light emitting unit under control of the scan signal line and the light emitting signal line.

FIG. 8c is a schematic diagram of an arrangement of light-emitting units according to an exemplary embodiment of the present disclosure. A light-emitting unit may include a light-emitting layer E0. As shown in FIG. 8c, in an exemplary implementation, on a plane parallel to the display substrate, a light-emitting structure layer of the display substrate may include a plurality of light-emitting units PB arranged regularly, the plurality of light-emitting units PB may constitute a plurality of sub-pixel rows and a plurality of sub-pixel columns. A sub-pixel row may include a plurality of light-emitting units PB sequentially arranged in the first direction X, and a sub-pixel column may include a plurality of light-emitting units PB sequentially arranged in the second direction Y.

In an exemplary implementation, a plurality of light-emitting units PB may include a red light-emitting unit emitting red light, a blue light-emitting unit emitting blue light, and a green light-emitting unit emitting green light. The red light-emitting unit, the green light-emitting unit and the blue light-emitting unit in each sub-pixel row may be arranged periodically in the first direction X, and the red light-emitting unit, the blue light-emitting unit and the green light-emitting unit are disposed in a misaligned manner.

In an exemplary implementation, a light emitting unit is connected to a pixel drive circuit of a corresponding circuit unit, and is configured to emit light of a corresponding brightness in response to a current output by the pixel drive circuit connected to the light emitting unit.

In an exemplary implementation, a shape of a light emitting unit PB may include any one or more of the following: a triangle, a rectangle, a diamond, a pentagon, and a hexagon.

As in FIG. 8c, a first light-emitting unit PB1, a second light-emitting unit PB2 and a third light-emitting unit PB3 may be included, in FIG. 7c, the pixel opening 901 of the first sub-pixel corresponds to the first light-emitting unit PB1, the pixel opening 902 of the second sub-pixel corresponds to the second light-emitting unit PB2, and the pixel opening 903 of the third sub-pixel corresponds to the third light-emitting unit PB3. In FIG. 8b, the circuit units may include a circuit unit PA1 of the first sub-pixel, a circuit unit PA2 of the second sub-pixel, and a circuit unit PA3 of the third sub-pixel. The light-emitting unit PB1 of the first sub-pixel is electrically connected to the circuit unit PA1 of the corresponding first sub-pixel, the light-emitting unit PB2 of the second sub-pixel is electrically connected to the circuit unit PA2 of the corresponding second sub-pixel, and the light-emitting unit PB3 of the third sub-pixel is electrically connected to the circuit unit PA3 of the corresponding third sub-pixel. In an exemplary implementation, the circuit unit PAI of the first sub-pixel, the circuit unit PA3 of the third sub-pixel, and the circuit unit PA2 of the second sub-pixel may be periodically arranged in the first direction X.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate (or substrate) using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A coincides with the boundary of the orthographic projection of B.

In an exemplary implementation, taking 18 sub-pixels (in 2 sub-pixel rows and 9 sub-pixel columns) in a display area (AA) as an example, a manufacturing process of a display substrate may include following operations.

(101) A base substrate is manufactured on a glass carrier plate. In an exemplary implementation, the base substrate may be a flexible base substrate, or a rigid base substrate. The rigid substrate may include, but is not limited to, one or more of glass and quartz. The flexible substrate may be, but is not limited to, one or more of polyethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, an adhesive layer, a second flexible material layer, and a second inorganic material layer which are stacked. Materials of the first flexible material layer and the second flexible material layer may be Polyimide (PI), Polyethylene Terephthalate (PET), or a polymer soft thin film subjected to surface treatment, etc. Materials of the first inorganic material layer and the second inorganic material layer may be Silicon Nitride (SiNx), Silicon Oxide (SiOx), or the like, so as to improve a water-oxygen resistance capability of the base substrate. The first inorganic material layer and the second inorganic material layer are also referred to as barrier layers, and a material of the adhesive layer may be amorphous silicon (a-si). In an exemplary implementation, taking a stacked structure PI1/Barrier1/a-si/PI2/Barrier2 as an example, its manufacturing process may include: firstly coating a layer of polyimide on a glass carrier board, and curing it into a film to form a first flexible material (PI1) layer; then depositing a layer of barrier thin film on the first flexible layer to form a first barrier (Barrier1) layer overlying the first flexible material layer; then depositing a layer of amorphous silicon thin film on the first barrier layer to form an amorphous silicon (a-si) layer overlying the first barrier layer; then coating a layer of polyimide on the amorphous silicon layer, and curing it into a film to form a second flexible material (PI2) layer; and then depositing a barrier thin film on the second flexible layer to form a second barrier (Barrier2) layer overlying the second flexible layer, thus completing the manufacturing of the base substrate.

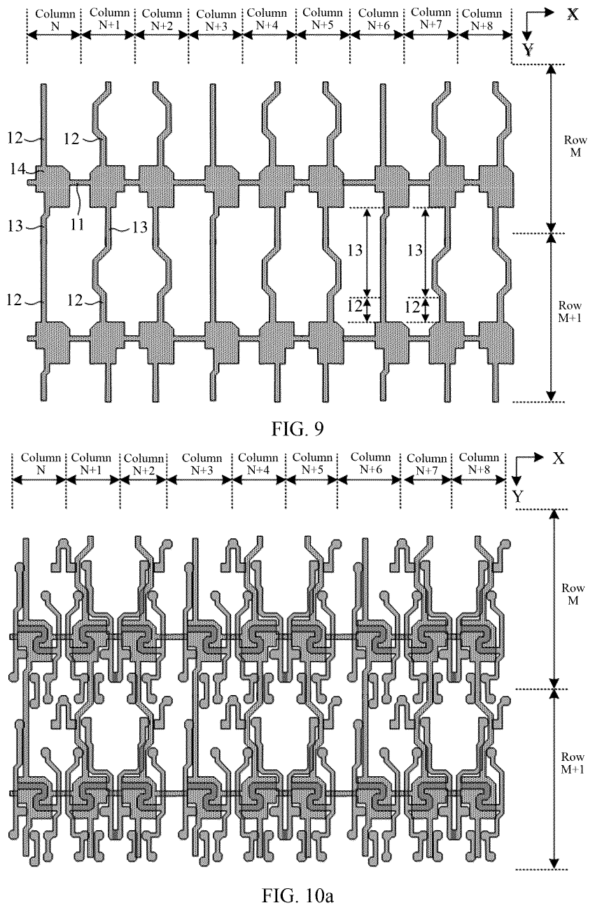

(102) A pattern of a shield layer is formed. In an exemplary implementation, forming the pattern of the shield layer may include: depositing a conductive thin film of the shield layer on the base substrate, and patterning the conductive thin film of the shield layer through a patterning process, to form the pattern of the shield layer on the base substrate, as shown in FIG. 9, which is a planar structure view of patterns of the shield layers in eighteen sub-pixels.

In an exemplary implementation, the pattern of the shield layer of each sub-pixel may include a first shield structure 11, a second shield structure 12, a third shield structure 13 and a shielding block 14. The shielding block 14 may be in a shape of a rectangle, an edge of the rectangle may be a polyline, and a corner of the rectangle may be chamfered. The first shield structure 11 may be in a shape of a strip extending in the first direction X, and the first shield structure 11 is disposed at a side of the shielding block 14 in the first direction X and connected to the shielding block 14. The second shield structure 12 may be in a shape of a strip extending in the second direction Y, and the second shield structure 12 is disposed at a side of the shielding block 14 in an opposite direction of the second direction Y and connected to the shielding block 14. The third shield structure 13 may be in a shape of a bend line extending in the second direction Y, and the third shield structure 13 is disposed at a side of the shielding block 14 in the second direction Y and connected to the shielding block 14.

In an exemplary implementation, the first shield structure 11 of each sub-pixel is connected to the shielding blocks 14 of adjacent sub-pixels in the first direction X such that the shield layers in a sub-pixel row are connected as a whole to form an interconnected integral structure.

In an exemplary implementation, the second shield structure 12 of each sub-pixel is connected to the third shield structures 13 of adjacent sub-pixels in the second direction Y such that the shield layers in a sub-pixel column are connected as a whole to form an interconnected integral structure.

In an exemplary implementation, the shield layers in a sub-pixel row and a sub-pixel column are connected as a whole, which may ensure that the shield layers in the display substrate have a same potential, and this is beneficial to improving uniformity of a panel, avoiding display defect of the display substrate, and ensuring a display effect of the display substrate.

In an exemplary implementation, the shield layer in column N+1 and the shield layer in column N+2 may be mirror symmetrical with respect to a first centerline, the shield layer in column N+4 and the shield layer in column N+5 may be mirror symmetrical with respect to a second centerline, and the shield layer in column N+7 and the shield layer in column N+8 may be mirror symmetrical with respect to a third centerline. The first centerline, the second centerline and the third centerline may each be a straight line extending in the second direction Y between adjacent sub-pixel columns. For example, the first centerline may be a straight line extending in the second direction Y between the sub-pixels in column N+1 and column N+2, the second centerline may be a straight line extending in the second direction Y between the sub-pixels in column N+4 and column N+5, and the third centerline may be a straight line extending in the second direction Y between the sub-pixels in column N+7 and column N+8.

In an exemplary implementation, shapes of the shield layers in a plurality of sub-pixel rows may be the same. In an exemplary implementation, in one sub-pixel row, in the first direction X, the shield layers in three adjacent sub-pixel columns may be taken as one repeating unit, a plurality of repeating units are arranged in the first direction X, and a plurality of repeating units in a plurality of sub-pixel rows may be arranged in an array in the first direction X and the second direction Y. The orthographic projection of the third shield structure 13 at the first opening K1 on the base substrate does not overlap with the orthographic projection of the first opening K1 on the base substrate, so as to avoid shielding the first opening K1. In an exemplary implementation, the third shield structure 13 may be a polyline structure bent in a direction facing away from the first opening K1 to avoid shielding the first opening K1.

(103) A pattern of a first semiconductor layer is formed. In an exemplary implementation, forming the pattern of the first semiconductor layer may include: depositing sequentially a first insulation thin film and a first semiconductor thin film on the base substrate on which the aforementioned patterns are formed, and patterning the first semiconductor thin film through a patterning process to form a first insulation layer covering the pattern of the shield layer, and the pattern of the first semiconductor layer disposed on the first insulation layer, as shown in FIGS. 10a and 10b, FIG. 10a being a diagram of a planar structure of eighteen sub-pixels, and FIG. 10b being a planar schematic view of a first semiconductor layer in FIG. 10a.

In an exemplary implementation, the pattern of the first semiconductor layer of each sub-pixel may include the active layer 21 of the first transistor T1, the active layer 23 of the third transistor T3 to the active layer 28 of the eighth transistor T8, and the active layer 23 of the third transistor T3 to the active layer 27 of the seventh transistor T7 are connected to each other to form an integrated structure.

In an exemplary implementation, in the first direction X, the active layer 24 of the fourth transistor T4 and the active layer 25 of the fifth transistor T5 are located on the same side of the active layer 23 of the third transistor T3, the active layer 21 of the first transistor Tl and the active layer 26 of the sixth transistor T6 are located on the other side of the active layer 23 of the third transistor T3, and the active layer 28 of the eighth transistor T8 is located between the active layer 25 of the fifth transistor T5 and the active layer 27 of the seventh transistor T7; and in the second direction Y, the active layer 24 of the fourth transistor T4 and the active layer 25 of the fifth transistor T5 are located on two sides of the active layer 23 of the third transistor T3, the active layer 25 of the fifth transistor T5, the active layer 26 of the sixth transistor T6, the active layer 27 of the seventh transistor T7, and the active layer 28 of the eighth transistor T8 are located on the same side of the active layer 23 of the third transistor T3, the active layer 27 of the seventh transistor T7 is located on a side of the active layer 26 of the sixth transistor T6 away from the active layer 21 of the first transistor T1, the active layer 28 of the eighth transistor T8 is located on a side of the active layer 23 of the third transistor T3 away from the active layer 24 of the fourth transistor T4, and the active layer 21 of the first transistor T1 is located on a side of the active layer 23 of the third transistor T3 away from the active layer 26 of the sixth transistor T6.

In an exemplary implementation, taking the sub-pixel in row M and column N as an example: in the first direction X, the active layer 24 of the fourth transistor T4 and the active layer 25 of the fifth transistor T5 are located on a side of the active layer 23 of the third transistor T3 away from the sub-pixels in column N+1, and the active layer 21 of the first transistor T1 and the active layer 26 of the sixth transistor T6 are located on a side of the active layer 23 of the third transistor T3 away from the sub-pixels in column N−1; and in the second direction Y, the active layer 24 of the fourth transistor T4 is located on a side of the active layer 23 of the third transistor T3 away from the sub-pixels in row M+1, the active layer 25 of the fifth transistor T5, the active layer 26 of the sixth transistor T6, and the active layer 27 of the seventh transistor T7 are located on a side of the active layer 23 of the third transistor T3 away from the sub-pixels in row M−1, the active layer 27 of the seventh transistor T7 is located on a side of the active layer 26 of the sixth transistor T6 away from the active layer 23 of the third transistor T3, the active layer 28 of the eighth transistor T8 is located on a side of the active layer 23 of the third transistor T3 away from the active layer 24 of the fourth transistor T4, and the active layer 21 of the first transistor T1 is located on a side of the active layer 23 of the third transistor T3 away from the active layer 26 of the sixth transistor T6.

In an exemplary implementation, the active layer 23 of the third transistor T3 may be in a shape of “S”, the active layer 21 of the first transistor T1, the active layer 24 of the fourth transistor T4, and the active layer 28 of the eighth transistor T8 may be in a shape of “I”, the active layer 25 of the fifth transistor T5 may be in a shape of “Z”, the active layer 26 of the sixth transistor T6 may be in a shape of a polyline extending in the second direction Y, and the active layer 27 of the seventh transistor T7 may be in a shape of “L”.

In an exemplary implementation, an active layer of each transistor may include a first region, a second region, and a channel region located between the first region and the second region. In an exemplary implementation, the first region 23-1 of the active layer 23 of the third transistor T3 may serve as the second region 24-2 of the active layer 24 of the fourth transistor T4 and the second region 25-2 of the active layer 25 of the fifth transistor T5; the second region 23-2 of the active layer 23 of the third transistor T3 may serve as the first region 26-1 of the active layer 26 of the sixth transistor T6; the second region 26-2 of the active layer 26 of the sixth transistor T6 may serve as the second region 27-2 of the active layer 27 of the seventh transistor T7; the first region 21-1 and the second region 21-2 of the active layer 21 of the first transistor T1, the first region 24-1 of the active layer 24 of the fourth transistor T4, the first region 25-1 of the active layer 25 of the fifth transistor T5, the first region 27-1 of the active layer 27 of the seventh transistor T7, and the first region 28-1 and the second region 28-2 of the active layer 28 of the eighth transistor T8 may be disposed separately.

In an exemplary implementation, an orthographic projection of the active layer 23 of the third transistor T3 on the base substrate may be at least partially overlapped with an orthographic projection of the shielding block 14 on the base substrate. In an exemplary implementation, an orthographic projection of the channel region of the active layer 23 of the third transistor T3 on the base substrate is within the range of the orthographic projection of the shielding block 14 on the base substrate.

In an exemplary implementation, the first region 25-1 of the active layer 25 of the fifth transistor T5 in column N+1 and the first region 25-1 of the active layer 25 of the fifth transistor T5 in column N+2 are connected to each other, the first region 25-1 of the active layer 25 of the fifth transistor T5 in column N+4 and the first region 25-1 of the active layer 25 of the fifth transistor T5 in column N+5 are connected to each other, and the first region 25-1 of the active layer 25 of the fifth transistor T5 in column N+7 and the first region 25-1 of the active layer 25 of the fifth transistor T5 in column N+8 are connected to each other. In an exemplary implementation, since a first region of an active layer of a fifth transistor T5 in each sub-pixel is connected to a first power supply line formed subsequently, by forming first regions of active layers of fifth transistors T5 of adjacent sub-pixels into an interconnected integrated structure, first electrodes of the fifth transistors T5 in the adjacent sub-pixels may be ensured to have a same potential, which is beneficial to improving display uniformity of a panel and avoiding poor display of the display substrate, thereby ensuring a display effect of the display substrate.

In an exemplary implementation, the first region 21-1 of the active layer 21 of the first transistor T1 in column N and the first region 21-1 of the active layer 21 of the first transistor T1 in column N+1 are connected to each other, the first region 21-1 of the active layer 21 of the first transistor T1 in column N+3 and the first region 21-1 of the active layer 21 of the first transistor T1 in column N+4 are connected to each other, and the first region 21-1 of the active layer 21 of the first transistor T1 in column N+6 and the first region 21-1 of the active layer 21 of the first transistor T1 in column N+7 are connected to each other. In an exemplary implementation, since the first region of the active layer 21 of the first transistor T1 in each sub-pixel is connected to the first initial signal line formed subsequently, by forming the first regions of the active layers 21 of the first transistors T1 of adjacent sub-pixels into an interconnected integrated structure, it can be ensured that the first electrodes of the first transistors T1 of adjacent sub-pixels have a same potential, which is beneficial to improving display uniformity of a panel and avoiding poor display of the display substrate, thereby ensuring display effect of the display substrate.

In an exemplary implementation, the first semiconductor layer in column N+1 and the first semiconductor layer in column N+2 may be mirror symmetrical with respect to the first centerline, the first semiconductor layer in column N+4 and the first semiconductor layer in column N+5 may be mirror symmetrical with respect to the second centerline, and the first semiconductor layer in column N+7 and the first semiconductor layer in column N+8 may be mirror symmetrical with respect to the third centerline.

In an exemplary implementation, the first region and the channel region of the active layer 24 of the fourth transistor T4 at the position of the first opening K1 are bent in a direction facing away from the first opening K1 to avoid shielding the first opening K1.

In an exemplary implementation, the first semiconductor layer may be made of poly-crystalline silicon (p-Si), i.e., the first transistor T1, the third transistor T3 to the eighth transistor T8 are LTPS thin film transistors. In an exemplary implementation, patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a polysilicon thin film. Subsequently, the poly silicon thin film is patterned to form the pattern of the first semiconductor layer.

(104) Forming a pattern of a first conductive layer. In an exemplary implementation, forming the pattern of the first conductive layer may include: sequentially depositing a second insulation thin film and a first conductive thin film on the base substrate where the above-mentioned patterns are formed, and patterning the first conductive thin film through a patterning process to form a second insulation layer that covers the pattern of the first semiconductor layer and the pattern of the first conductive layer disposed on the second insulation layer, as shown in FIG. 11a and FIG. 11b, FIG. 11b is a planar schematic view of the first conductive layer in FIG. 11a. In an exemplary implementation, the first conductive layer may be referred to as a first gate metal (GATE1) layer.

In an exemplary implementation, the pattern of the first conductive layer may at least include: a first scan signal line 31, a second scan signal line 32, a first plate 33 of a storage capacitor, a light emission control line 34, and a third scan signal line 35. Main body portions of the first scan signal line 31, the light emission control line 34, and the third scan signal line 35 may extend in the first direction X, and the second scan signal line 32 may be a polyline structure extending in the first direction X. In a same sub-pixel, the first scan signal line 31, the second scan signal line 32, the first plate 33 of the storage capacitor, the light emission control line 34, and the third scan signal line 35 are arranged in the second direction Y.

In an exemplary implementation, in the second direction Y, the second scan signal line 32 and the light emitting control line 34 are located on two sides of the first plate 33 of the storage capacitor, the first scan signal line 31 is located on one side of the second scan signal line 32 away from the first plate 33 of the storage capacitor, and the third scan signal line 35 is located on one side of the light emitting control line 34 away from the first plate 33 of the storage capacitor. For example, the first scan signal line 31, the second scan signal line 32, the first plate of the storage capacitor 33, the light emitting control line 34, and the third scan signal line 35 are arranged in sequence in the second direction.

The sub-pixel of M-th row and N-th column is described as an example. In the second direction Y, the second scan signal line 32 may be located on one side of the first plate 33 of the storage capacitor in the present sub-pixel close to the sub-pixels of (M−1)-th row; the light emitting control line 34 may be located on one side of the first plate 33 of the storage capacitor of the present sub-pixel close to the sub-pixel of (M+1)-th row; the first scan signal line 31 may be located on one side of the second scan signal line 32 close to the sub-pixels of (M−1)-th row; the third scan signal line 35 may be located on one side of the light emitting control line 34 close to the sub-pixels of (M+1)-th row.

In an exemplary implementation, the first plate 33 may be located between the light emitting control line 34 and the second scan signal line 32, the first plate 33 may be in a shape of a rectangle, corners of the rectangle may be chamfered, edges of the rectangle may be in a polyline shape, and an orthographic projection of the first plate 33 on the base substrate is overlapped with an orthographic projection of the active layer of the third transistor T3 on the base substrate. In an exemplary implementation, the first plate 33 may simultaneously serve as a plate of the storage capacitor and the control electrode of the third transistor T3.

In an exemplary implementation, the first plate 33 in column N+1 and the first plate 33 in column N+2 may be mirror symmetrical with respect to the first centerline, the first plate 33 in column N+4 and the first plate 33 in column N+5 may be mirror symmetrical with respect to the second centerline, and the first plate 33 in column N+7 and the first plate 33 in column N+8 may be mirror symmetrical with respect to the third centerline. In an exemplary implementation, an area where the light emission control line 34 (i.e., the light-emitting signal line EML in FIG. 8) overlaps with the active layer of the fifth transistor T5 may serve as the control electrode of the fifth transistor T5, an area where the light emission control line 34 overlaps with the active layer of the sixth transistor T6 may serve as the control electrode of the sixth transistor T6, an area where the first scan signal line 31 (i.e., the first scan signal line S1 in FIG. 8) overlaps with the active layer of the first transistor T1 may serve as the control electrode of the first transistor T1, an area where the second scan signal line 32 (i.e., the second scan signal line S2 in FIG. 8) overlaps with the active layer of the fourth transistor T4 may serve as the control electrode of the fourth transistor T4, an area where the third scan signal line 35 (i.e., the third scan signal line S3 in FIG. 8) overlaps with the active layer of the seventh transistor T7 may serve as the control electrode of the seventh transistor T7, and an area where the third scan signal line 35 overlaps with the active layer of the eighth transistor T8 may serve as the control electrode of the eighth transistor T8.

In an exemplary implementation, the first scan signal line 31, the third scan signal line 35 and the light emitting control line 34 may be designed with an equal width or with non-equal widths, thereby not only a layout of a pixel structure may be facilitated, but also a parasitic capacitance between signal lines may be reduced.

In an exemplary implementation, the second scan signal line 32 may be a bent structure in which the main body portion extends in the first direction X, the second scan signal line 32 may include a first bent structure 321 and a second bent structure 322, the first bent structure 321 is bent in a direction facing away from the first plate 33 of the storage capacitor C, and the orthographic projection of the first bent structure 321 on the base substrate 10 does not overlap with the orthographic projection of the first opening K1 formed subsequently on the base substrate 10, so as to avoid shielding the first opening K1 formed subsequently.

In an exemplary implementation, after the pattern of the first conductive layer is formed, a conductive treatment may be performed on the semiconductor layer by using the first conductive layer as a shield. A region of the semiconductor layer, which is shielded by the first conductive layer, forms channel regions of the first transistor T1, the third transistor T3 to the eighth transistor T8, and a region of the semiconductor layer, which is not shielded by the first conductive layer, is made to be conductive, that is, the first regions and the second regions of the active layer 21 of the first transistor T1, the active layer 23 of the third transistor T3 to the active layer 28 of the eighth transistor T8 are all made to be conductive.

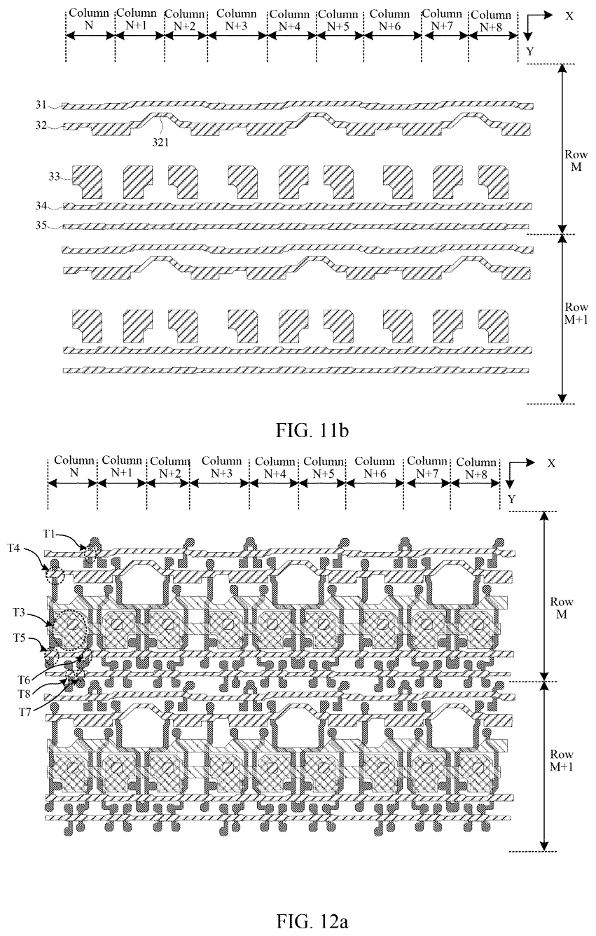

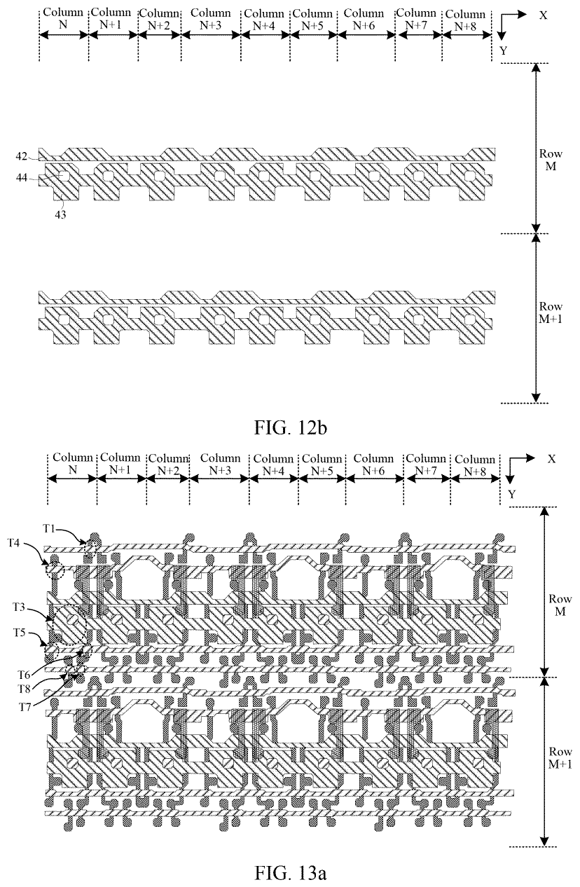

(105) Forming a pattern of a second conductive layer. In an exemplary implementation, forming the pattern of the second conductive layer may include: depositing sequentially a third insulation thin film and a second conductive thin film on the base substrate where the aforementioned patterns are formed, and patterning the second conductive thin film through a patterning process to form a third insulation layer covering the first conductive layer and the pattern of the second conductive layer disposed on the third insulation layer, as shown in FIG. 12a and FIG. 12b, FIG. 12a being a diagram of a planar structure of eighteen sub-pixels, and FIG. 12b being a planar schematic view of the second conductive layer in FIG. 12a. In an exemplary implementation, the second conductive layer may be referred to as a second gate metal (GATE2) layer.

In an exemplary implementation, the pattern of the second conductive layer at least includes: a first shielding line 41, and a second plate 43 of the storage capacitor. The main body portion of the first shielding line 42 may extend in the first direction X. The second plate 43 of the storage capacitor serves as the other plate of the storage capacitor. In the second direction Y, the first shielding line 42 is located on a side of the second plate 43. For example, in the same sub-pixel, the first shielding line 42, and the second plate 43 of the storage capacitor (i.e., the storage capacitor C in FIG. 8) are sequentially arranged in the second direction Y.

In an exemplary implementation, the first shielding line 42 is configured as a shield layer of the second transistor T2, to shield the channel of the second transistor T2, and ensure electrical performance of the oxide second transistor T2. In an exemplary implementation, signals of the first shielding line 42 and a fourth scan signal line 51 subsequently formed may be the same, i.e., the first shielding line 42 and the fourth scan signal line 51 subsequently formed are connected in parallel, and are connected to a same signal source, so that the first shielding line 42 may serve as a bottom gate electrode (i.e., a bottom control electrode) of the second transistor T2, forming a second transistor T2 with a double-gate structure.

In an exemplary implementation, a profile of the second plate 43 may be in a shape of a rectangle whose corners may be chamfered and edges may be polylines, an orthographic projection of the second plate 43 on the base substrate is overlapped with an orthographic projection of the first plate 33 on the base substrate, and the first plate 33 and the second plate 43 form the storage capacitor of the pixel drive circuit. The second plate 43 is provided with an opening 44, and the opening 44 may be located in the middle of the second plate 43. The opening 44 may be rectangular and enables the second plate 43 to form an annular structure. The opening 44 exposes the third insulation layer covering the first plate 33, and an orthographic projection of the first plate 33 on the base substrate contains an orthographic projection of the opening 44 on the base substrate. In an exemplary example, the opening 44 is configured to accommodate a thirteenth via formed subsequently, and the thirteenth via is located in the opening 44 and exposes the first plate 33, so that the first electrode of the second transistor T2 formed subsequently is connected to the first plate 33.

In an exemplary implementation, the second plate 43 in column N+1 and the second plate 43 in column N+2 may be mirror symmetrical with respect to the first centerline, the second plate 43 in column N+4 and the second plate 43 in column N+5 may be mirror symmetrical with respect to the second centerline, and the second plate 43 in column N+7 and the second plate 43 in column N+8 may be mirror symmetrical with respect to the third centerline.

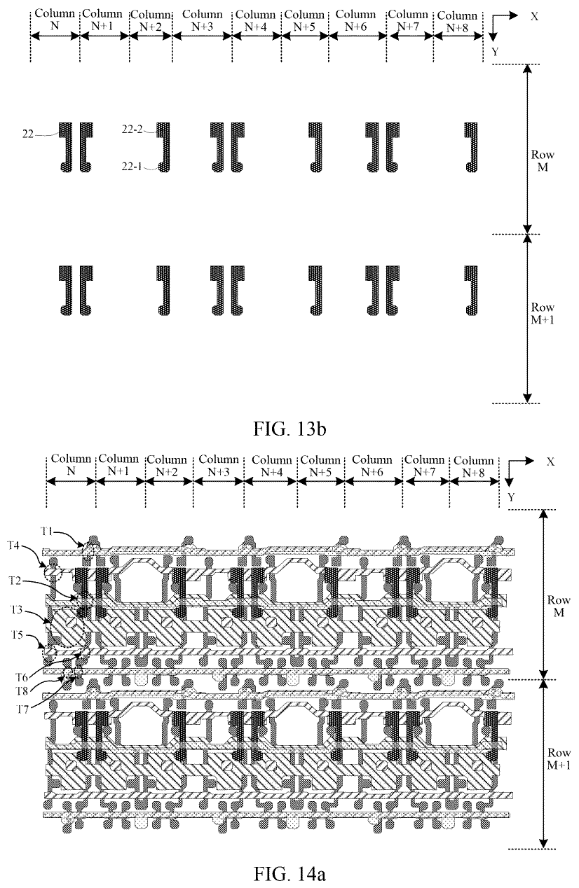

(106) A pattern of a second semiconductor layer is formed. In an exemplary implementation, forming the pattern of the second semiconductor layer may include: depositing sequentially a fourth insulation thin film and a second semiconductor thin film on the base substrate where the aforementioned patterns are formed, and patterning the second semiconductor thin film by a patterning process to form a fourth insulation layer covering the base substrate and the pattern of the second semiconductor layer disposed on the fourth insulation layer, as shown in FIG. 13a and FIG. 13b, FIG. 13a being a diagram of a planar structure of eighteen sub-pixels and FIG. 13b being a planar schematic view of the second semiconductor layer in FIG. 13a.

In an exemplary implementation, the pattern of the second semiconductor layer in each sub-pixel at least includes the active layer 22 of the second transistor T2.

In an exemplary implementation, the active layer 22 of the second transistor T2 may be in a shape of “I”, and the first region 22-1 and the second region 22-2 of the active layer 22 of the second transistor T2 may be separately disposed.

In an exemplary implementation, the second semiconductor layer in column N+1 and the second semiconductor layer in column N+2 may be mirror symmetrical with respect to the first centerline, the second semiconductor layer in column N+4 and the second semiconductor layer in column N+5 may be mirror symmetrical with respect to the second centerline, and the second semiconductor layer in column N+7 and the second semiconductor layer in column N+8 may be mirror symmetrical with respect to the third centerline.

In an exemplary implementation, shapes of the second semiconductor layers in a plurality of sub-pixels row may be the same.

In an exemplary implementation, in the plane where the display substrate is located, in the first direction X, the active layer 21 of the first transistor T1 and the active layer 22 of the second transistor T2 are located on the same side of the active layer 23 of the third transistor T3; and in the second direction Y, the active layer 22 of the second transistor T2 is located on a side of the active layer 23 of the third transistor T3 away from the active layer 27 of the seventh transistor T7. For example, in the second direction Y, the active layer 22 of the second transistor T2 may be located between the active layer 21 of the first transistor Tl and the active layer 23 of the third transistor T3.

In an exemplary implementation, taking the sub-pixel of M-th row and the N-th column as an example: in the first direction X, the active layer 21 of the first transistor T1, the active layer 22 of the second transistor T2 and the active layer 26 of the sixth transistor T6 are located on a side of the active layer 23 of the third transistor T3 away from the sub-pixels of (N−1)-th column; in the second direction Y, the active layer 22 of the second transistor T2 is located on one side of the active layer 23 of the third transistor T3 away from the sub-pixels of (M+1)-th row;

In an exemplary implementation, the second semiconductor layer may be made of an oxide, i.e., the second transistor T2 is an oxide thin film transistor. In an exemplary implementation, the oxide may be any one or more of following: Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAO), Strontium Copper Oxide (SrCuO), Lanthanum Copper Sulfur Oxide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementations, the second semiconductor thin film may be made of Indium Gallium Zinc Oxide (IGZO), an electron mobility of Indium Gallium Zinc Oxide (IGZO) is higher than an electron mobility of amorphous silicon. Because the leakage current of IGZO TFT is relatively small, the second transistors T2 are N-type transistors, which can avoid the leakage of electricity of the first node NI in the light emitting stage.

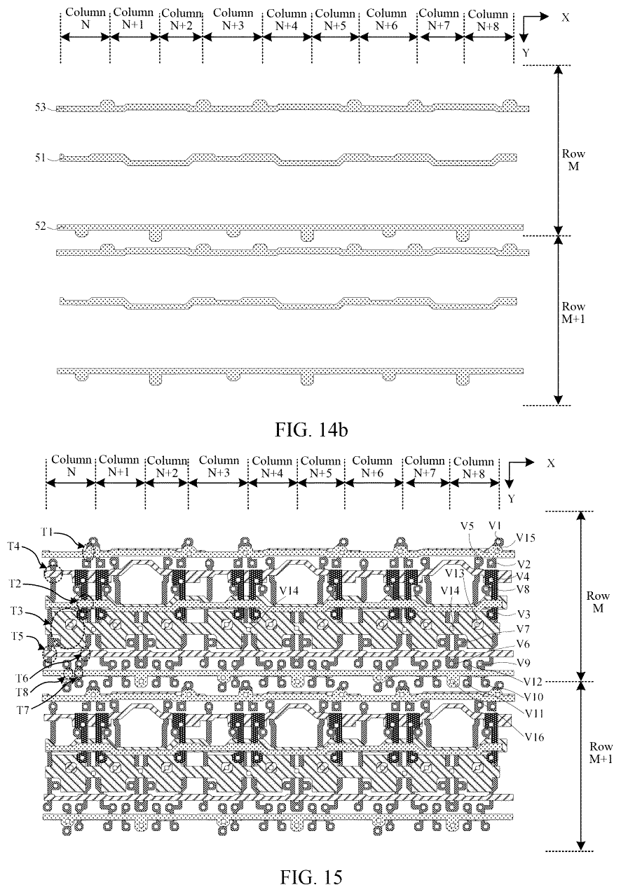

(107) Forming a pattern of a third conductive layer. In an exemplary implementation, forming the pattern of the third conductive layer may include: depositing sequentially a fifth insulation thin film and a third conductive thin film on the base substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIG. 14a and FIG. 14b, FIG. 14a being a planar structure view of eighteen sub-pixels, and FIG. 14b being a planar schematic view of the third conductive layer in FIG. 14a. In an exemplary implementation, the third conductive layer may be referred to as a third gate metal (GATE3) layer.

In an exemplary implementation, the pattern of the third conductive layer at least includes a fourth scan signal line 51, a third initial signal line 52 (i.e., the third initial signal line Vinit3 in FIG. 8), and a first initial signal line 53, main body portions of the fourth scan signal line 51, the third initial signal line 52, and the first initial signal line 53 may extend in the first direction X, and in the same sub-pixel row, the first initial signal line 53, the fourth scan signal line 51, and the third initial signal line 52 are arranged sequentially in the second direction Y.

In an exemplary implementation, a region where the fourth scan signal line 51 (i.e. the fourth scan signal line S4 in FIG. 8) is overlapped with the active layer 22 of the second transistor T2 serves as the control electrode of the second transistor T2.

In an exemplary implementation, signals of the first shielding line 42 and the fourth scan signal line 51 may be the same, i.e., the first shielding line 42 and the fourth scan signal line 52 are connected in parallel and connected to a same signal source, so that the first shielding line 42 may serve as a bottom gate electrode (i.e., a bottom control electrode) of the second transistor T2, forming the second transistor T2 with a double-gate structure.

(108) A pattern of a sixth insulation layer is formed. In an exemplary example, forming the pattern of the sixth insulation layer may include: depositing a sixth insulation thin film on the base substrate on which the aforementioned patterns are formed, and patterning the sixth insulation thin film through a patterning process to form the sixth insulation layer covering the third conductive layer, the sixth insulation layer being provided with a plurality of vias, as shown in FIG. 15 which is a diagram of a planar structure of eighteen sub-pixels.

In an exemplary implementation, the plurality of vias of each sub-pixel at least include: a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16.

In an exemplary implementation, an orthographic projection of the first via V1 on the base substrate is located within a range of an orthographic projection of the active layer 21 of the first transistor T1 on the base substrate, and the sixth insulation layer, the fifth insulation layer, the fourth insulation layer, the third insulation layer, and the second insulation layer within the first via V1 are etched away to expose a surface of the first region 21-1 of the active layer 21 of the first transistor T1. The first via VI is configured so that the first electrode of the first transistor T1 subsequently formed is connected to the active layer 21 of the first transistor T1 through this via.

In an exemplary implementation, an orthographic projection of the second via V2 on the base substrate is located within a range of an orthographic projection of the active layer 21 of the first transistor T1 on the base substrate, and the sixth insulation layer, the fifth insulation layer, the fourth insulation layer, the third insulation layer, and the second insulation layer within the second via V2 are etched away to expose a surface of the second region 21-2 of the active layer 21 of the first transistor T1. The second via V2 is configured so that the second electrode of the first transistor T1 subsequently formed is connected to the active layer 21 of the first transistor T1 through this via.

In an exemplary implementation, an orthographic projection of the third via V3 on the base substrate is within a range of an orthographic projection of the active layer 22 of the second transistor T2 on the base substrate, and the sixth and fifth insulation layers within the third via V3 are etched away to expose the surface of the first region 22-1 of the active layer 22 of the second transistor T2. The third via V3 is configured so that the first electrode of the second transistor T2 subsequently formed is connected to the active layer 22 of the second transistor T2 through this via.

In an exemplary implementation, the orthographic projection of the fourth via V4 on the base substrate is within the range of the orthographic projection of the active layer 22 of the second transistor T2 on the base substrate, and the sixth insulation layer and the fifth insulation layer within the fourth via V4 are etched away to expose a surface of the second region 22-2 of the active layer 22 of the second transistor T2. The fourth via V4 is configured so that the second electrode of the second transistor T2 subsequently formed is connected to the active layer 22 of the second transistor T2 through this via.

In an exemplary implementation, an orthographic projection of the fifth via V5 on the base substrate is within a range of an orthographic projection of the active layer 24 of the fourth transistor T4 on the base substrate, and the sixth insulation layer, the fifth insulation layer, the fourth insulation layer, the third insulation layer and the second insulation layer within the fourth via V4 are etched away to expose the first region 24-1 of the active layer 24 of the fourth transistor T4. The fifth via V5 is configured such that the first electrode of the fourth transistor T4 subsequently formed is connected to the active layer 24 of the fourth transistor T4 through the fifth via V5.

In an exemplary implementation, an orthographic projection of the sixth via V6 on the base substrate is located within a range of an orthographic projection of the active layer 25 of the fifth transistor T5 on the base substrate, and the sixth insulation layer, the fifth insulation layer, the fourth insulation layer, the third insulation layer, and the second insulation layer within the sixth via V6 are etched away to expose a surface of a first region 25-1 of the active layer 25 of the fifth transistor T5. The sixth via V6 is configured such that the first electrode of the fifth transistor T5 subsequently formed is connected to the active layer 25 of the fifth transistor T5 through the sixth via V6.

In an exemplary implementation, an orthographic projection of the seventh via V7 on the base substrate is located within a range of an orthographic projection of the active layer 25 of the fifth transistor T5 on the base substrate, and the sixth insulation layer, the fifth insulation layer, the fourth insulation layer, the third insulation layer, and the second insulation layer within the seventh via V7 are etched away to expose a surface of the second region 25-2 of the active layer 25 of the fifth transistor T5 (it is also the first region 23-1 of the active layer 23 of the third transistor T3 and the second region 24-2 of the active layer 24 of the fourth transistor T4). The seventh via V7 is configured such that the second electrode of the fifth transistor T5 formed subsequently is connected to the active layer 25 of the fifth transistor T5 through this via, the first electrode of the third transistor T3 formed subsequently is connected to the active layer 23 of the third transistor T3 through this via, and the second electrode of the fourth transistor T4 formed subsequently is connected to the active layer 24 of the fourth transistor T4 through this via.

In an exemplary implementation, an orthographic projection of the eighth via V8 on the base substrate is within a range of an orthographic projection of the active layer 26 of the sixth transistor T6 on the base substrate, and the sixth insulation layer, the fifth insulation layer, the fourth insulation layer, the third insulation layer, and the second insulation layer within the sixth via V6 are etched away, exposing a surface of the first region 26-1 of the active layer 26 of the sixth transistor T6 (it is also the second region of the active layer 23 of the third transistor T3). The eighth via V8 is configured such that the first electrode of the sixth transistor T6 formed subsequently is connected to the active layer 26 of the sixth transistor T6 through this via, and the second electrode of the third transistor T3 formed subsequently is connected to the active layer 23 of the third transistor T3 through this via.

In an exemplary implementation, an orthographic projection of the ninth via V9 on the base substrate is located within a range of an orthographic projection of the active layer 26 of the sixth transistor T6 on the base substrate, and the sixth insulation layer, the fifth insulation layer, the fourth insulation layer, the third insulation layer and the second insulation layer in the ninth via V9 are etched away to expose a surface of a second region 26-2 (it is also a second region 27-2 of the active layer 27 of the seventh transistor T7) of the active layer 26 of the sixth transistor T6. The ninth via V9 is configured so that the second electrode of the sixth transistor T6 subsequently formed is connected to the active layer 26 of the sixth transistor T6 through this via, and the second electrode of the seventh transistor T7 subsequently formed is connected to the active layer 27 of the seventh transistor T7 through this via.

In an exemplary implementation, an orthographic projection of the tenth via V10 on the base substrate is located within a range of an orthographic projection of the active layer 27 of the seventh transistor T7 on the base substrate, and the sixth insulation layer, the fifth insulation layer, the fourth insulation layer, the third insulation layer, and the second insulation layer within the tenth via V10 are etched away to expose a surface of a first region 27-1 of the active layer 27 of the seventh transistor T7. The tenth via V10 is configured so that the first electrode of the seventh transistor T7 subsequently formed is connected to the active layer 27 of the seventh transistor T7 through this via.

In an exemplary implementation, an orthographic projection of the eleventh via V11 on the base substrate is within a range of an orthographic projection of the active layer 28 of the eighth transistor T8 on the base substrate, and the sixth insulation layer, the fifth insulation layer, the fourth insulation layer, the third insulation layer, and the second insulation layer within the eleventh via V11 are etched away, exposing a surface of the first region 28-1 of the active layer 28 of the eighth transistor T8. The eleventh via V11 is configured so that the first electrode of the eighth transistor T8 subsequently formed is connected to the active layer 28 of the eighth transistor T8 through this via.

In an exemplary implementation, an orthographic projection of the twelfth via V12 on the base substrate is located within a range of an orthographic projection of the active layer 28 of the eighth transistor T8 on the base substrate, and the sixth insulation layer, the fifth insulation layer, the fourth insulation layer, the third insulation layer, and the second insulation layer within the twelfth via V12 are etched away to expose a surface of a second region 28-2 of the active layer 28 of the eighth transistor T8. The twelfth via V12 is configured so that the second electrode of the eighth transistor T8 subsequently formed is connected to the active layer 28 of the eighth transistor T8 through this via.

In an exemplary implementation, an orthographic projection of the thirteenth via V13 on the base substrate is located within a range of an orthographic projection of an opening 44 on the base substrate, and the sixth insulation layer, the fifth insulation layer, the fourth insulation layer, and the third insulation layer in the thirteenth via V13 are etched away to expose a surface of the first plate 33. The thirteenth via V13 is configured so that the first electrode of the second transistor T2 subsequently formed is connected to the first plate 33 through this via.

In an exemplary implementation, the fourteenth via V14 is located within a range of an orthographic projection of the second plate 43 on the base substrate, and the sixth insulation layer, the fifth insulation layer and the fourth insulation layer in the fourteenth via V14 are etched away to expose a surface of the second plate 43. The fourteenth via V14 is configured so that the fifth connection electrode that is subsequently formed is connected to the second plate 43 through this via. In an exemplary implementation, there may be a plurality of fourteenth vias V14 which serve as power supply vias, and the plurality of fourteenth vias V14 may be sequentially arranged in the second direction Y or the first direction X, thereby increasing the reliability of the connection between the first power supply connection line and the second plate 43.

In an exemplary implementation, an orthographic projection of the fifteenth via V15 on the base substrate is within a range of an orthographic projection of the first initial signal line 53 on the base substrate, and the sixth insulation layer in the fifteenth via V15 is etched away, exposing a surface of the first initial signal line 53. The fifteenth via V15 is configured so that the first electrode of the first transistor Tl subsequently formed is connected to the first initial signal line 53 through this via.

In an exemplary implementation, an orthographic projection of the sixteenth via V16 on the base substrate is within a range of an orthographic projection of the third initial signal line 52 on the base substrate, and the sixth insulation layer within the sixteenth via V16 is etched away, exposing a surface of the third initial signal line 52. The sixteenth via V16 is configured so that the eighth connection electrode 68 formed subsequently is connected to the third initial signal line 52 through this via.

(109) Forming a pattern of a fourth conductive layer. In an exemplary embodiment, forming the pattern of the fourth conductive layer may include: depositing a fourth conductive thin film on the base substrate on which the aforementioned patterns are formed, and patterning the fourth conductive thin film by a patterning process to form the fourth conductive layer disposed on the sixth insulation layer, as shown in FIG. 16a and FIG. 16b, FIG. 16a being a diagram of a planar structure of eighteen sub-pixels, and FIG. 16b being a planar schematic view of the fourth conductive layer in FIG. 16a. In an exemplary implementation, the fourth conductive layer may be referred to as a first source drain metal (SD1) layer.

In an exemplary implementation, the fourth conductive layer at least includes: a first connection electrode 61, a second connection electrode 62, a third connection electrode 63, a fourth connection electrode 64, a fifth connection electrode 65, a sixth connection electrode 66, a seventh connection electrode 67, an eighth connection electrode 68, a second initial signal line 69 (i.e., the second initial signal line Vinit2 in FIG. 8), a second initial signal connection line 610, and a ninth connection electrode 611.

In an exemplary implementation, the first connection electrode 61 may be in a shape of a strip whose main portion extends in the first direction X, and the first connection electrode 61 is connected to the first region 21-1 of the active layer 21 of the first transistor T1 through the first via V1 and connected to the first initial signal line 53 in sub-pixels in a row through the fifteenth via V15 in that sub-pixel row. In an exemplary implementation, the first connection electrode 61 may serve as the first electrode of the first transistor T1, and the first connection electrode 61 is configured to be connected to the first initial signal line 53 and the active layer 21 of the first transistor T1.

In an exemplary implementation, a main body portion of the second connection electrode 62 extends in the second direction Y, a first end of the second connection electrode 62 is connected to the second region 21-2 of the active layer 21 of the first transistor T1 through the second via V2, and a second end of the second connection electrode 62 is connected to the second region 22-2 of the active layer 22 of the second transistor T2 through the fourth via V4, and to the first region 26-1 of the active layer 26 of the sixth transistor T6 (also the second region 23-2 of the active layer 23 of the third transistor T3) through the eighth via V8, such that the second electrode of the first transistor T1, the second electrode of the second transistor T2, the second electrode of the third transistor T3, and the first electrode of the sixth transistor T6 have the same potential. In an exemplary implementation, the second connection electrode 62 may serve as a second electrode of the first transistor T1, a second electrode of the third transistor T3, and a first electrode of the sixth transistor T6.

In an exemplary implementation, one end of the third connection electrode 63 is connected to the first region 22-1 of the active layer 22 of the second transistor T2 through the third via V3, and the other end of the third connection electrode 63 is connected to the first plate 33 through the thirteenth via V13. In an exemplary implementation, the third connection electrode 63 may serve as the first electrode of a second transistor T2.

In an exemplary implementation, the fourth connection electrode 64 is connected to the first region 24-1 of the active layer 24 of the fourth transistor T4 through the fifth via V5. In an exemplary implementation, the fourth connection electrode 64 may serve as the first electrode of the fourth transistor T4, and is configured to be electrically connected to a data signal line formed subsequently.

In an exemplary implementation, the fifth connection electrode 65 is connected to the first region 25-1 of the active layer 25 of the fifth transistor T5 through the sixth via V6, and the fifth connection electrode 65 is connected to the second plate 43 through the fourteenth via V14. In an exemplary implementation, the fifth connection electrode 65 may serve as the first electrode of the fifth transistor T5, and is configured to be connected to the first power supply connection line formed subsequently.

In an exemplary implementation, the sixth connection electrode 66 is connected to the second region 26-2 (it is also the second region 27-2 of the active layer 27 of the seventh transistor T7) of the active layer 26 of the sixth transistor T6 through the ninth via V9. In an exemplary implementation, the sixth connection electrode 66 may serve as the second electrode of the sixth transistor T6 and the second electrode of the seventh transistor T7, and the sixth connection electrode 66 is configured to be connected to an anode connection electrode of the light emitting element formed subsequently.

In an exemplary implementation, one end of the seventh connection electrode 67 is connected to the second region 25-2 of the active layer 25 of the fifth transistor T5 (also the second region 24-2 of the active layer 24 of the fourth transistor T4 and the first region 23-1 of the active layer 23 of the third transistor T3) through the seventh via V7, and the other end of the seventh connection electrode 67 is connected to the second region 28-2 of the active layer 28 of the eighth transistor T8 through the twelfth via V12. In an exemplary implementation, the seventh connection electrode 67 may serve as the first electrode of the third transistor T3, the second electrode of the fourth transistor T4, the second electrode of the fifth transistor T5, and the second electrode of the eighth transistor T8.

In an exemplary implementation, one end of the eighth connection electrode 68 may be connected to the first region 28-1 of the active layer 28 of the eighth transistor T8 through the eleventh via V11, and the other end of the eighth connection electrode 68 may be connected to the third initial signal line 52 through the sixteenth via V16. In an exemplary implementation, the eighth connection electrode 68 may serve as the first electrode of the eighth transistor T8. In an exemplary implementation, the eighth connection electrodes 68 in the sub-pixels in column N, column N+3, and column N+6 may be a strip structure extending in the second direction Y; and in the same sub-pixel row, the eighth connection electrodes 68 in the sub-pixels in column N+1 and column N+2 may be connected to each other to form an integrated structure, the eighth connection electrodes 68 in the sub-pixels in column N+4 and column N+5 may be connected to each other to form an integrated structure, the eighth connection electrodes 68 in the sub-pixels in column N+7 and column N+8 may be connected to each other to form an integrated structure, and the integrated structure may be a strip structure extending in the first direction X.

In an exemplary implementation, the second initial signal line 69 may be in a shape of a bend line whose main portion extends in the first direction X, and the second initial signal line 69 is connected to the first regions 27-1 of the active layers 27 of a plurality of seventh transistors T7 through a plurality of tenth vias V10 in a sub-pixel row, to write an initial voltage into the plurality of seventh transistors T7 in the sub-pixel row. In an exemplary implementation, because the second initial signal line 69 is connected to the first regions 27-1 of the active layers 27 of all seventh transistors T7 in a sub-pixel row, the first electrodes of all seventh transistors T7 in a sub-pixel row may be ensured to have a same potential, which is beneficial to improving uniformity of the panel, avoiding display defect of the display substrate, and ensuring the display effect of the display substrate. In an exemplary implementation, the second initial signal line 67 may serve as the first electrode of the seventh transistor T7.

In an exemplary implementation, the second initial signal connection line 610 may be a bend line shape of which a main body portion extends along the second direction Y, and both ends of the second initial signal connection line 610 are respectively connected to two adjacent second initial signal lines 69. In the second direction Y, the second initial signal lines 69 are located between the two adjacent second initial signal lines 69. In an exemplary implementation, the second initial signal connection line 610 and the second initial signal line 69 may form an integrated structure. In an exemplary implementation, the second initial signal connection line 610 connects a plurality of second initial signal lines 69 arranged along the second direction Y into an integrated structure, so that the plurality of second initial signal lines 69 have a same potential, which is beneficial to improving uniformity of the panel, avoiding poor display of the display substrate, improving low gray-scale image quality, and ensuring the display effect of the display substrate. In an exemplary embodiment, the second initial signal connection line 610 may be provided in one of three adjacent sub-pixel columns. For example, as shown in FIG. 16b, the second initial signal connection line 610 may be provided for the sub-pixels in column N, column N+3, and column N+6. In an exemplary embodiment, in the first direction X, the spacing between two adjacent second initial signal connection lines 610 may be the same as the width of three adjacent sub-pixel columns. In an exemplary implementation, in the first direction X, the second initial signal connection line 610 may be provided in the drive circuit of the first sub-pixel.

In an exemplary implementation, in the first direction X, the distance between the fifth connection electrode 65 and the third connection electrode 63 in the sub-pixel column provided with a second initial signal connection line 610 may be larger than the distance between the fifth connection electrode 65 and the third connection electrode 63 in the sub-pixel column not provided with a second initial signal connection line 610, and the distance between the fourth connection electrode 64 and the second connection electrode 62 in the sub-pixel column provided with a second initial signal connection line 610 may be larger than the distance between the fourth connection electrode 64 and the second connection electrode 62 in the sub-pixel column not provided with a second initial signal connection line 610, so as to reserve sufficient space to accommodate the second initial signal connection line 610.

In an exemplary implementation, the ninth connection electrode 611 may be connected to the second plate 43 through the thirteenth via V13, and the ninth connection electrode 611 may be configured to be connected to the first power supply connection line formed subsequently.

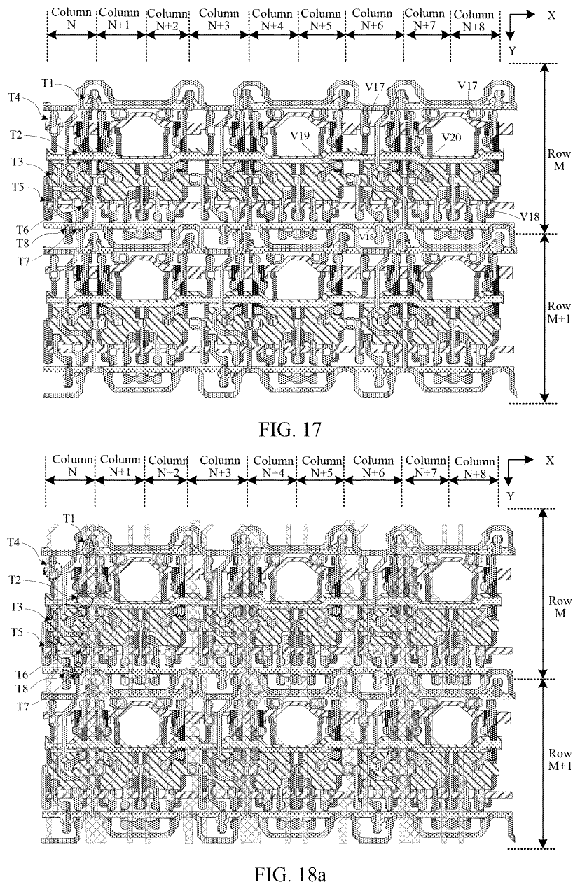

(110) Patterns of a seventh insulation layer and a first planarization layer are formed. In an exemplary embodiment, forming the patterns of the seventh insulation layer and the first planarization layer may include: first depositing a seventh insulation thin film on the base substrate on which the aforementioned patterns are formed, and then coating a first planarization thin film, and patterning the first planarization thin film and the seventh insulation thin film by a patterning process, to form a seventh insulation layer covering the pattern of the fourth conductive layer and the first planarization layer disposed on the seventh insulation layer, the seventh insulation layer and the first planarization layer being provided with a plurality of vias, as shown in FIG. 17, FIG. 17 being a planar structure view of eighteen sub-pixels.

In an exemplary implementation, the plurality of vias in each sub-pixel may at least include a seventeenth via V17, an eighteenth via V18, a nineteenth via V19, and a twentieth via hole V20.

In an exemplary implementation, an orthographic projection of the seventeenth via V17 on the base substrate is located within a range of an orthographic projection of a fourth connection electrode 64 on the base substrate. The first planarization layer and the seventh insulation layer in the seventeenth via V17 are etched away to expose a surface of the fourth connection electrode 64. The seventeenth via V17 is configured so that the data signal line formed subsequently is connected to the fourth connection electrode 64 through this via.

In an exemplary implementation, an orthographic projection of the eighteenth via V18 on the base substrate is within a range of an orthographic projection of the sixth connection electrode 66 on the base substrate, and the first planarization layer and the seventh insulation layer in the eighteenth via V18 are etched away, exposing a surface of the sixth connection electrode 66. The eighteenth via V18 is configured so that an anode connection electrode of a light emitting element formed subsequently is electrically connected to the sixth connection electrode 66 through this via.

In an exemplary implementation, an orthographic projection of the nineteenth via V19 on the base substrate is within a range of an orthographic projection of the fifth connection electrode 65 on the base substrate. The first planarization layer and the seventh insulation layer in the nineteenth via V19 are etched away to expose a surface of the fifth connection electrode 65. The nineteenth via V19 is configured so that the first power supply line formed subsequently is connected to the sixth connection electrode 65 through this via.

In an exemplary implementation, in the first direction X, a distance between the seventeenth via V17 and the second connection electrode 62 in the sub-pixel column provided with a second initial signal connection line 610 is larger than a distance between the seventeenth via V17 and the second connection electrode 62 in the sub-pixel column not provided with a second initial signal connection line 610, which, on the one hand, can increase the space for accommodating the second initial signal connection line 610, and on the other hand, can save the space of the sub-pixel column not provided with a second initial signal connection line 610.

In an exemplary implementation, an orthographic projection of the twentieth via V20 on the base substrate is within a range of an orthographic projection of the ninth connection electrode 611 on the base substrate, and the first planarization layer and the seventh insulation layer within the twentieth via V20 are etched away, exposing a surface of the ninth connection electrode 611. The twentieth via V20 is configured such that the first power supply connection line formed subsequently is connected to the ninth connection electrode 611 through this via.

(111) Forming a pattern of a fifth conductive layer. In an exemplary embodiment, forming the pattern of the fifth conductive layer may include: depositing a fifth conductive thin film on the base substrate on which the aforementioned patterns are formed, and patterning the fifth conductive thin film through a patterning process to form the fifth conductive layer disposed on the first planarization layer, as shown in FIG. 18a to FIG. 18d, FIG. 18a and FIG. 18c being diagrams of a planar structure of eighteen sub-pixels, and FIG. 18b and FIG. 18d being schematic planar views of the fifth conductive layer in FIG. 18a and FIG. 18c, respectively. In an exemplary implementation, the fifth conductive layer may be referred to as a second source-drain metal (SD2) layer.

In an exemplary embodiment, the fifth conductive layer at least includes a data signal line 71 (i.e., the data signal line DL in FIG. 8), a first power supply line 72 (i.e., the first power supply line VDD in FIG. 8), and an anode connection electrode 83. In an exemplary embodiment, an anode connection electrode 73 is an anode connection electrode of a light emitting element.

In an exemplary embodiment, the data signal line 71 is in a shape of a polyline with a main body portion extending in the second direction Y, and the data signal line 71 is connected to the fourth connection electrode 64 through the seventeenth via V17. Because the fourth connection electrode 64 is connected to the first region 24-1 of the active layer 24 of the fourth transistor T4 through a via, the connection of the data signal line 71 to the first electrode of the fourth transistor T4 is achieved, and a data signal is written to the fourth transistor T4. In an exemplary implementation, the data signal lines 71 located on two sides of the first opening K1 in the row direction X may include a first portion 711 and a second portion 712 which are integrally formed, the first portion 711 extends in the column direction Y, the second portion 712 is a bent structure, orthographic projections of the channel region and the first region of the fourth transistor T4 on the base substrate overlap with an orthographic projection of the first portion 711 on the base substrate, the first portions 711 of two data signal lines 71 located on two sides of the first opening K1 in the row direction X form a second opening K2, and the orthographic projection of the first opening K1 on the base substrate is within a range of an orthographic projection of the second opening K2 on the base substrate, so as to prevent the data signal line 71 from shielding the first opening K1.

In an exemplary embodiment, the first power supply line 72 is in a shape of a polyline with a main body portion extending in the second direction Y, and the first power supply line 72 is connected to the fifth connection electrode 65 through the nineteenth via V19. Because the fifth connection electrode 65 is connected to the second plate 43 through a via, connection between the first power supply line 72 and the second plate 43 is achieved, and a power signal is written into the second plate 43. Because the fifth connection electrode 65 is connected to the first region 25-1 of the active layer 25 of the fifth transistor T5 through a via, connection between the first power supply line 72 and the first electrode of the fifth transistor T5 is achieved, and a power signal is written into the fifth transistor T5.

In an exemplary embodiment, as shown in FIGS. 18d and 19b, the first power supply line 72 may include a proximal portion 721 and a distal portion 722 relative to the pixel opening 902 of the second sub-pixel, the pixel opening 902 of the second sub-pixel formed subsequently overlaps with the proximal portion 721 of the first power supply line 72, a hollow structure 720 may be disposed in the middle of the distal portion 722, the hollow structure 720 is arranged to accommodate the anode connection electrode 73, and an orthographic projection of the anode connection electrode 73 on the base substrate is overlapped with an orthographic projection of the corresponding hollow structure 720 on the base substrate. In an exemplary implementation, the orthographic projection of the anode connection electrode 73 on the base substrate is within the range of the orthographic projection of the corresponding hollow structure 720 on the base substrate, and the orthographic projection of the anode via V21 formed subsequently on the base substrate is within the range of the orthographic projection of the corresponding anode connection electrode 73 on the base substrate.

In an exemplary implementation, as shown in FIG. 18d, an electrical layer of the first power supply line 72 may include a first protrusion 701 and a second protrusion 702, the orthographic projection of the pixel opening 901 of the first sub-pixel formed subsequently on the base substrate is within the range of an orthographic projection of the first protrusion 701 on the base substrate, and the orthographic projection of the pixel opening 903 of the third sub-pixel formed subsequently on the base substrate is within the range of an orthographic projection of the second protrusion 702 on the base substrate. In an embodiment of the present disclosure, by means of the first protrusion 701 and the second protrusion 702, the anode of the first sub-pixel and the anode of the third sub-pixel can be at a same height, thereby improving the flatness of the anodes of the first sub-pixel and the third sub-pixel, and improving the problems of color separation and color cast of a COE panel.

In an exemplary embodiment, the anode connection electrode 73 is connected to the sixth connection electrode 66 through the eighteenth via V18. Because the sixth connection electrode 66 is connected to the second region 26-2 (it is also the second region 27-2 of the active layer 27 of the seventh transistor T7) of the active layer 26 of the sixth transistor T6 through a via, connections between the anode connection electrode 73 and the second electrode of the sixth transistor T6 as well as the second electrode of the seventh transistor T7 are achieved.

(112) A pattern of a second planarization layer is formed. In an exemplary embodiment, forming the pattern of the second planarization layer may include: coating a second planarization thin film on the base substrate on which the aforementioned patterns are formed, and patterning the second planarization thin film by a patterning process, to form the second planarization layer covering the pattern of the fifth conductive layer, the second planarization layer being provided with a plurality of vias, as shown in FIG. 19a and FIG. 19b, FIG. 19a and FIG. 19 being planar structure diagrams of eighteen sub-pixels corresponding to FIG. 18a and FIG. 18c.

In an exemplary implementation, the plurality of vias may at least include a twenty-first via V21.

In an exemplary implementation, vias of each sub-pixel at least include a twenty-first via V21. An orthographic projection of the twenty-first via V21 on the base substrate is within a range of the orthographic projection of the anode connection electrode 73 on the base substrate, the second planarization layer within the twenty-first via V21 is etched away to expose a surface of the anode connection electrode 73, and the twenty-first via V21 is configured such that the anode formed subsequently is electrically connected to the anode connection electrode 73 through this via. In an exemplary implementation, the twenty-first via V21 may be used as an anode via.

So far, a drive circuit layer has been manufactured on the base substrate. In an exemplary implementation, in a plane perpendicular to the display substrate, the drive circuit layer may include a shield layer, a first semiconductor layer, a first conductive layer, a second conductive layer, a second semiconductor layer, a third conductive layer, a fourth conductive layer, and a fifth conductive layer that are sequentially disposed on the base substrate.

In an exemplary implementation, the drive circuit layer may include a first insulation layer, a second insulation layer, a third insulation layer, a fourth insulation layer, a fifth insulation layer, a sixth insulation layer, a seventh insulation layer, a first planarization layer and a second planarization layer. The first insulation layer is disposed between the shield layer and the first semiconductor layer, the second insulation layer is disposed between the first semiconductor layer and the first conductive layer, the third insulation layer is disposed between the first conductive layer and the second conductive layer, the fourth insulation layer is disposed between the second conductive layer and the second semiconductor layer, the fifth insulation layer is disposed between the second semiconductor layer and the third conductive layer, the sixth insulation layer is disposed between the third conductive layer and the fourth conductive layer, the seventh insulation layer and the first planarization layer are disposed between the fourth conductive layer and the fifth conductive layer, and the second planarization layer is disposed on the fifth conductive layer.

In an exemplary embodiment, after the completion of the manufacturing of the drive circuit layer, a light-emitting structure layer is manufactured on the drive circuit layer, and the manufacturing process of the light-emitting structure layer may include the following operations: forming a pattern of a third planarization layer, the third planarization layer being at least provided with an anode via; forming a pattern of an anode (i.e., an anode conductive layer), the anode being connected to an anode connection electrode through the anode via; forming a pixel definition layer, the pixel definition layer being provided with a pixel opening that exposes the anode; forming an organic light-emitting layer by evaporation or ink-jet printing process, the organic light-emitting layer being connected to the anode through the pixel opening, and forming a cathode on the organic light-emitting layer; forming an encapsulation layer, wherein the encapsulation layer may include a first encapsulation layer, a second encapsulation layer, and a third encapsulation layer that are stacked, the first encapsulation layer and the third encapsulation layer may be made of inorganic materials, the second encapsulation layer may be made of organic materials, and the second encapsulation layer is arranged between the first encapsulation layer and the third encapsulation layer, which may ensure that external moisture cannot enter the light-emitting structure layer. The steps of forming the anode conductive layer and the pixel definition layer are as follows:

(113) A pattern of an anode conductive layer is formed. In an exemplary implementation, forming the pattern of the anode conductive layer may include: depositing an anode conductive thin film on the base substrate on which the aforementioned patterns are formed, and patterning the anode conductive thin film by a patterning process, to form the pattern of the anode conductive layer disposed on the planarization layer, as shown in FIG. 20a to FIG. 20d, FIG. 20a and FIG. 20c being schematic diagrams of a planar structure of eight sub-pixels corresponding to FIG. 19a and FIG. 19b, respectively, and FIG. 20b and FIG. 20d being planar schematic diagrams of the anode conductive layer in FIG. 22a and FIG. 20c, respectively.

In an exemplary implementation, the pattern of the anode conductive layer may at least include a plurality of anodes 80, and the plurality of anodes 80 may include a first anode 81 of a red light emitting unit, a second anode 82 of a blue light emitting unit, and a third anode 83 of a green light emitting unit. A region where the first anode 81 is located may form a red light emitting unit that emits red light, a region where the second anode 82 is located may form a blue light emitting unit that emits blue light, and a region where the third anode 83 is located may form a green light emitting unit that emits green light.

In an exemplary implementation, the first anode 81, the second anode 82, and the third anode 83 may be connected to the anode connection electrodes 73 in corresponding sub-pixels through the twentieth via V20. Since the anode connection electrode 73 in the sub-pixel is electrically connected to the second electrode of the sixth transistor T6 (also the second electrode of the seventh transistor T7) through this via, the first anode 81, the second anode 82 and the third anode 83 can be connected to the second electrode of the sixth transistor T6 and the second electrode of the seventh transistor T7 through the anode connection electrode 73, respectively, thereby realizing that the pixel drive circuit drives the light emitting device to emit light.

In an exemplary implementation, the anode 80 may include a main body portion 801 and a connection portion 802, the main body portion 801 may have a circular structure, one end of the connection portion 802 of the anode is connected to the main body portion 801 of the anode, and the other end of the connection portion 802 of the anode is electrically connected to the anode connection electrode 73 through the twentieth via V20. The anode connection portion 802 may have a strip structure, and the anode connection portion 802 may be disposed to compensate for the difference of the parasitic capacitance caused by the signal wiring between the plurality of sub-pixels. By disposing the anode connection portion 802, the parasitic capacitance of the plurality of sub-pixels can be kept consistent, and the display uniformity of the display substrate can be improved.

(114) A pattern of a pixel definition layer is formed. In an exemplary implementation, forming the pattern of the pixel definition layer may include: depositing a pixel definition layer thin film on the base substrate on which the aforementioned patterns are formed, and patterning the pixel definition layer thin film by a patterning process, to form the pattern of the pixel definition layer disposed on the anode conductive layer, as shown in FIG. 21a to FIG. 21d, FIG. 21a and FIG. 21c being schematic diagrams of a planar structure of eighteen sub-pixels corresponding to FIG. 20a and FIG. 20c, respectively, and FIG. 21b and FIG. 21d being schematic diagrams of a planar structure of the pixel definition layer in FIG. 21a and FIG. 21c, respectively.

In an exemplary implementation, the pattern of the pixel definition layer may include a plurality of pixel openings 90 and a plurality of first openings K1, the pixel opening exposing the anode 80. In an exemplary implementation, an orthographic projection of a pixel opening 90 on the base substrate is located within a range of an orthographic projection of an anode 80 on the base substrate. In an exemplary implementation, the pixel opening 90 may include a pixel opening 901 of a first sub-pixel, a pixel opening 902 of a second sub-pixel, and a pixel opening 903 of a third sub-pixel. An orthographic projection of the pixel opening 901 of the first sub-pixel on the base substrate is overlapped with an orthographic projection of the anode 81 of the first sub-pixel on the base substrate, an orthographic projection of the pixel opening 902 of the second sub-pixel on the base substrate is overlapped with the orthographic projection of the anode 82 of the second sub-pixel on the base substrate, and an orthographic projection of the pixel opening 903 of the third sub-pixel on the base substrate is overlapped with the orthographic projection of the anode 83 of the third sub-pixel on the base substrate.

In an exemplary implementation, the first openings K1 may be arranged in an array in the first direction X and the second direction Y, the first openings K1 and the pixel openings 902 of the second sub-pixels are alternately arranged in the second direction Y, the centers of the first openings K1 in the same row are on the same straight line, the center of the first opening K1 in row i and column j is on the same straight line as the centers of the first openings K1 in row i+1 and column j+1 and row i+2 and column j+2, i is a positive integer greater than 1 and smaller than or equal to M, and j is a positive integer greater than 1 and smaller than or equal to N. The center of the first opening K1 in row i and column j+2 is on the same straight line as the centers of the first openings K1 in row i+1 and column j+1 and row i+2 and column j. In an exemplary implementation, the pixel opening 902 of the second sub-pixel overlaps with patterns of at least two portions of signal lines in at least one conductive layer in the drive circuit layer, and the patterns of at least two portions of signal lines are distributed on two sides of the center of the pixel opening 902 of the second sub-pixel, so that anode flatness in each area in one second sub-pixel can be as consistent as possible, and anode flatness of a plurality of second sub-pixels can be as consistent as possible, thereby improving the display uniformity of the display substrate.

In an exemplary implementation, the main body portions of the signal lines in the patterns of at least two portions of signal lines extend in the column direction Y, as shown in FIGS. 18b and 18d, the patterns of at least two portions of signal lines of the at least one conductive layer in the drive circuit layer may include a data signal line 71, the main body portion of the data signal line 71 may extend in the column direction Y, in the column direction Y, two data signal lines 71 may be distributed on two sides of the center of the pixel opening 902 of the second sub-pixel (i.e., in the column direction Y, an overlapping area of two data signal lines 71 with the pixel opening 902 of the second sub-pixel may be symmetrical with respect to the centerline of the pixel opening 902 of the second sub-pixel extending in the column direction Y), and in the row direction X, any data signal line 71 may be distributed on two sides of the center of the pixel opening 902 of the second sub-pixel (i.e., in the row direction X, an overlapping area of a same data signal line 71 with the pixel opening 902 of the second sub-pixel may be symmetrical with respect to the centerline of the pixel opening 902 of the second sub-pixel extending in the row direction X).

In an exemplary implementation, as shown in FIG. 18b, the patterns of at least two portions of signal lines may further include a first power supply line 72, in the column direction Y, two first power supply lines 72 may be distributed on two sides of the center of the pixel opening 902 of the second sub-pixel (i.e., in the column direction Y, an overlapping area of two first power supply lines 72 with the pixel opening 902 of the second sub-pixel may be symmetrical with respect to the centerline of the pixel opening 902 of the second sub-pixel extending in the column direction Y), and in the row direction X, any first power supply line 72 may be distributed on two sides of the center of the pixel opening 902 of the second sub-pixel (i.e., in the row direction X, an overlapping area of a same first power supply line 72 with the pixel opening 902 of the second sub-pixel may be symmetrical with respect to the centerline of the pixel opening 902 of the second sub-pixel extending in the row direction X).

In an exemplary implementation, the pixel opening 902 of the second sub-pixel may also overlap with at least part of signal wires other than the patterns of at least two portions of signal lines in the drive circuit layer, and the at least part of signal wires located on two sides of the center of the pixel opening 902 of the second sub-pixel have a same overlapping area so as to improve flatness of the anode of the second sub-pixel, thereby improving the display uniformity of the display substrate. For example, as shown in FIGS. 16a and 16b, the at least part of signal wires may include a fifth connection electrode 65 (which may serve as a first electrode of a fifth transistor T5) and a seventh connection electrode 67 (which may serve as a second electrode of the fifth transistor T5); and as shown in FIG. 10b, at least part of signal wires may further include an active layer 25 of the fifth transistor T5.

(115) A pattern of a light emitting layer is formed. In an exemplary implementation, forming the pattern of the light-emitting layer may include: depositing a light-emitting layer thin film on the base substrate on which the aforementioned patterns are formed, and patterning the light-emitting layer thin film by a patterning process to form the pattern of the light-emitting layer located in the pixel opening and disposed on the anode conductive layer, as shown in FIGS. 22a and 22b, FIG. 22a being a schematic diagram of a planar structure of eighteen sub-pixels corresponding to FIG. 21a, and FIG. 22b being a schematic planar view of the light-emitting layer in FIG. 22a.

In some other exemplary implementations, taking 16 sub-pixels (2 sub-pixel rows and 8 sub-pixel columns) in a display area (AA) as an example, a manufacturing process of a display substrate may include following operations.

(201) A base substrate is manufactured on a glass carrier plate. The manufacturing method is the same as that in the operation (101) above, and will not be described here.

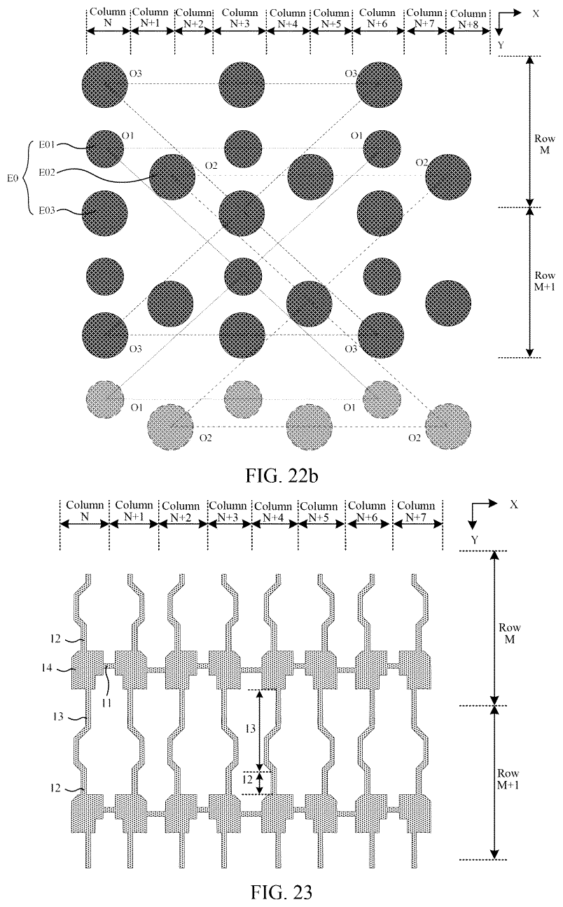

(202) A pattern of a shield layer is formed. The manufacturing method is the same as that in the operation (102) above, and will not be described here. As shown in FIG. 23, FIG. 23 is a planar structure diagram of a pattern of a shield layer in sixteen sub-pixels, and it is different from the pattern of the shield layer in FIG. 9 in that the shield layers in two adjacent columns of sub-pixels are symmetrically disposed with respect to a centerline between the two adjacent columns of sub-pixels. In an exemplary implementation, the centerline between two adjacent columns of sub-pixels may be a straight line extending in the second direction Y between the two adjacent columns of sub-pixels.

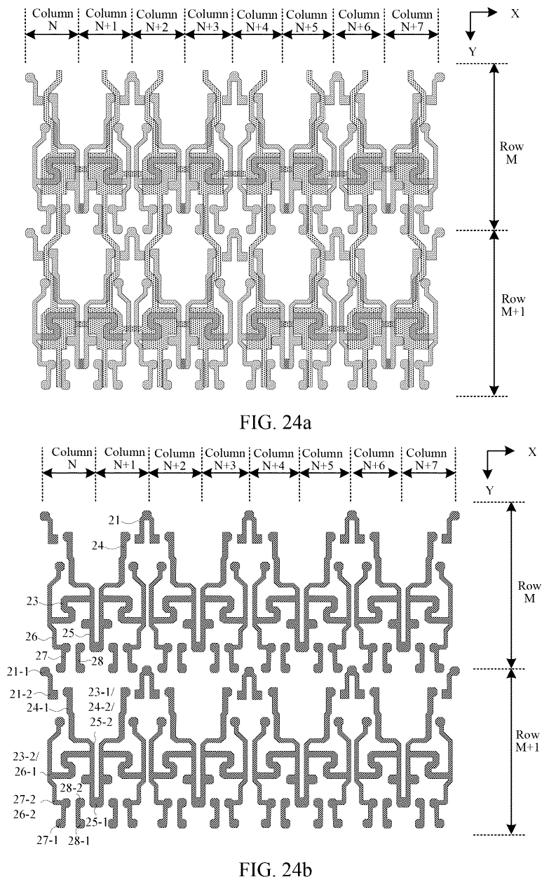

(203) A pattern of a first semiconductor layer is formed. The manufacturing method is the same as that in the operation (103) above, and will not be described here. As shown in FIGS. 24a and 24b, FIG. 24a is a planar structure diagram of sixteen sub-pixels, and FIG. 24b is a schematic planar diagram of the first semiconductor layer in FIG. 24a. The pattern of the first semiconductor layer in FIG. 24b is different from the pattern of the first semiconductor layer in FIG. 10b in that the first semiconductor layers in two adjacent columns of sub-pixels are disposed symmetrically with respect to the centerline between the two adjacent columns of sub-pixels.

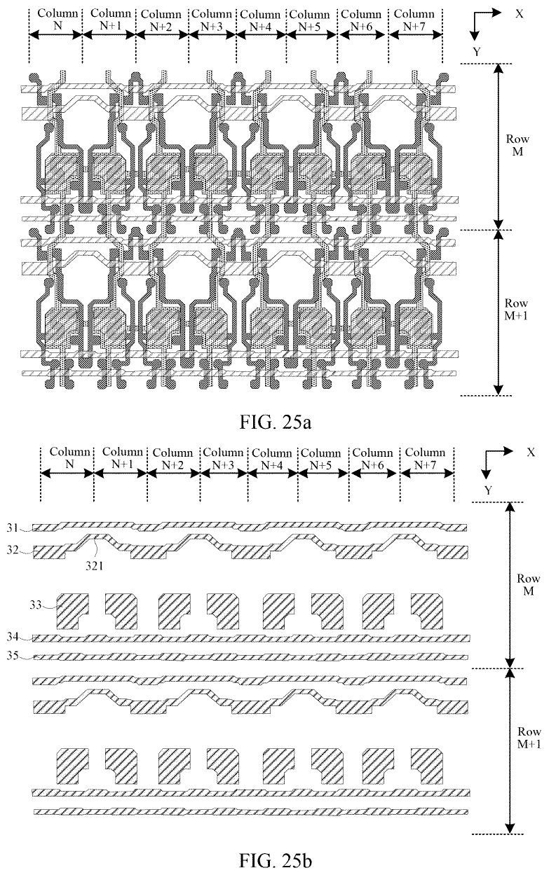

(204) Forming a pattern of a first conductive layer. The manufacturing method is the same as that in the operation (104) above, and will not be described here. As shown in FIGS. 25a and 25b, FIG. 25a is a planar structure diagram of sixteen sub-pixels, and FIG. 25b is a schematic planar diagram of the first conductive layer in FIG. 25a. The pattern of the first conductive layer in FIG. 25b is different from the pattern of the first conductive layer in FIG. 11b in that the first conductive layers in two adjacent columns of sub-pixels are disposed symmetrically with respect to the centerline between the two adjacent columns of sub-pixels.

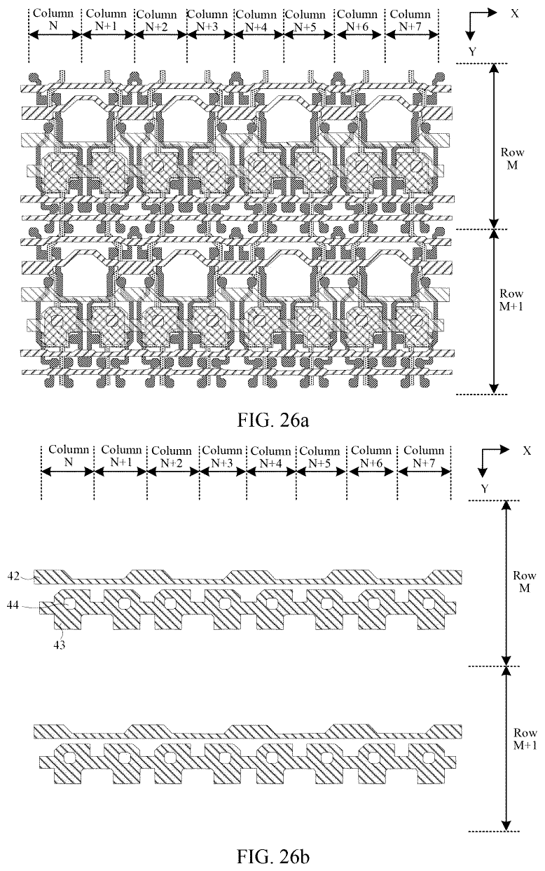

(205) Forming a pattern of a second conductive layer. The manufacturing method is the same as that in the operation (105) above, and will not be described here. As shown in FIGS. 26a and 26b, FIG. 26a is a planar structure diagram of sixteen sub-pixels, and FIG. 26b is a schematic planar diagram of the second conductive layer in FIG. 26a. The pattern of the second conductive layer in FIG. 25b is different from the pattern of the second conductive layer in FIG. 12b in that the second conductive layers in two adjacent columns of sub-pixels are disposed symmetrically with respect to the centerline between the two adjacent columns of sub-pixels.

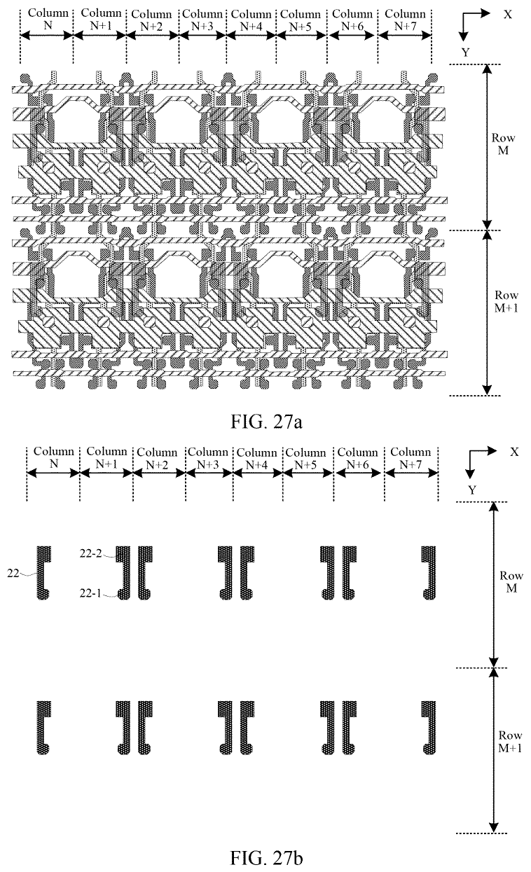

(206) A pattern of a second semiconductor layer is formed. The manufacturing method is the same as that in the operation (106) above, and will not be described here. As shown in FIGS. 27a and 27b, FIG. 27a is a planar structure diagram of sixteen sub-pixels, and FIG. 27b is a schematic planar diagram of the second semiconductor layer in FIG. 27a. The pattern of the second semiconductor layer in FIG. 27b is different from the pattern of the second semiconductor layer in FIG. 13b in that the second semiconductor layers in two adjacent columns of sub-pixels are disposed symmetrically with respect to the centerline between the two adjacent columns of sub-pixels

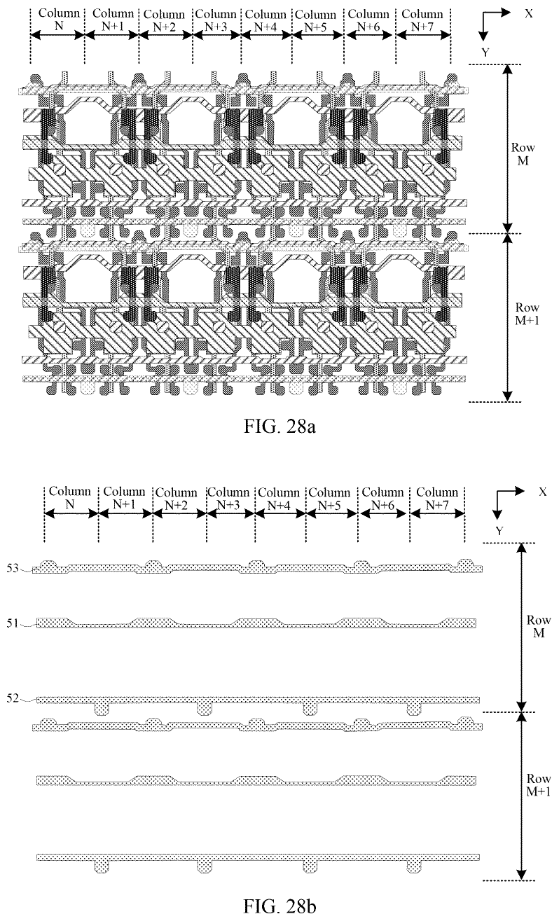

(207) Forming a pattern of a third conductive layer. The manufacturing method is the same as that in the operation (107) above, and will not be described here. As shown in FIGS. 28a and 28b, FIG. 28a is a planar structure diagram of sixteen sub-pixels, and FIG. 28b is a schematic planar diagram of the third conductive layer in FIG. 28a. The pattern of the third conductive layer in FIG. 28b is different from the pattern of the third conductive layer in FIG. 14b in that the third conductive layers in two adjacent columns of sub-pixels are disposed symmetrically with respect to the centerline between the two adjacent columns of sub-pixels.

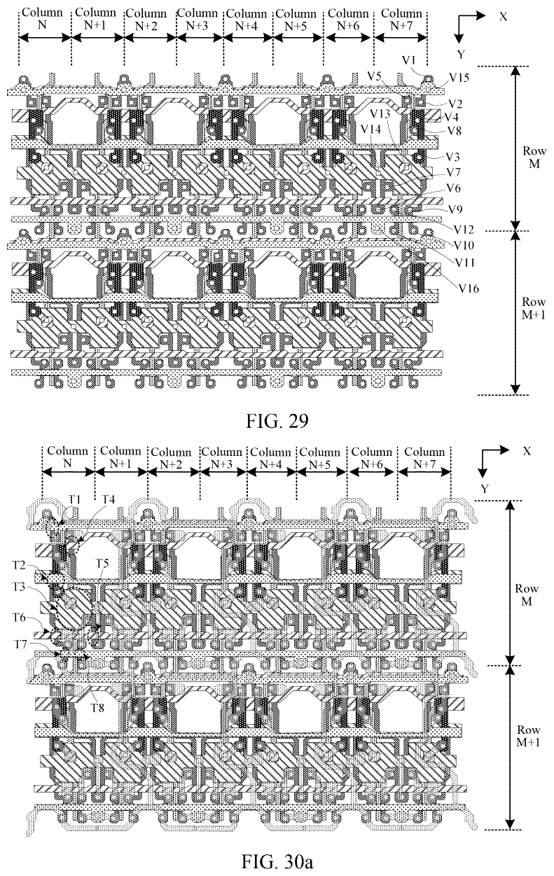

(208) A pattern of a sixth insulation layer is formed. The manufacturing method is the same as that in the operation (108) above, and will not be described here. FIG. 29 is a planar structure diagram of sixteen sub-pixels after the pattern of the sixth insulation layer is formed.

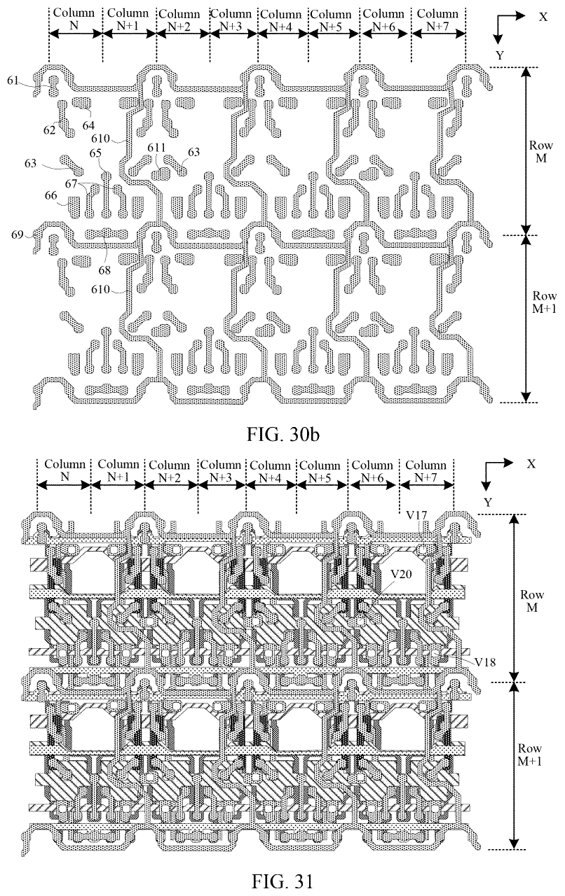

(209) Forming a pattern of a fourth conductive layer. The manufacturing method is the same as that in the operation (109) above, and will not be described here. As shown in FIGS. 30a and 30b, FIG. 30a is a planar structure diagram of sixteen sub-pixels, and FIG. 30b is a schematic planar diagram of the fourth conductive layer in FIG. 30a. The pattern of the fourth conductive layer in FIG. 30b is different from the pattern of the fourth conductive layer in FIG. 16b in that, in addition to the structure of the second initial signal connection line 610, the fourth conductive layers in two adjacent columns of sub-pixels are symmetrically disposed with respect to the centerline between the two adjacent columns of sub-pixels. In the structure shown in FIG. 30b, one second initial signal connection line 610 may be provided for two adjacent columns of sub-pixels, and in this case, the second initial signal connection line 610 for two adjacent columns of sub-pixels may be symmetrically disposed with respect to the centerline between the two columns of sub-pixels. In some other embodiments, a second initial signal connection line 610 may be provided for each sub-pixel, or one second initial signal connection line 610 may be provided for three to six adjacent sub-pixels.

(210) Patterns of a seventh insulation layer and a first planarization layer are formed. The manufacturing method is the same as that in the operation (110) above, and will not be described here. FIG. 31 is a planar structure diagram of sixteen sub-pixels after the seventh insulation layer and the pattern of the first planarization layer are formed. FIG. 31 is different from FIG. 17 in that the nineteenth via V19 is not provided in FIG. 31.

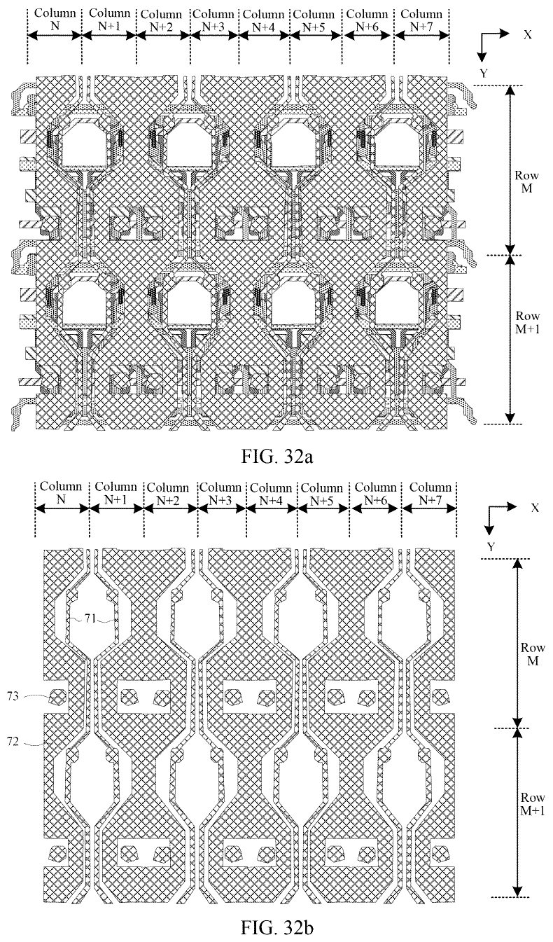

(211) Forming a pattern of a fifth conductive layer. The manufacturing method is the same as that in the operation (111) above, and will not be described here. As shown in FIGS. 32a and 32b, FIG. 32a is a planar structure diagram of sixteen sub-pixels, and FIG. 32b is a schematic planar diagram of the fifth conductive layer in FIG. 32a. The pattern of the fifth conductive layer in FIG. 32b is different from the pattern of the fifth conductive layer in FIG. 18d in that the fifth conductive layers in two adjacent columns of sub-pixels are disposed symmetrically with respect to the centerline between the two adjacent columns of sub-pixels.

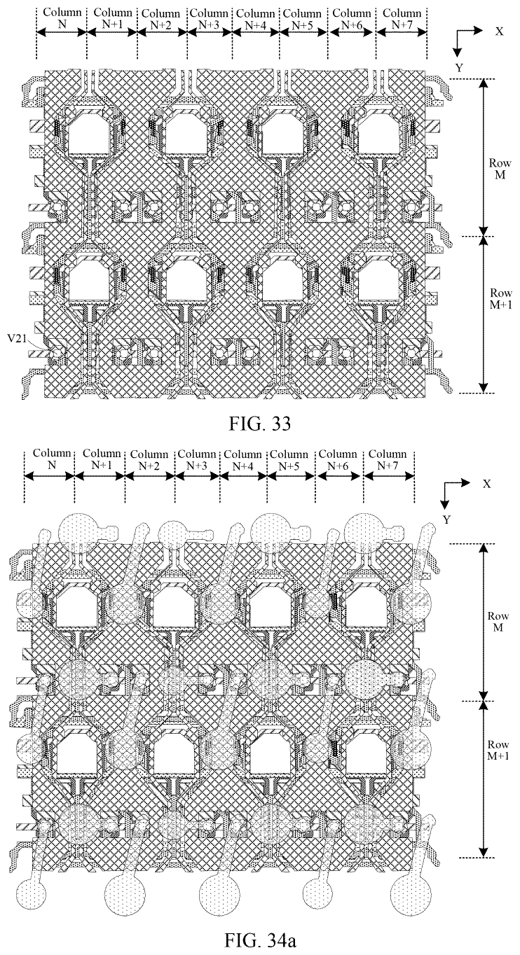

(212) A pattern of a second planarization layer is formed. The manufacturing method is the same as that in the operation (112) above, and will not be described here. FIG. 33 is a planar structure diagram of sixteen sub-pixels after the pattern of the second planarization layer is formed.

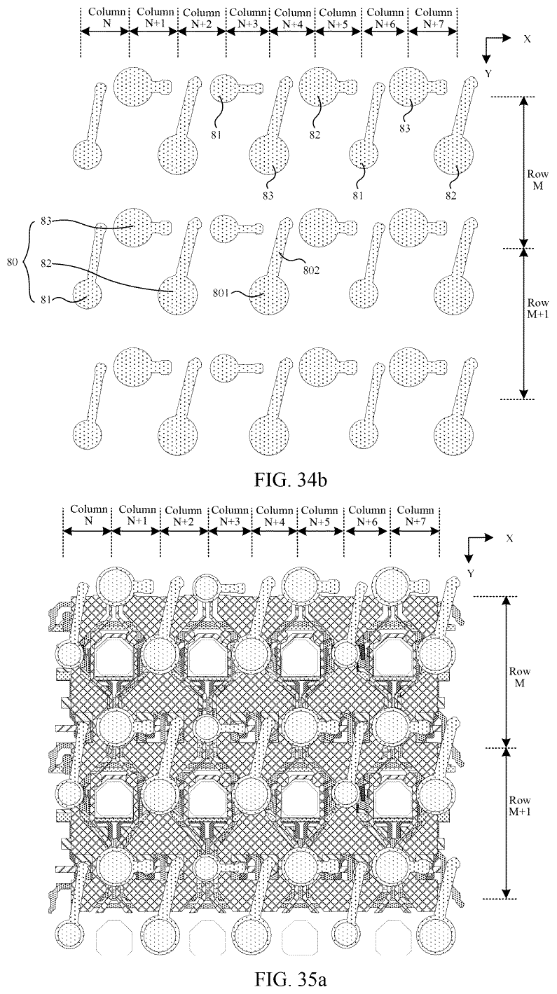

(213) A pattern of an anode conductive layer is formed. The manufacturing method is the same as that in the operation (113) above, and will not be described here. As shown in FIGS. 34a and 34b, FIG. 34a is a planar structure diagram of sixteen sub-pixels, and FIG. 34b is a schematic planar diagram of the anode conductive layer in FIG. 34a. The differences between the pattern of the anode conductive layer in FIG. 34b and the pattern of the anode conductive layer in FIG. 20d at least include: the anodes of a plurality of same type sub-pixels may be located in the same column, a plurality of repeating units are included in the first direction X, the plurality of repeating units are arranged in the first direction X, and each repeating unit includes an anode 81 of a first sub-pixel, an anode 82 of a second sub-pixel, and an anode 83 of a third sub-pixel arranged sequentially in the first direction X.

In an exemplary implementation, as shown in FIG. 34b, in the first direction X, a first anode 81 (the anode of the first sub-pixel) in one pixel row may be located between a second anode 82 (the anode of the second sub-pixel) and a third anode 83 (the anode of the third sub-pixel) in adjacent pixel rows, and the three anodes form a pixel unit arranged in a triangle. In the first direction X, a second anode 82 at one pixel row may be located between a third anode 83 and a first anode 81 at an adjacent pixel row, and these three anodes constitute a triangular-arranged pixel unit. In the first direction X, a third anode 83 at one pixel row may be located between a first anode 81 and a second anode 82 at an adjacent pixel row, and these three anodes constitute a triangular-arranged pixel unit.

In an exemplary implementation, as shown in FIG. 34b, in the second direction Y, the first anode 81 in one pixel column may be located between two second anodes 82 in one adjacent pixel column, and the first anode 81 in one pixel column may be located between two third anodes 83 in the other adjacent pixel column. In the second direction Y, the second anode 82 in one pixel column may be located between two first anodes 81 in one adjacent pixel column, and the second anode 82 in one pixel column may be located between two third anodes 83 in the other adjacent pixel column. In the second direction Y, the third anode 83 in one pixel column may be located between two second anodes 82 in one adjacent pixel column, and the third anode 83 in one pixel column may be located between two first anodes 81 in the other adjacent pixel column.

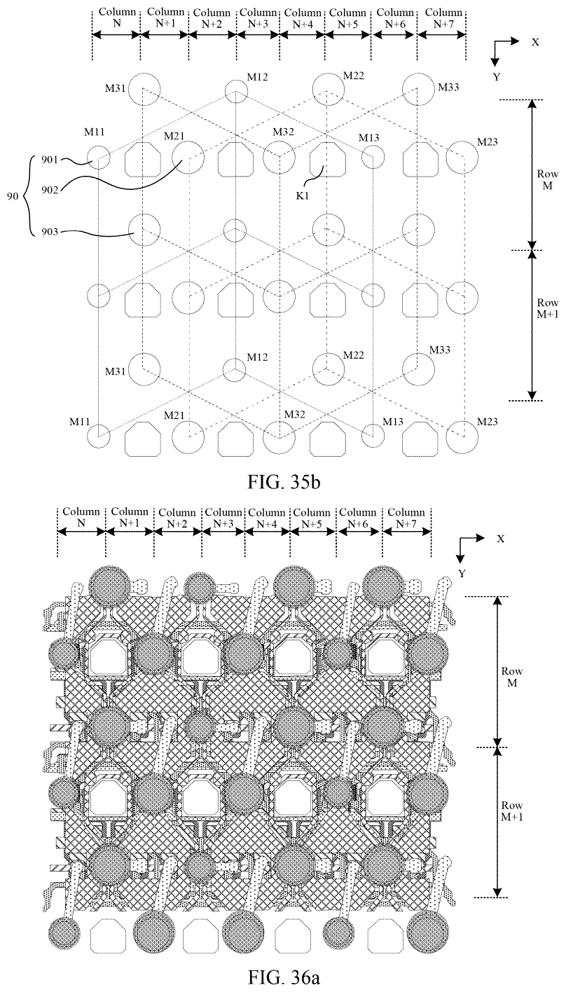

(214) A pattern of a pixel definition layer is formed. The manufacturing method is the same as that in the operation (114) above, and will not be described here. As shown in FIGS. 35a and 35b, FIG. 35a is a planar structure diagram of sixteen sub-pixels, and FIG. 35b is a schematic planar diagram of the pixel definition layer in FIG. 35a. The differences between the pattern of the anode conductive layer in FIG. 35b and the pattern of the anode conductive layer in FIG. 21d at least include: the pixel openings of a plurality of same type sub-pixels may be located in the same column, a plurality of repeating units are included in the first direction X, the plurality of repeating units are arranged in the first direction X, and each repeating unit includes a pixel opening 901 of a first sub-pixel, a pixel opening 902 of a second sub-pixel, and a pixel opening 903 of a third sub-pixel arranged sequentially in the first direction X. The arrangement of a plurality of pixel openings in FIG. 35b is the same as the arrangement of a plurality of corresponding anodes in FIG. 34b.

As shown in FIG. 35b, a line connecting the centers of the pixel openings of a plurality of same type sub-pixels in the first direction X is a polyline. For example, a line connecting the centers of the pixel openings 901 of a plurality of first sub-pixels in the first direction X is a polyline M11-M12-M13; a line connecting the centers of the pixel openings 902 of a plurality of second sub-pixels in the first direction X is a polyline M21-M22-M23; and a line connecting the centers of the pixel openings 903 of a plurality of third sub-pixels in the first direction X is a polyline M31-M32-M33.

As shown in FIG. 35b, a line connecting the centers of the pixel openings of a plurality of same type sub-pixels in the second direction Y is a straight line. For example, a line connecting the centers of the pixel openings 901 of a plurality of first sub-pixels in the second direction Y is a straight line M11-M11, M12-M12, and M13-M13; a line connecting the centers of the pixel openings 902 of a plurality of second sub-pixels in the second direction Y is a straight line M21-M21, M22-M22, and M23-M23; and a line connecting the centers of the pixel openings 903 of a plurality of third sub-pixels in the second direction Y is a straight line M31-M31, M32-M32, and M33-M33.

As shown in FIG. 35b, a plurality of first openings KI are arranged in the first direction X and the second direction Y, in the first direction X, one pixel opening is provided between two adjacent first openings K1, and in the second direction Y, one pixel opening is provided between two adjacent first openings K1.

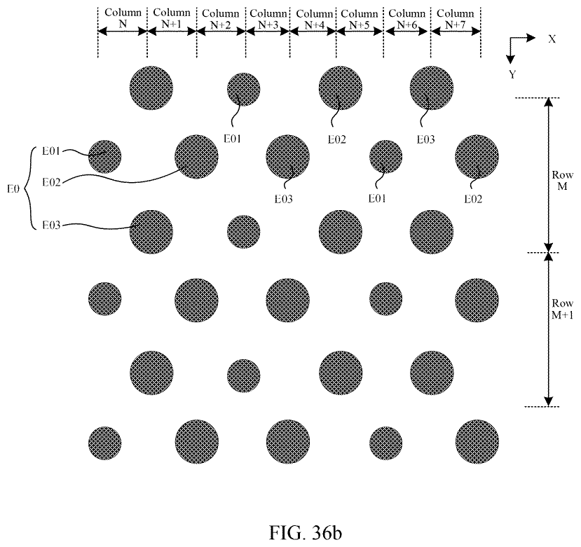

(215) A pattern of a light emitting layer is formed. The manufacturing method is the same as that in the operation (115) above, and will not be described here. As shown in FIGS. 36a and 36b, FIG. 36a is a planar structure diagram of sixteen sub-pixels, and FIG. 36b is a schematic planar diagram of the pixel definition layer in FIG. 36a. The pattern of the anode conductive layer in FIG. 36b is different from the pattern of the anode conductive layer in FIG. 22b in that: light-emitting layers of a plurality of same type sub-pixels are located in the same column, in the first direction X, a plurality of repeating units are arranged in the first direction X, and each repeating unit includes a light-emitting layer E01 of a first sub-pixel, a light-emitting layer E02 of a second sub-pixel, and a light-emitting layer E03 of a third sub-pixel arranged sequentially in the first direction X. The arrangement of a plurality of light-emitting layers in FIG. 36b is the same as the arrangement of a plurality of corresponding pixel openings in FIG. 35b.

As shown in FIG. 22a, FIG. 22b, FIG. 36a, and FIG. 36b, an orthographic projection of a light-emitting layer on the base substrate at least partially overlaps with an orthographic projection of a corresponding pixel opening on the base substrate. The light-emitting layer E0 may include a light-emitting layer E01 of a first sub-pixel, a light-emitting layer E02 of a second sub-pixel, and a light-emitting layer E03 of a third sub-pixel. An orthographic projection of the light-emitting layer E01 of the first sub-pixel on the base substrate is overlapped with an orthographic projection of the pixel opening 901 of the first sub-pixel on the base substrate; an orthographic projection of the light-emitting layer E02 of the second sub-pixel on the base substrate is overlapped with an orthographic projection of the pixel opening 902 of the second sub-pixel on the base substrate; and an orthographic projection of the light-emitting layer E03 of the third sub-pixel on the base substrate is overlapped with an orthographic projection of the pixel opening 903 of the third sub-pixel on the base substrate. In an exemplary implementation, the shield layer, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo and Ti/Al/Ti. The first insulation layer, the second insulation layer, the third insulation layer, the fourth insulation layer, the fifth insulation layer, the sixth insulation layer, and the seventh insulation layer may be made of any one or more of silicon oxide (SiOx), silicon nitride (SiNx), and silicon oxynitride (SiON), and may be single layers, a plurality of layers, or composite layers. The first insulation layer may be referred to as a Buffer layer, which is used for improving the water and oxygen resistance of the base substrate. The second insulation layer, the third insulation layer, the fourth insulation layer, and the fifth insulation layer may be referred to as a gate insulation (GI) layer, the sixth insulation layer may be referred to as an interlayer dielectric (ILD) layer, and the seventh insulation layer may be referred to as a passivation (PVX) layer.

The structure and manufacturing process shown in the aforementioned embodiments of the present disclosure are only an exemplary explanation. In an exemplary implementation, the corresponding structure can be changed and the patterning process can be added or reduced according to actual needs. The display substrate of an embodiment of the present disclosure may be applied to other display devices with a pixel drive circuit, such as a quantum dot display. The present disclosure is not limited herein.

The present disclosure further provides a display apparatus, including the display substrate according to any of the aforementioned embodiments. The display apparatus may be any product or component with a display function, such as a mobile phone, a tablet computer, a television, a display, a laptop computer, a digital photo frame, or a navigator.

An embodiment of the present disclosure further provides a display apparatus including the display substrate including the first opening described above. The display apparatus may further include a photosensitive element, and an orthographic projection of the photosensitive element on the base substrate of the display substrate is within a range of an orthographic projection of the first opening of the display substrate on the base substrate.

In the display substrate and the display apparatus according to embodiments of the present disclosure, the area of the pixel opening of the first sub-pixel in the display substrate is smaller than the area of the pixel opening of the second sub-pixel, and the overlapping area of the pixel opening of the first sub-pixel with the at least one conductive layer is larger than the overlapping area of the pixel opening of the second sub-pixel with the at least one conductive layer, which can solve the problems of color separation, color cast and poor uniformity in the display panel. The drawings of the embodiments of the present disclosure only involve structures involved in the embodiments of the present disclosure, and other structures may refer to a general design.

The embodiments of the present disclosure, that is, features in the embodiments, may be combined with each other to obtain new embodiments in the case of no conflict.

Although the implementations disclosed in the embodiments of the present disclosure are described above, contents are only implementations for facilitating understanding of the embodiments of the present disclosure, but are not intended to limit the embodiments of the present disclosure. Any person skilled in the art to which the embodiments of the present disclosure pertain may make any modifications and variations in forms and details of implementation without departing from the spirit and the scope disclosed in the embodiments of the present disclosure. Nevertheless, the scope of patent protection of the embodiments of the present disclosure shall still be subject to the scope defined by the appended claims.

1. A display substrate, comprising a base substrate, and a plurality of sub-pixels, a drive circuit layer and a pixel definition layer disposed on the base substrate, wherein in a direction perpendicular to a plane of the display substrate, the drive circuit layer is located between the base substrate and the pixel definition layer, a plurality of pixel openings are formed in the pixel definition layer, and each sub-pixel comprises at least one pixel opening;
the plurality of sub-pixels comprise a plurality of types of sub-pixels, the plurality of types of sub-pixels at least comprise a first sub-pixel and a second sub-pixel, an area of a pixel opening of the first sub-pixel is smaller than an area of a pixel opening of the second sub-pixel, the pixel opening of the first sub-pixel and the pixel opening of the second sub-pixel overlap with at least one conductive layer in the drive circuit layer, and an overlapping area of the pixel opening of the first sub-pixel with the at least one conductive layer is larger than an overlapping area of the pixel opening of the second sub-pixel with the at least one conductive layer.

2. The display substrate according to claim 1, wherein the plurality of types of sub-pixels further comprise a third sub-pixel, the area of the pixel opening of the first sub-pixel is smaller than an area of a pixel opening of the third sub-pixel, and an overlapping area of the pixel opening of the third sub-pixel with the at least one conductive layer is larger than the overlapping area of the pixel opening of the second sub-pixel with the at least one conductive layer.

3. The display substrate according to claim 2, wherein orthographic projections of the pixel opening of the first sub-pixel and the pixel opening of the third sub-pixel on the base substrate are within a range of an orthographic projection of the at least one conductive layer on the base substrate.

4. The display substrate according to claim 3, wherein the at least one conductive layer comprises a first protrusion and a second protrusion, an orthographic projection of the pixel opening of the first sub-pixel on the base substrate is within a range of an orthographic projection of the first protrusion on the base substrate, and an orthographic projection of the pixel opening of the third sub-pixel on the base substrate is within a range of an orthographic projection of the second protrusion on the base substrate.

5. The display substrate according to claim 3, wherein the pixel opening of the second sub-pixel overlaps with patterns of at least two portions of signal lines in the at least one conductive layer, and the patterns of the at least two portions of signal lines are distributed on two sides of a center of the pixel opening of the second sub-pixel.

6. The display substrate according to claim 5, wherein the pixel opening of the first sub-pixel and the pixel opening of the third sub-pixel are arranged in a column direction, and main body portions of the signal lines in the patterns of the at least two portions of signal lines extend in the column direction; or
wherein the display substrate further comprises an anode via and an anode connection electrode, wherein the patterns of the at least two portions of signal lines comprise a proximal portion and a distal portion relative to the pixel opening of the second sub-pixel, the pixel opening of the second sub-pixel overlaps with the proximal portion, a hollow structure is provided in middle of the distal portion, the hollow structure is configured to accommodate the anode connection electrode, an orthographic projection of the anode connection electrode on the base substrate is overlapped with an orthographic projection of a corresponding hollow structure on the base substrate, and an orthographic projection of the anode via on the base substrate is overlapped with an orthographic projection of a corresponding anode connection electrode on the base substrate; or
wherein the pixel opening of the second sub-pixel also overlaps with at least part of signal wires other than the patterns of the at least two portions of signal lines in the drive circuit layer, and the at least part of signal wires located on two sides of the center of the pixel opening of the second sub-pixel have a same overlapping area with the pixel opening of the second sub-pixel

7-8. (canceled)

9. The display substrate according to claim 1, further comprising an anode conductive layer, in the direction perpendicular to the plane of the display substrate, the anode conductive layer is located between the drive circuit layer and the pixel definition layer, and at least a part of the at least one conductive layer comprises a conductive layer closest to the anode conductive layer in the drive circuit layer.

10. The display substrate according to claim 2, wherein pixel openings of a plurality of a same type of sub-pixels are arranged in a row direction and a column direction, and centers of pixel openings of a plurality of a same type of sub-pixels located in a same row are on a same straight line.

11. The display substrate according to claim 10, wherein the pixel openings of the plurality of the same type of sub-pixels form M rows and N columns, where M and N are positive integers greater than 1, among the pixel openings of the plurality of the same type of sub-pixels in the M rows and N columns, a center of a pixel opening of a sub-pixel located in row i and column j is on a same straight line as centers of pixel openings of sub-pixels located in row i+1 and column j+1 and in row i+2 and column j+2, where i is a positive integer greater than 1 and smaller than or equal to M, and j is a positive integer greater than 1 and smaller than or equal to N.

12. The display substrate according to claim 11, wherein among the pixel openings of the plurality of the same type of sub-pixels in the M rows and the N columns, a centerline of a pixel opening of a sub-pixel located in row i and column j+2 is on a same straight line as centerlines of pixel openings of sub-pixels located in row i+1 and column j+1 and in row i+2 and column j; or
wherein the at least one conductive layer comprises a plurality of data signal lines, a main body portion of a data signal line extends in the column direction, the pixel definition layer is further formed with a plurality of first openings arranged in an array, an orthographic projection of a first opening on the base substrate does not overlap with an orthographic projection of the data signal line on the base substrate, and the first openings and pixel openings of second sub-pixels are alternately arranged in the column direction.

13. (canceled)

14. The display substrate according to claim 12, wherein in the column direction, pixel openings of first sub-pixels and pixel openings of third sub-pixels are alternately arranged, a pixel opening of a second sub-pixel and a first opening are located between pixel openings of first sub-pixels and pixel openings of third sub-pixels in adjacent columns, and a pixel opening of a first sub-pixel and a pixel opening of a third sub-pixel are located between first openings and pixel openings of second sub-pixels in adjacent columns; or
wherein in the row direction, a pixel opening of a first sub-pixel and a pixel opening of a third sub-pixel are located between two first openings in adjacent rows and pixel openings of two second sub-pixels in adjacent rows, and a pixel opening of a second sub-pixel and a first opening are located between pixel openings of two first sub-pixels in adjacent rows and pixel openings of two third sub-pixels in adjacent rows; or
the display substrate further comprises an anode conductive layer, the at least one conductive layer comprises a fifth conductive layer, on the plane perpendicular to the display substrate, the anode conductive layer is located between the fifth conductive layer and the pixel definition layer, the anode conductive layer comprises an anode of the second sub-pixel, there is a first overlapping area between an orthographic projection of the fifth conductive layer on the base substrate and orthographic projections of the pixel opening of the second sub-pixel and the anode of the second sub-pixel on the base substrate, and on a plane parallel to the display substrate, the first overlapping area is symmetrical with respect to centerlines of the pixel opening of the second sub-pixel in the row direction and the column direction.

15-16. (canceled)

17. The display substrate according to claim 14, wherein the anode conductive layer further comprises an anode of the first sub-pixel and an anode of the third sub-pixel, the fifth conductive layer comprises a plurality of first power supply lines, main body portions of the first power supply lines extend in the column direction, and orthographic projections of the pixel opening and the anode of the first sub-pixel and the pixel opening and the anode of the third sub-pixel on the base substrate are within a range of an orthographic projection of the first power supply lines on the base substrate; or
wherein in the row direction, the first opening is located between two adjacent data signal lines, and the two data signal lines located on two sides of the first opening are symmetrically disposed with respect to a centerline, extending in the column direction, of the pixel opening of the second sub-pixel in the column where the first opening is located.

18. (canceled)

19. The display substrate according to claim 17, wherein at least one sub-pixel comprises a pixel drive circuit, the pixel drive circuit comprises a plurality of transistors, the plurality of transistors comprise a drive transistor and a fourth transistor, a second electrode of the fourth transistor is electrically connected to a first electrode of the drive transistor, the fourth transistor is disposed to provide a data signal to the drive transistor, the data signal lines located on the two sides of the first opening in the row direction comprise a first portion and a second portion which are integrally formed, the first portion extends in the column direction, the second portion is a bent structure, orthographic projections of a channel region and a first region of the fourth transistor on the base substrate overlap with an orthographic projection of the first portion on the base substrate, first portions of the two data signal lines located on the two sides of the first opening in the row direction form a second opening, and an orthographic projection of the first opening on the base substrate is within a range of an orthographic projection of the second opening on the base substrate.

20. The display substrate according to claim 19, wherein a middle portion of the second portion is bent in a direction close to the first opening, and an orthographic projection of the middle portion of the second portion on the base substrate is overlapped with orthographic projections of the pixel opening and the anode of the second sub-pixel on the base substrate.

21. The display substrate according to claim 2, wherein the plurality of sub-pixels further comprise light-emitting layers corresponding to the pixel openings, the first sub-pixel comprises a first light-emitting layer, the second sub-pixel comprises a second light-emitting layer, the third sub-pixel comprises a third light-emitting layer, light-emitting layers of a plurality of types of sub-pixels are arranged in a row direction and a column direction, and centerlines of light-emitting layers of a plurality of a same type of sub-pixels located in a same row are on a same straight line; or
wherein the first sub-pixel is a sub-pixel emitting red light, the second sub-pixel is a sub-pixel emitting blue light, and the third sub-pixel is a sub-pixel emitting green light.

22. The display substrate according to claim 21, wherein the light-emitting layers of the plurality of the same type of sub-pixels form M rows and N columns, where M and N are positive integers greater than 1, among the light-emitting layers of the plurality of the same type of sub-pixels in the M rows and N columns, a center of a light-emitting layer of a sub-pixel located in row i and column j is on a same straight line as centers of light-emitting layers of sub-pixels located in row i+1 and column j+1 and in row i+2 and column j+2, where i is a positive integer greater than 1 and smaller than or equal to M, and j is a positive integer greater than 1 and smaller than or equal to N.

23. The display substrate according to claim 22, wherein among the light-emitting layers of the plurality of the same type of sub-pixels in the M rows and the N columns, a centerline of a light-emitting layer of a sub-pixel located in row i and column j+2 is on a same straight line as centerlines of light-emitting layers of sub-pixels located in row i+1 and column j+1 and in row i+2 and column j.

24. The display substrate according to claim 21, wherein the light-emitting layers of the plurality of sub-pixels have a same shape as corresponding pixel openings, and an orthographic projection of the light-emitting layers of the plurality of sub-pixels on the base substrate is overlapped with an orthographic projection of the corresponding pixel openings on the base substrate.

25. (canceled)

26. A display apparatus, comprising the display substrate according to claim 1.

27. A display apparatus, comprising the display substrate according to claim 12, wherein the display apparatus further comprises a photosensitive element, and an orthographic projection of the photosensitive element on the base substrate of the display substrate is within a range of an orthographic projection of a first opening of the display substrate on the base substrate.
